(19) United States
(12) Patent Application Publication
(10) Pub. No.: US 2023/0422616 A1
(43) Pub. Date: Dec. 28, 2023

(54) LIGHT ABSORPTION ANISOTROPIC FILM, LAMINATE, IMAGE DISPLAY DEVICE, AND LIQUID CRYSTAL COMPOSITION

(71) Applicant: FUJIFILM Corporation, Tokyo (JP)

(72) Inventors: Hiroshi MATSUYAMA, Kanagawa (JP); Wataru HOSHINO, Kanagawa (JP); Naoki KOITO, Kanagawa (JP); Aiko YOSHIDA, Kanagawa (JP)

(73) Assignee: FUJIFILM Corporation, Tokyo (JP)

(21) Appl. No.: 18/339,732

(22) Filed: Jun. 22, 2023

Related U.S. Application Data
(63) Continuation of application No. PCT/JP2021/047595, filed on Dec. 22, 2021.

(30) Foreign Application Priority Data
Dec. 25, 2020 (JP) 2020-216580
Dec. 16, 2021 (JP) 2021-204149

(51) Int. Cl. H10K 85/60; H10K 85/00; H10K 85/10; H10K 50/816

(52) U.S. Cl. CPC H10K 85/658; H10K 50/816; H10K 85/10; H10K 85/731

(57) ABSTRACT

An object of the present invention is to provide Provided is a light absorption anisotropic film, a laminate, an image display device, and a liquid crystal composition with excellent adhesiveness and a high alignment degree. The light absorption anisotropic film of the present invention is a light absorption anisotropic film is formed of a liquid crystal composition that contains a liquid crystal compound, a dichroic substance, and a boronic acid compound containing a polymerizable group, in which the liquid crystal compound is horizontally aligned.

### CROSS-REFERENCE TO RELATED APPLICATIONS

This application is a Continuation of PCT International Application No. PCT/JP2021/047595 filed on Dec. 22, 2021, which claims priority under 35 U.S.C. § 119(a) to Japanese Patent Application No. 2020-216580 filed on Dec. 25, 2020 and Japanese Patent Application No. 2021-204149 filed on Dec. 16, 2021. The above applications are hereby expressly incorporated by reference, in their entirety, into the present application.

### BACKGROUND OF THE INVENTION

### 1. Field of the Invention

The present invention relates to a light absorption anisotropic film, a laminate, an image display device, and a liquid crystal composition.

### 2. Description of the Related Art

In the related art, in a case where an attenuation function, a polarization function, a scattering function, a light-shielding function of irradiation light including laser light or natural light is required, a device that is operated according to principles different for each function is used. Therefore, products corresponding to the above-described functions are also produced by production processes different for each function.

For example, a linear polarizer or a circular polarizer is used in an image display device (for example, a liquid crystal display device) to control optical rotation or birefringence in display. Further, a circular polarizer is used in an organic light emitting diode (OLED) to prevent reflection of external light.

In the related art, iodine has been widely used as a dichroic substance in these polarizers, but a polarizer that uses an organic coloring agent in place of iodine as a dichroic substance has also been examined.

For example, WO2017/195833A discloses that a light absorption anisotropic film is formed of a liquid crystal composition (coloring composition) containing a dichroic substance (dichroic coloring agent compound) having a predetermined structure. (claims 1 and 14 and the like).

### SUMMARY OF THE INVENTION

In recent years, a light absorption anisotropic film formed of a liquid crystal composition has been required to further improve the performance thereof, and specifically, a light absorption anisotropic film having an excellent alignment degree and excellent adhesiveness to other members has been required.

As a result of examination on the light absorption anisotropic film described in WO2017/195833A, the present inventors found that the light absorption anisotropic film exhibits a high alignment degree, but there is room for improvement in the adhesiveness of the light absorption anisotropic film to other members depending on the kind of the liquid crystal composition used to form the light absorption anisotropic film.

Therefore, an object of the present invention is to provide a light absorption anisotropic film, a laminate, an image display device, and a liquid crystal composition with excellent adhesiveness and a high alignment degree.

As a result of intensive examination conducted by the present inventors in order to achieve the above-described object, it was found that a light absorption anisotropic film formed of a liquid crystal composition that contains a liquid crystal compound, a dichroic substance, and a boronic acid compound containing a polymerizable group, in which the liquid crystal compound is horizontally aligned, has excellent adhesiveness to other layers and exhibits a high alignment degree, thereby completing the present invention.

That is, the present inventors found that the above-described problems can be solved by employing the following configurations.
[1] A light absorption anisotropic film formed of a liquid crystal composition that contains a liquid crystal compound, a dichroic substance, and a boronic acid compound containing a polymerizable group, in which the liquid crystal compound is horizontally aligned.
[2] The light absorption anisotropic film according to [1], in which the boronic acid compound containing a polymerizable group includes at least one of a compound represented by Formula (B-1) or a compound represented by Formula (BX-1),
in Formula (B-1), R^{B11} represents a hydrogen atom or a methyl group, L^{B1} represents a single bond, a divalent aliphatic hydrocarbon group, or a divalent group in which one or more of —CH₂ —'s constituting a divalent aliphatic hydrocarbon group is substituted with at least one group selected from the group consisting of —O—, —C(═O)—, and —N(R^{B14})—, R^{B14} represents a hydrogen atom or an alkyl group, A^{B1} represents an arylene group that may have a substituent or a heteroarylene group that may have a substituent, R^{B12} and R^{B13} each independently represent a hydrogen atom, an alkyl group that may have a substituent, an aryl group that may have a substituent, or a heteroaryl group that may have a substituent, and R^{B12} and R^{B13} may be bonded to each other to form a ring,
in Formula (BX-1), R^{BX11} represents a hydrogen atom or a methyl group, where a plurality of R^{BX11}'s may be the same as or different from each other, L^{BX1} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{BX14})—, where a plurality of L^{BX1}'s may be the same as or different from each other, R^{BX14} represents a hydrogen atom or an alkyl group, and in a case where a plurality of R^{BX14}'s are present, the plurality of R^{BX14}'s may be the same as or different from each other, A^{BX1} represents an arylene group that may have a substituent or a heteroarylene group that may have a substituent, and a plurality of A^{BX1}'s may be the same as or different from each other.
[3] The light absorption anisotropic film according to [1] or [2], in which the boronic acid compound containing a polymerizable group includes at least one of a compound represented by Formula (B-2) or a compound represented by Formula (BX-2),

in Formula (B-2), R^{B21} represents a hydrogen atom or a methyl group, L^{B2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{B25})—, R^{B25} represents a hydrogen atom or an alkyl group, R^{B22} and R^{B23} each independently represent a hydrogen atom, an alkyl group that may have a substituent, an aryl group that may have a substituent, or a heteroaryl group that may have a substituent, where R^{B22} and R^{B23} may be bonded to each other to form a ring, R^{B24} represents a monovalent substituent, nb represents an integer of 0 to 4, and in a case where nb represents 2 or greater, a plurality of R^{B24}'s may be the same as or different from each other,
in Formula (BX-2), R^{BX21} represents a hydrogen atom or a methyl group, where a plurality of R^{BX21}'s may be the same as or different from each other, L^{BX2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{BX25})—, where a plurality of L^{BX2}'s may be the same as or different from each other, R^{BX25} represents a hydrogen atom or an alkyl group, and in a case where a plurality of R^{BX25}'s are present, the plurality of R^{BX25}'s may be the same as or different from each other, R^{BX24} represents a monovalent substituent, where in a case where a plurality of R^{BX24}'s are present, the plurality of R^{BX24}'s may be the same as or different from each other, nc represents an integer of 0 to 4, and a plurality of nc's may be the same as or different from each other.
[4] The light absorption anisotropic film according to any one of [1] to [3], in which a content of the boronic acid compound containing a polymerizable group is in a range of 0.1% to 10% by mass with respect to a total mass of a solid content of the liquid crystal composition.

[5] The light absorption anisotropic film according to [2], in which the boronic acid compound containing a polymerizable group includes the compound represented by Formula (B-1) and the compound represented by Formula (BX-1), and a mass ratio of a content of the compound represented by Formula (B-1) to a content of the compound represented by Formula (BX-1) is in a range of 5 to 500.
[6] The light absorption anisotropic film according to [3], in which the boronic acid compound containing a polymerizable group includes the compound represented by Formula (B-2) and the compound represented by Formula (BX-2), and a mass ratio of a content of the compound represented by Formula (B-2) to a content of the compound represented by Formula (BX-2) is in a range of 5 to 500.
[7] The light absorption anisotropic film according to any one of [1] to [6], in which the liquid crystal compound includes a polymer liquid crystal compound.
[8] A laminate comprising: the light absorption anisotropic film according to any one of [1] to [7]; and a layer containing a polyvinyl alcohol-based resin disposed to be in contact with the light absorption anisotropic film.
[9] The laminate according to [8], further comprising: a λ/4 plate on a side of the light absorption anisotropic film opposite to the layer containing a polyvinyl alcohol-based resin.
[10] An image display device comprising: the light absorption anisotropic film according to any one of [1] to [7]; or the laminate according to [8] or [9].
[11] A liquid crystal composition comprising: a liquid crystal compound; a dichroic substance; and a boronic acid compound containing a polymerizable group, in which the boronic acid compound containing a polymerizable group includes at least one of a compound represented by Formula (B-2) or a compound represented by Formula (BX-1),
in Formula (B-2), R^{B21} represents a hydrogen atom or a methyl group, L^{B2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{B25})—, R^{B25} represents a hydrogen atom or an alkyl group, R^{B22} and R^{B23} each independently represent a hydrogen atom, an alkyl group that may have a substituent, an aryl group that may have a substituent, or a heteroaryl group that may have a substituent, where R^{B22} and R^{B23} may be bonded to each other to form a ring, R^{B24} represents a monovalent substituent, nb represents an integer of 0 to 4, and in a case where nb represents 2 or greater, a plurality of RB²⁴'s may be the same as or different from each other,
in Formula (BX-1), R^{BX11} represents a hydrogen atom or a methyl group, where a plurality of R^{BX11}'s may be the same as or different from each other, L^{BX1} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{BX14})—, where a plurality of L^{BX1}'s may be the same as or different from each other, R^{BX14} represents a hydrogen atom or an alkyl group, and in a case where a plurality of R^{BX14}'s are present, the plurality of R^{BX14}'s may be the same as or different from each other, A^{BX1} represents an arylene group that may have a substituent or a heteroarylene group that may have a substituent, and a plurality of A^{BX1}'s may be the same as or different from each other.
[12] The liquid crystal composition according to [11], in which the compound represented by Formula (BX-1) is a compound represented by Formula (BX-2),
in Formula (BX-2), R^{BX21} represents a hydrogen atom or a methyl group, where a plurality of R^{BX21}'s may be the same as or different from each other, L^{BX2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{BX25})—, where a plurality of L^{BX2}'s may be the same as or different from each other, R^{BX25} represents a hydrogen atom or an alkyl group, and in a case where a plurality of R^{BX25}'s are present, the plurality of R^{BX25}'s may be the same as or different from each other, R^{BX24} represents a monovalent substituent, where in a case where a plurality of R^{BX24}'s are present, the plurality of R^{BX24}'s may be the same as or different from each other, nc represents an integer of 0 to 4, and a plurality of nc's may be the same as or different from each other.
[13] The liquid crystal composition according to or [12], in which a content of the boronic acid compound containing a polymerizable group is in a range of 0.1% to 10% by mass with respect to a total mass of a solid content of the liquid crystal composition.
[14] The liquid crystal composition according to any one of to [13], in which the boronic acid compound containing a polymerizable group includes the compound represented by Formula (B-2) and the compound represented by Formula (BX-1), and a mass ratio of a content of the compound represented by Formula (B-2) to a content of the compound represented by Formula (BX-1) is in a range of 5 to 500.

According to the present invention, it is possible to provide a light absorption anisotropic film, a laminate, an image display device, and a liquid crystal composition with excellent adhesiveness and a high alignment degree.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

Further, in the present specification, the numerical ranges shown using “to” indicate ranges including the numerical values described before and after “to” as the lower limits and the upper limits.

Further, in the present specification, materials corresponding to respective components may be used alone or in combination of two or more kinds thereof. Here, in a case where two or more kinds of materials corresponding to respective components are used in combination, the content of the components indicates the total content of the combined materials unless otherwise specified.

Further, in the present specification, “(meth)acrylate” denotes “acrylate” or “methacrylate”, “(meth)acryl” denotes “acryl” or “methacryl”, “(meth)acryloyl” denotes “acryloyl” or “methacryloyl”, and “(meth)acrylic acid” denotes “acrylic acid” or “methacrylic acid”.

### [Light Absorption Anisotropic Film]

A light absorption anisotropic film according to the embodiment of the present invention is a light absorption anisotropic film formed of a liquid crystal composition that contains a liquid crystal compound, a dichroic substance, and a boronic acid compound containing a polymerizable group (hereinafter, also referred to as “polymerizable boronic acid compound”), in which the liquid crystal compound is horizontally aligned.

The light absorption anisotropic film according to the embodiment of the present invention has excellent adhesiveness and exhibits a high alignment degree.

The polymerizable boronic acid compound is a compound containing a polymerizable group and at least one of a boronic acid group or a boronic acid ester group, as described below. It is assumed that the adhesiveness between the light absorption anisotropic film and other members is improved due to the interaction of these groups (the polymerizable group, the boronic acid group, and the boronic acid ester group) of the polymerizable boronic acid compound with other members.

Further, the polymerizable boronic acid compound is widely used as a vertical alignment agent that vertically aligns a liquid crystal compound. However, the reason for this is not clear, but in the present invention, it is considered that the polymerizable boronic acid compound does not sufficiently function as a vertical alignment agent and thus does not inhibit horizontal alignment of the liquid crystal compound. In this manner, a light absorption anisotropic film having a high alignment degree is assumed to be obtained.

### [Liquid Crystal Composition]

The liquid crystal composition used for forming the light absorption anisotropic film according to the embodiment of the present invention contains a liquid crystal compound, a dichroic substance, and a polymerizable boronic acid compound. The liquid crystal composition may contain a solvent, an interface improver, a polymerization initiator, and components other than the components described above as necessary.

Hereinafter, each component will be described.

### <Liquid Crystal Compound>

The liquid crystal composition contains a liquid crystal compound. In a case where the composition contains a liquid crystal compound, the dichroic substances can be aligned with a high alignment degree while the precipitation of the dichroic substances is suppressed.

As the liquid crystal compound, both a low-molecular-weight liquid crystal compound and a polymer liquid crystal compound can be used, but a polymer liquid crystal compound is more preferable from the viewpoint of obtaining a high alignment degree. Here, the “low-molecular-weight liquid crystal compound” indicates a liquid crystal compound having no repeating units in the chemical structure. Here, the “polymer liquid crystal compound” indicates a liquid crystal compound having a repeating unit in the chemical structure.

Examples of the low-molecular-weight liquid crystal compound include liquid crystal compounds described in JP2013-228706A.

Examples of the polymer liquid crystal compound include thermotropic liquid crystal polymers described in JP2011-237513A. Further, the polymer liquid crystal compound may contain a crosslinkable group (such as an acryloyl group or a methacryloyl group) at a terminal.

The liquid crystal compound may be used alone or in combination of two or more kinds thereof.

From the viewpoint that the alignment degree and the adhesiveness of the light absorption anisotropic film are more excellent, it is preferable that the liquid crystal compound includes a polymer liquid crystal compound.

From the viewpoint that the alignment degree of the dichroic substance (particularly, the dichroic azo coloring agent compound) is more excellent, it is preferable that the liquid crystal compound is a polymer liquid crystal compound having a repeating unit represented by Formula (3-1) (hereinafter, also referred to as “repeating unit (3-1)”).

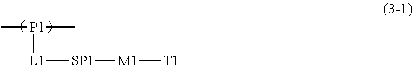

In Formula (3-1), P1 represents the main chain of the repeating unit, L1 represents a single bond or a divalent linking group, SP1 represents a spacer group, M1 represents a mesogen group, and T1 represents a terminal group.

Further, in the repeating unit (3-1), the difference between the log P value of P1, L1, and SP1 and the log P value of M1 is preferably 4 or greater. The difference is still more preferably 4.5 or greater. The repeating unit is in a state in which the compatibility between the mesogen group and the structure from the main chain to the spacer group is low because the log P value of the main chain, L1, and the spacer group and the log P value of the mesogen group are separated by a predetermined value or greater. In this manner, it is assumed that since the crystallinity of the polymer liquid crystal compound increases, the alignment degree of the polymer liquid crystal compound increases. As described above, it is assumed that in a case where the alignment degree of the polymer liquid crystal compound is high, the compatibility between the polymer liquid crystal compound and the organic dichroic substance (particularly, the dichroic azo coloring agent compound) is decreased (that is, the crystallinity of the dichroic azo coloring agent compound is improved), and the alignment degree of the dichroic azo coloring agent compound is improved. As a result, it is considered that the alignment degree of the light absorption anisotropic film to be obtained is increased.

Specific examples of the main chain of the repeating unit represented by P1 include groups represented by Formulae (P1-A) to (P1 -D). Among these, from the viewpoints of diversity and handleability of a monomer serving as a raw material, a group represented by Formula (P1-A) is preferable.

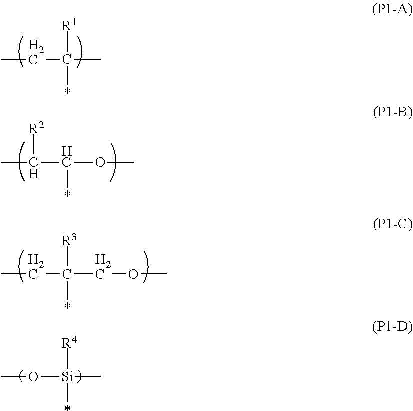

In Formulae (P1-A) to (P1-D), “*” represents a bonding position with respect to L1 in Formula (3-1).

In Formulae (P1-A) to (P1-D), R¹, R², R³, and R⁴ each independently represent a hydrogen atom, a halogen atom, a cyano group, an alkyl group having 1 to 10 carbon atoms, or an alkoxy group having 1 to 10 carbon atoms. The alkyl group may be a linear or branched alkyl group or an alkyl group having a cyclic structure (cycloalkyl group). Further, the number of carbon atoms of the alkyl group is preferably in a range of 1 to 5.

It is preferable that the group represented by Formula (P1-A) is a unit of a partial structure of poly(meth)acrylic acid ester obtained by polymerization of (meth)acrylic acid ester.

It is preferable that the group represented by Formula (P1-B) is an ethylene glycol unit formed by ring-opening polymerization of an epoxy group of a compound containing the epoxy group.

It is preferable that the group represented by Formula (P1-C) is a propylene glycol unit formed by ring-opening polymerization of an oxetane group of a compound containing the oxetane group.

It is preferable that the group represented by Formula (P1-D) is a siloxane unit of a polysiloxane obtained by polycondensation of a compound containing at least one of an alkoxysilyl group or a silanol group. Here, examples of the compound containing at least one of an alkoxysilyl group or a silanol group include a compound containing a group represented by Formula SiR¹⁴(OR¹⁵)₂—. In the formula, R¹⁴ has the same definition as that for R¹⁴ in Formula (P1-D), and a plurality of R¹⁵'s each independently represent a hydrogen atom or an alkyl group having 1 to 10 carbon atoms.

L1 represents a single bond or a divalent linking group.

Examples of the divalent linking group represented by L1 include —C(O)O—, —OC(O)—, —O—, —S—, —C(O)NR³—, —NR³C(O)—, —SO₂—, and —NR³R⁴—. In the formulae, R³ and R⁴ each independently represent a hydrogen atom or an alkyl group having 1 to 6 carbon atoms which may have a substituent (described below).

In a case where P1 represents a group represented by Formula (P1-A), from the viewpoint that the alignment degree of the light absorption anisotropic film is more excellent, it is preferable that L1 represents a group represented by —C(O)O—.

In a case where P1 represents a group represented by any of Formulae (P1-B) to (P1-D), from the viewpoint that the alignment degree of the light absorption anisotropic film is more excellent, it is preferable that L1 represents a single bond.

From the viewpoints of easily exhibiting liquid crystallinity and the availability of raw materials, it is preferable that the spacer group represented by SP1 has at least one structure selected from the group consisting of an oxyethylene structure, an oxypropylene structure, a polysiloxane structure, and an alkylene fluoride structure.

Here, as the oxyethylene structure represented by SP1, a group represented by *—(CH₂—CH₂O)ₙ₁—* is preferable. In the formula, n1 represents an integer of 1 to 20, and * represents a bonding position with respect to L1or M1 in Formula (3-1). From the viewpoint that the alignment degree of the light absorption anisotropic film is more excellent, n1 represents preferably an integer of 2 to 10, more preferably an integer of 2 to 4, and most preferably 3.

Further, from the viewpoint that the alignment degree of the light absorption anisotropic film is more excellent, a group represented by *—(CH(CH₃)—CH₂O)ₙ₂—* is preferable as the oxypropylene structure represented by SP1. In the formula, n2 represents an integer of 1 to 3, and “*” represents a bonding position with respect to L1 or M1.

Further, from the viewpoint that the alignment degree of the light absorption anisotropic film is more excellent, a group represented by *—(Si(CH₃)₂O)ₙ₃—* is preferable as the polysiloxane structure represented by SP1. In the formula, n3 represents an integer of 6 to 10, and “*” represents a bonding position with respect to L1 or M1.

Further, from the viewpoint that the alignment degree of the light absorption anisotropic film is more excellent, a group represented by *—(CF₂—CF₂)ₙ₄—* is preferable as the alkylene fluoride structure represented by SP1. In the formula, n4 represents an integer of 6 to 10, and “*” represents a bonding position with respect to L1 or M1.

The mesogen group represented by M1 is a group showing a main skeleton of a liquid crystal molecule that contributes to liquid crystal formation. A liquid crystal molecule exhibits liquid crystallinity which is in an intermediate state (mesophase) between a crystal state and an isotropic liquid state. The mesogen group is not particularly limited, and for example, particularly description on pages 7 to 16 of “Flussige Kristalle in Tabellen II” (VEB Deutsche Verlag fur Grundstoff Industrie, Leipzig, 1984) and particularly the description in Chapter 3 of “Liquid Crystal Handbook” (Maruzen, 2000) edited by Liquid Crystal Handbook Editing Committee can be referred to.

As the mesogen group, for example, a group having at least one cyclic structure selected from the group consisting of an aromatic hydrocarbon group, a heterocyclic group, and an alicyclic group is preferable.

From the viewpoint that the alignment degree of the light absorption anisotropic film is more excellent, the mesogen group contains preferably an aromatic hydrocarbon group, more preferably two to four aromatic hydrocarbon groups, and still more preferably three aromatic hydrocarbon groups.

From the viewpoints of exhibiting the liquid crystallinity, adjusting the liquid crystal phase transition temperature, and the availability of raw materials and synthetic suitability and from the viewpoint that the alignment degree of the light absorption anisotropic film is more excellent, a group represented by Formula (M1-A) or Formula (M1-B) is preferable, and a group represented by Formula (M1-B) is more preferable as the mesogen group.

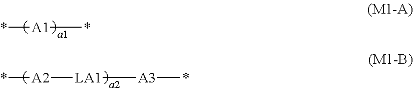

In Formula (M1-A), A1 represents a divalent group selected from the group consisting of an aromatic hydrocarbon group, a heterocyclic group, and an alicyclic group. These groups may be substituted with an alkyl group, a fluorinated alkyl group, an alkoxy group, or a substituent.

It is preferable that the divalent group represented by A1 is a 4- to 6-membered ring. Further, the divalent group represented by A1 may be a monocycle or a fused ring.

Further, “*” represents a bonding position with respect to SP1 or T1.

Examples of the divalent aromatic hydrocarbon group represented by A1 include a phenylene group, a naphthylene group, a fluorene-diyl group, an anthracene-diyl group, and a tetracene-diyl group. From the viewpoints of design diversity of a mesogenic skeleton and the availability of raw materials, a phenylene group or a naphthylene group is preferable, and a phenylene group is more preferable.

The divalent heterocyclic group represented by A1 may be any of aromatic or non-aromatic, but a divalent aromatic heterocyclic group is preferable as the divalent heterocyclic group from the viewpoint of further improving the alignment degree.

The atoms other than carbon constituting the divalent aromatic heterocyclic group include a nitrogen atom, a sulfur atom, and an oxygen atom. In a case where the aromatic heterocyclic group has a plurality of atoms constituting a ring other than carbon, these may be the same as or different from each other.

Specific examples of the divalent aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

Specific examples of the divalent alicyclic group represented by A1 include a cyclopentylene group and a cyclohexylene group.

In Formula (M1-A), a1 represents an integer of 1 to 10. In a case where a1 represents 2 or greater, a plurality of A1's may be the same as or different from each other.

In Formula (M1-B), A2 and A3 each independently represent a divalent group selected from the group consisting of an aromatic hydrocarbon group, a heterocyclic group, and an alicyclic group. Specific examples and preferred embodiments of A2 and A3 are the same as those for A1 in Formula (M1-A), and thus description thereof will not be repeated.

In Formula (M1-B), a2 represents an integer of 1 to 10. In a case where a2 represents 2 or greater, a plurality of A2′s may be the same as or different from each other, a plurality of A3's may be the same as or different from each other, and a plurality of LA1's may be the same as or different from each other. From the viewpoint that the alignment degree of the light absorption anisotropic film is more excellent, a2 represents preferably an integer of 2 or greater and more preferably 2.

In Formula (M1-B), in a case where a2 represents 1, LA1 represents a divalent linking group. In a case where a2 represents 2 or greater, a plurality of LA1's each independently represent a single bond or a divalent linking group, and at least one of the plurality of LA1's is a divalent linking group. In a case where a2 represents 2, from the viewpoint that the alignment degree of the light absorption anisotropic film is more excellent, it is preferable that one of the two LA1's represents a divalent linking group and the other represents a single bond.

In Formula (M1-B), examples of the divalent linking group represented by LA1 include —O—, —(CH₂)_{g}—, —(CF₂)_{g}—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)═N—N═C(Z′)— (Z, Z′, and Z″ each independently represent a hydrogen atom, an alkyl group having 1 to 4 carbon atoms, a cycloalkyl group, an aryl group, a cyano group, or a halogen atom), —C≡C, N═N—, —S—, —S(O)—, —S(O)(O)—, —(O)S(O)O—, —O(O)S(O)O—, —SC(O)—, and —C(O)S—.

Among these, from the viewpoint that the alignment degree of the light absorption anisotropic film is more excellent, —C(O)O— is preferable.

LA1 may represent a group obtained by combining two or more of these groups.

Specific examples of M1 include the following structures. In the following specific example, “Ac” represents an acetyl group.

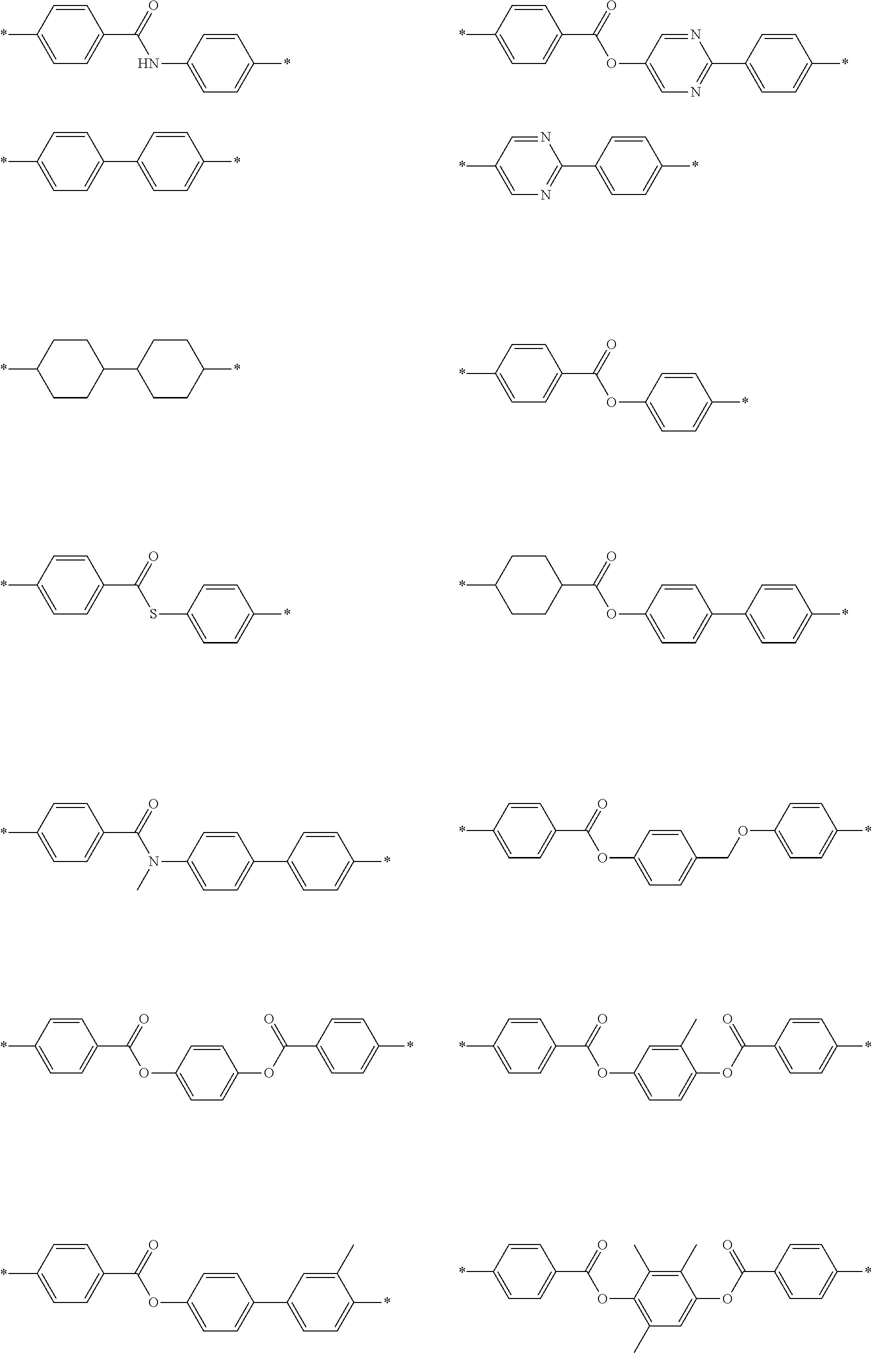

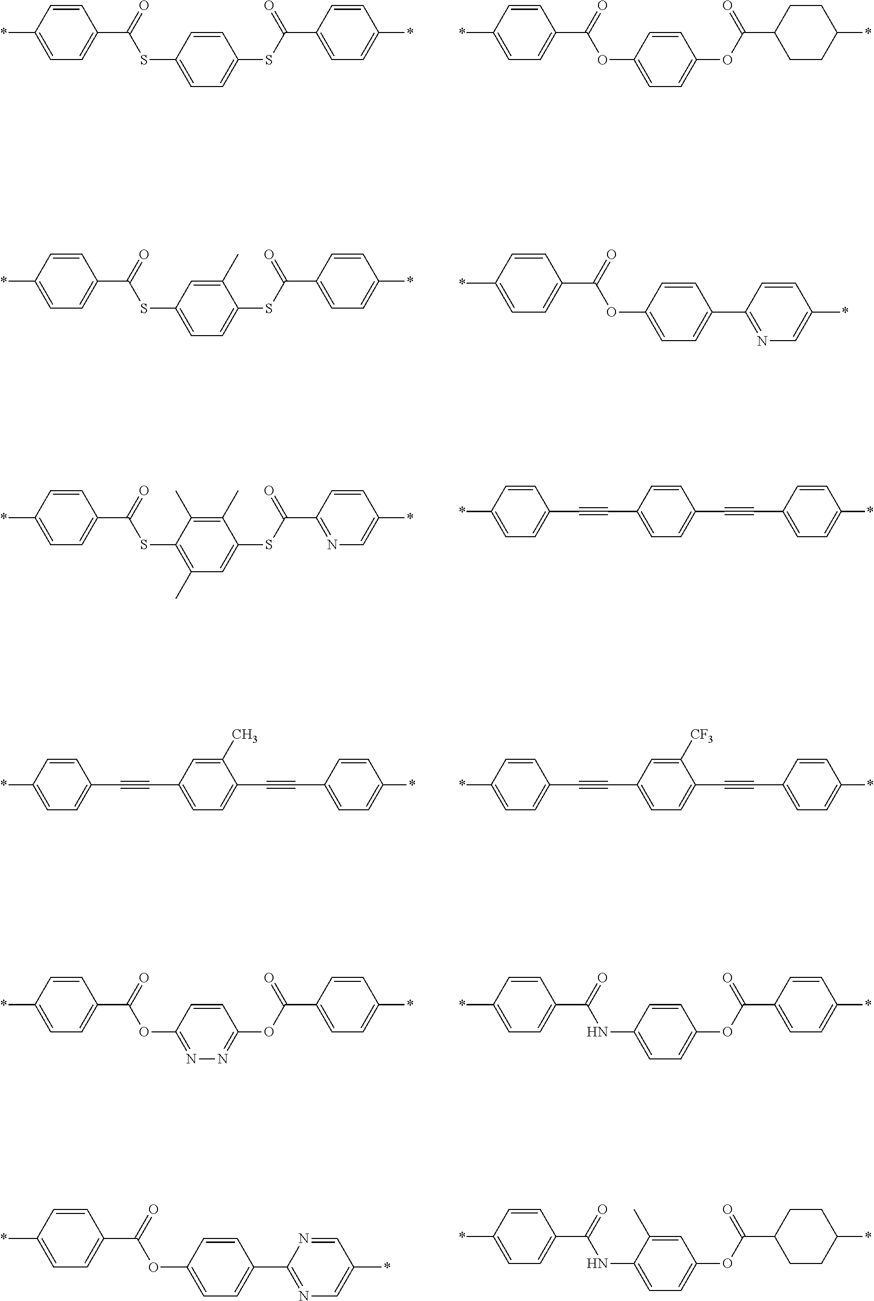

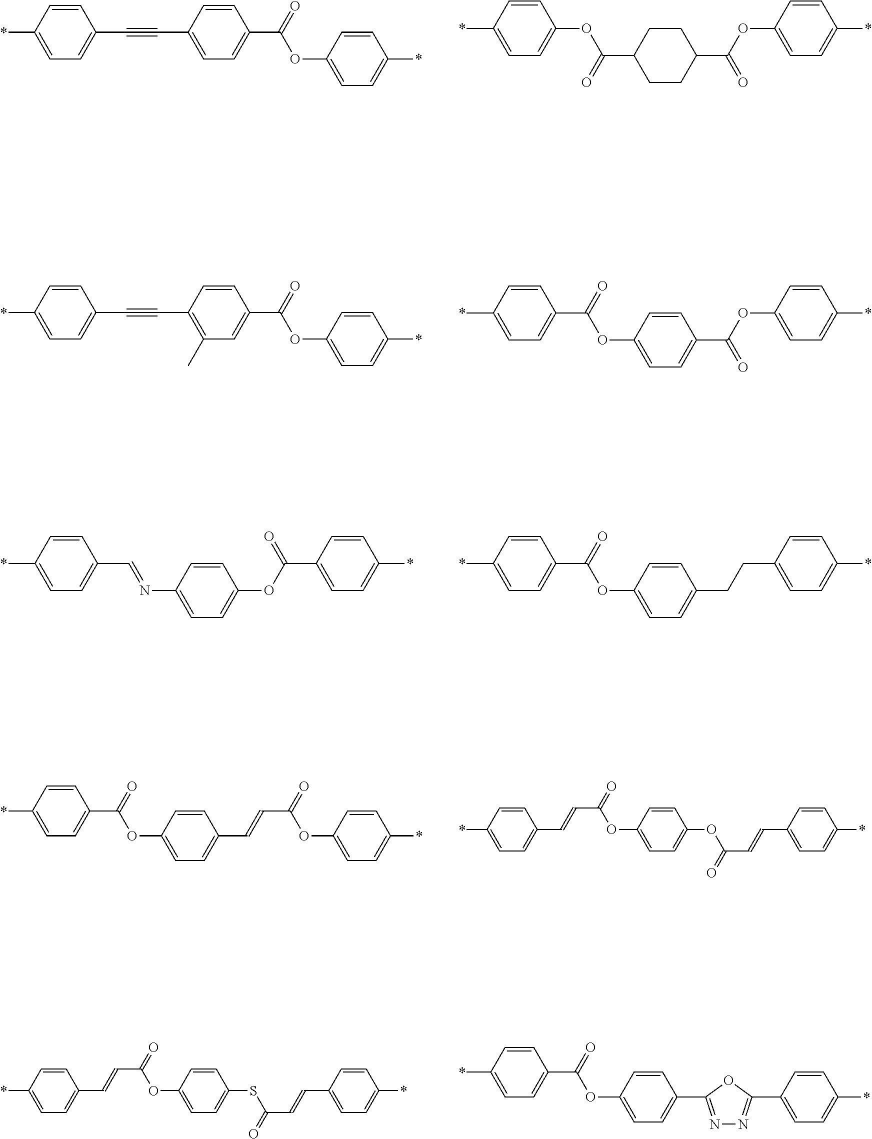

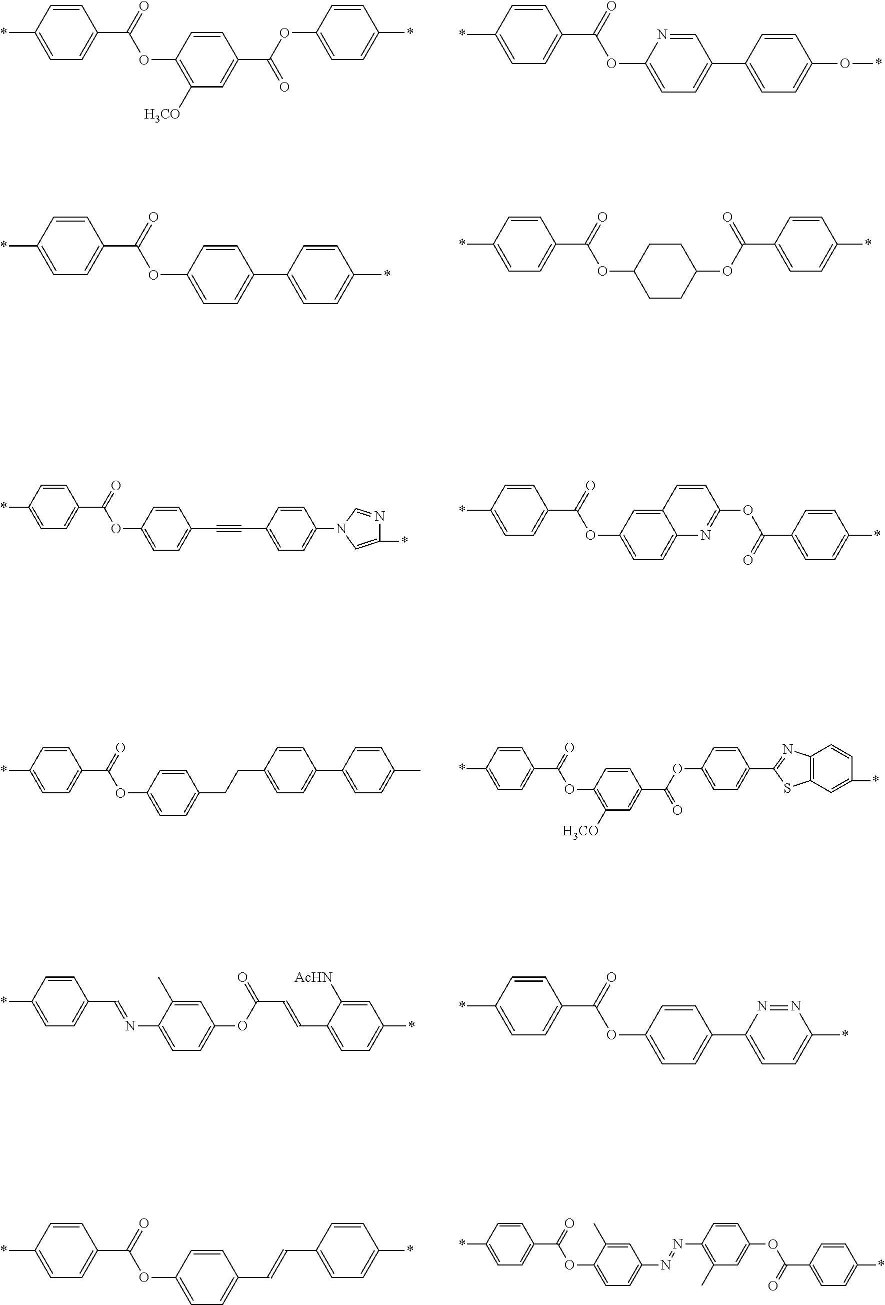

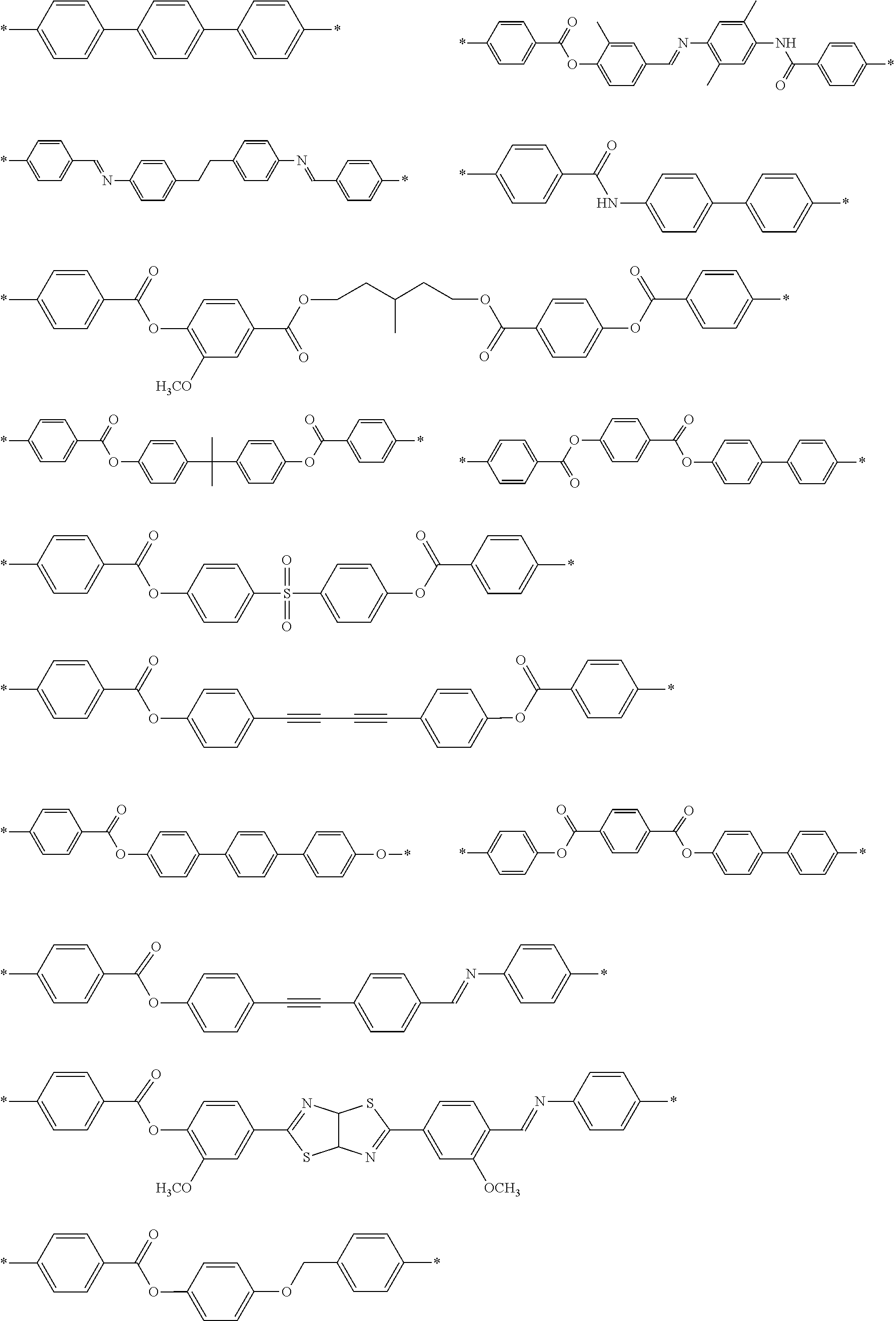

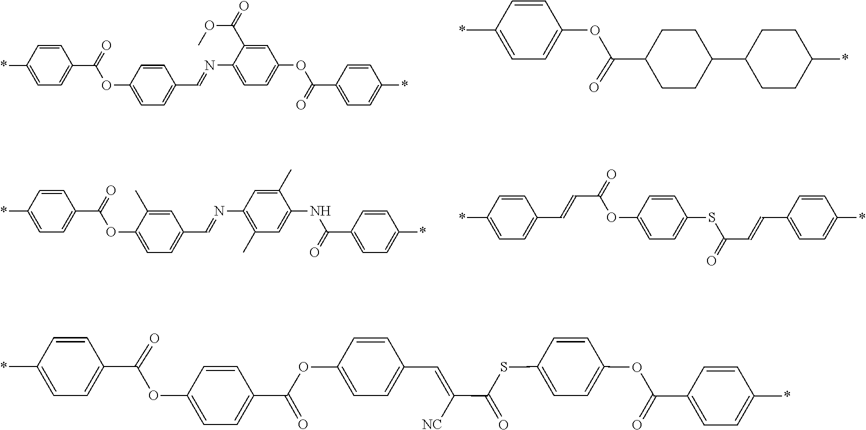 [SMILES: *c1ccc(C(=O)Oc2ccc(/C=N/c3ccc(OC(=O)c4ccc(*)cc4)cc3C(=O)OC)cc2)cc1 ; *c1ccc(OC(=O)C2CCC(C3CCC(*)CC3)CC2)cc1 ; *c1ccc(C(=O)Nc2cc(C)c(/N=C/c3ccc(OC(=O)c4ccc(*)cc4)c(C)c3)cc2C)cc1 ; *c1ccc(/C=C/C(=O)Oc2ccc(SC(=O)/C=C/c3ccc(*)cc3)cc2)cc1 ; *c1ccc(C(=O)Oc2ccc(SC(=O)/C(C#N)=C/c3ccc(OC(=O)c4ccc(OC(=O)c5ccc(*)cc5)cc4)cc3)cc2)cc1]

Examples of the terminal group represented by T1 include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group having 1 to 10 carbon atoms (ROC(O)—: R represents an alkyl group), an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureido group having 1 to 10 carbon atoms, and a (meth)acryloyloxy group-containing group. Examples of the (meth)acryloyloxy group-containing group include a group represented by -L-A (L represents a single bond or a linking group, specific examples of the linking group are the same as those for L1 and SP1 described above, and A represents a (meth)acryloyloxy group).

From the viewpoint that the alignment degree of the light absorption anisotropic film is more excellent, T1 represents preferably an alkoxy group having 1 to 10 carbon atoms, more preferably an alkoxy group having 1 to 5 carbon atoms, and still more preferably a methoxy group. These terminal groups may be further substituted with these groups or the polymerizable groups described in JP2010-244038A.

From the viewpoint that the alignment degree of the light absorption anisotropic film is more excellent, the number of atoms in the main chain of T1 is preferably in a range of 1 to more preferably in a range of 1 to 15, still more preferably in a range of 1 to 10, and particularly preferably in a range of 1 to 7. In a case where the number of atoms in the main chain of T1 is 20 or less, the alignment degree of the light absorption anisotropic film is further improved. Here, the “main chain” in T1 indicates the longest molecular chain bonded to M1, and the number of hydrogen atoms is not included in the number of atoms in the main chain of T1. For example, the number of atoms in the main chain is 4 in a case where T1 represents an n-butyl group, the number of atoms in the main chain is 3 in a case where T1 represents a sec-butyl group.

From the viewpoint that the alignment degree of the light absorption anisotropic film is more excellent, the content of the repeating unit (3-1) is preferably in a range of 20% to 100% by mass with respect to 100% by mass of all the repeating units of the polymer liquid crystal compound.

In the present invention, the content of each repeating unit contained in the polymer liquid crystal compound is calculated based on the charged amount (mass) of each monomer used for obtaining each repeating unit.

The polymer liquid crystal compound may have only one or two or more kinds of repeating units (3-1). In a case where the polymer liquid crystal compound has two or more kinds of repeating units (3-1), there is an advantage in that the solubility of the polymer liquid crystal compound in a solvent is improved and the liquid crystal phase transition temperature is easily adjusted. In a case where the polymer liquid crystal compound has two or more kinds of repeating units (3-1), it is preferable that the total amount thereof is in the above-described range.

In a case where the polymer liquid crystal compound has two kinds of the repeating units (3-1), from the viewpoint that the alignment degree of the light absorption anisotropic film is more excellent, it is preferable that the terminal group represented by T1 in one unit (repeating unit A) is an alkoxy group and the terminal group represented by T1 in the other unit (repeating unit B) is a group other than the alkoxy group.

From the viewpoint that the alignment degree of the light absorption anisotropic film is more excellent, as the terminal group represented by T1 in the repeating unit B, an alkoxycarbonyl group, a cyano group, or a (meth)acryloyloxy group-containing group is preferable, and an alkoxycarbonyl group or a cyano group is more preferable.

From the viewpoint that the alignment degree of the light absorption anisotropic film is more excellent, the ratio (AB) of the content of the repeating unit A in the polymer liquid crystal compound to the content of the repeating unit B in the polymer liquid crystal compound is preferably in a range of 50/50 to 95/5, more preferably in a range of 60/40 to 93/7, and still more preferably in a range of 70/30 to 90/10.

<Repeating unit (3-2)>

The polymer liquid crystal compound of the present invention may further have a repeating unit represented by Formula (3-2) (in the present specification, also referred to as “repeating unit (3-2)”). This provides advantages such as improvement of the solubility of the polymer liquid crystal compound in a solvent and ease of adjustment of the liquid crystal phase transition temperature.

The repeating unit (3-2) is different from the repeating unit (3-1) in terms that the repeating unit (3-2) does not contain at least a mesogen group.

In a case where the polymer liquid crystal compound has the repeating unit (3-2), the polymer liquid crystal compound is a copolymer of the repeating unit (3-1) and the repeating unit (3-2) (or may be a copolymer having repeating units A and B) and may be any polymer such as a block polymer, an alternating polymer, a random polymer, or a graft polymer.

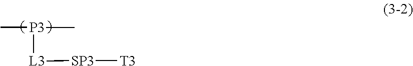

In Formula (3-2), P3 represents the main chain of the repeating unit, L3 represents a single bond or a divalent linking group, SP3 represents a spacer group, and T3 represents a terminal group.

Specific examples of P3, L3, SP3, and T3 in Formula (3-2) are the same as those for P1, L1, SP1, and T1 in Formula (3-1).

Here, from the viewpoint of improving the strength of the light absorption anisotropic film, it is preferable that T3 in Formula (3-2) contains a polymerizable group.

The content of the repeating unit (3-2) is preferably in a range of 0.5% to 40% by mass and more preferably in a range of 1% to 30% by mass with respect to 100% by mass of all the repeating units of the polymer liquid crystal compound.

The polymer liquid crystal compound may have only one or two or more kinds of repeating units (3-2). In a case where the polymer liquid crystal compound has two or more kinds of repeating units (3-2), it is preferable that the total amount thereof is in the above-described ranges.

### (Weight-Average Molecular Weight)

From the viewpoint that the alignment degree of the light absorption anisotropic film is more excellent, the weight-average molecular weight (Mw) of the polymer liquid crystal compound is preferably in a range of 1000 to 500000 and more preferably in a range of 2000 to 300000. In a case where the Mw of the polymer liquid crystal compound is in the above-described range, the polymer liquid crystal compound is easily handled.

In particular, from the viewpoint of suppressing cracking during the coating, the weight-average molecular weight (Mw) of the polymer liquid crystal compound is preferably 10000 or greater and more preferably in a range of 10000 to 300000.

In addition, from the viewpoint of the temperature latitude of the alignment degree, the weight-average molecular weight (Mw) of the polymer liquid crystal compound is preferably less than 10000 and more preferably 2000 or greater and less than 10000.

Here, the weight-average molecular weight and the number average molecular weight in the present invention are values measured by the gel permeation chromatography (GPC) method.
Solvent (eluent): N-methylpyrrolidone
Device name: TOSOH HLC-8220GPC
Column: Connect and use three of TOSOH TSKgel Super AWM-H (6 mm×15 cm)
Column temperature: 25° C.
Sample concentration: 0.1% by mass
Flow rate: 0.35 mL/min
Calibration curve: TSK standard polystyrene (manufactured by TOSOH Corporation), calibration curves of 7 samples with Mw of 2800000 to 1050 (Mw/Mn=1.03 to 1.06) are used. (Content of liquid crystal compound)

The content of the liquid crystal compound is preferably in a range of 10% to 97% by mass, more preferably in a range of 40% to 95% by mass, and particularly preferably in a range of 60% to 95% by mass with respect to the total mass of the solid content of the liquid crystal composition. In a case where the content of the liquid crystal compound is in the above-described ranges, the alignment degree of the light absorption anisotropic film is further improved.

It is preferable that the content of the liquid crystal compound in the light absorption anisotropic film with respect to the total mass of the light absorption anisotropic film is the same as the content of the liquid crystal compound with respect to the total mass of the solid content of the liquid crystal composition described above.

### <Dichroic Substance>

The dichroic substance contained in the liquid crystal composition is not particularly limited.

A dichroic azo coloring agent compound is preferable as the dichroic substance, and a dichroic azo coloring agent compound typically used for a so-called coating type polarizer can be used. The dichroic azo coloring agent compound is not particularly limited, and known dichroic azo coloring agents of the related art can be used, but the compounds described below are preferably used.

The dichroic substance may be polymerized in the light absorption anisotropic film.

In the present invention, the dichroic azo coloring agent compound denotes a coloring agent having different absorbances depending on the direction.

The dichroic azo coloring agent compound may or may not exhibit liquid crystallinity.

In a case where the dichroic azo coloring agent compound exhibits liquid crystallinity, the dichroic azo coloring agent compound may exhibit any of nematic liquid crystallinity or smectic liquid crystallinity. The temperature at which the liquid crystal phase is exhibited is preferably in a range of room temperature (approximately 20° C. to 28° C.) to 300° C. and from the viewpoints of handleability and manufacturing suitability, more preferably in a range of 50° C. to 200° C.

In the present invention, from the viewpoint of adjusting the tint, the light absorption anisotropic film contains preferably at least one coloring agent compound having a maximal absorption wavelength in a wavelength range of 560 to 700 nm (hereinafter, also referred to as “first dichroic azo coloring agent compound”) and at least one coloring agent compound having a maximal absorption wavelength in a wavelength range of 455 nm or greater and less than 560 nm (hereinafter, also referred to as “second dichroic azo coloring agent compound”) and specifically more preferably at least a dichroic azo coloring agent compound represented by Formula (1) and a dichroic azo coloring agent compound represented by Formula (2).

In the present invention, three or more kinds of dichroic azo coloring agent compounds may be used in combination. For example, from the viewpoint of making the color of the light absorption anisotropic film close to black, it is preferable to use the first dichroic azo coloring agent compound, the second dichroic azo coloring agent compound, and at least one coloring agent compound having a maximal absorption wavelength in a wavelength range of 380 nm or greater and less than 455 nm (preferably in a wavelength range of 380 to 454 nm) (hereinafter, also referred to as “third dichroic azo coloring agent compound”) in combination.

In the present invention, from the viewpoint of further enhancing pressing resistance, it is preferable that the dichroic azo coloring agent compound contains a crosslinkable group.

Specific examples of the crosslinkable group include a (meth)acryloyl group, an epoxy group, an oxetanyl group, and a styryl group. Among these, a (meth)acryloyl group is preferable.

### (First Dichroic Azo Coloring Agent Compound)

It is preferable that the first dichroic azo coloring agent compound is a compound having a chromophore which is a nucleus and a side chain bonded to a terminal of the chromophore.

Specific examples of the chromophore include an aromatic ring group (such as an aromatic hydrocarbon group or an aromatic heterocyclic group) and an azo group. In addition, a structure containing both an aromatic ring group and an azo group is preferable, and a bisazo structure containing an aromatic heterocyclic group (preferably a thienothiazole group) and two azo groups is more preferable.

The side chain is not particularly limited, and examples thereof include a group represented by L3, R2, or L4 in Formula (1).

From the viewpoint adjusting the tint of the light absorption anisotropic film, it is preferable that the first dichroic azo coloring agent compound is a dichroic azo coloring agent compound having a maximum absorption wavelength in a wavelength range of 560 nm or greater and 700 nm or less (more preferably in a range of 560 to 650 nm and particularly preferably in a range of 560 to 640 nm).

The maximum absorption wavelength (nm) of the dichroic azo coloring agent compound in the present specification is acquired from an ultraviolet visible spectrum in a wavelength range of 380 to 800 nm measured by a spectrophotometer using a solution prepared by dissolving the dichroic azo coloring agent compound in a good solvent.

In the present invention, from the viewpoint of further improving the alignment degree of the light absorption anisotropic film to be formed, it is preferable that the first dichroic azo coloring agent compound is a compound represented by Formula (1).

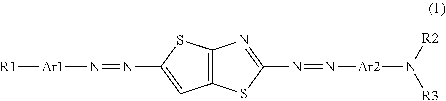

In Formula (1), Ar1 and Ar2 each independently represent a phenylene group which may have a substituent or a naphthylene group which may have a substituent. Among these, a phenylene group is preferable.

In Formula (1), R1 represents a hydrogen atom, a linear or branched alkyl group having 1 to 20 carbon atoms which may have a substituent, an alkoxy group, an alkylthio group, an alkylsulfonyl group, an alkylcarbonyl group, an alkyloxycarbonyl group, an acyloxy group, an alkylcarbonate group, an alkylamino group, an acylamino group, an alkylcarbonylamino group, an alkoxycarbonylamino group, an alkylsulfonylamino group, an alkylsulfamoyl group, an alkylcarbamoyl group, an alkylsulfinyl group, an alkylureido group, an alkylphosphoric acid amide group, an alkylimino group, or an alkylsilyl group.

Further, —CH₂— constituting the alkyl group may be substituted with —O—, —CO—, —C(O)—O—, —O—C(O)—, —Si(CH₃)₂—O—Si(CH₃)₂—, —N(R1′)—, —N(R1′)—CO—, —CO—N(R1′)—, —N(R1′)—C(O)—O—, —O—C(O)—N(R1′)—, —N(R1′)—C(O)—N(R1′)—, —CH═CH—, —N═N—, —C(R1′)═CH—C(O)—, or —O—C(O)—O—.

In a case where R1 represents a group other than a hydrogen atom, the hydrogen atom in each group may be substituted with a halogen atom, a nitro group, a cyano group, —N(R1′)₂, an amino group, —C(R1′)═C(R1′)—NO₂, —C(R1′)═C(R1′)—CN, or —C(R1′)═C(CN)₂.

R1′ represents a hydrogen atom or a linear or branched alkyl group having 1 to 6 carbon atoms. In a case where a plurality of (R1′)'s are present in each group, these may be the same as or different from one another.

In Formula (1), R2 and R3 each independently represent a hydrogen atom, a linear or branched alkyl group having 1 to 20 carbon atoms which may have a substituent, an alkoxy group, an acyl group, an alkyloxycarbonyl group, an alkylamide group, an alkylsulfonyl group, an aryl group, an arylcarbonyl group, an arylsulfonyl group, an aryloxycarbonyl group, or an arylamide group.

Further, —CH₂— constituting the alkyl group may be substituted with —O—, —S—, —C(O)—, —C(O)—O—, —O—C(O)—, —C(O)—S—, —S—C(O)—, —Si(CH₃)₂—O—Si(CH₃)₂—, —NR₂′—, —NR₂′—CO—, —CO—NR₂′—, —NR₂′—C(O)—O—, —O—C(O)—NR₂′—, —NR₂′—C(O)—NR₂′—, —CH═CH—, —N═N—, —C(R₂′)═CH—C(O)—, or —O—C(O)—O—.

In a case where R2 and R3 represent a group other than a hydrogen atom, the hydrogen atom of each group may be substituted with a halogen atom, a nitro group, a cyano group, a —OH group, —N(R2′)₂, an amino group, —C(R2′)═C(R2′)—NO₂, —C(R2′)═C(R2′)—CN, or —C(R2′)═C(CN)₂.

R2′ represents a hydrogen atom or a linear or branched alkyl group having 1 to 6 carbon atoms. In a case where a plurality of (R2′)'s are present in each group, these may be the same as or different from one another.

R2 and R3 may be bonded to each other to form a ring, or R2 or R3 may be bonded to Ar2 to form a ring.

From the viewpoint of the light fastness, it is preferable that R1 represents an electron-withdrawing group and R2 and R3 represent a group having a low electron-donating property.

Specific examples of such a group as R1 include an alkylsulfonyl group, an alkylcarbonyl group, an alkyloxycarbonyl group, an acyloxy group, an alkylsulfonylamino group, an alkylsulfamoyl group, an alkylsulfinyl group, and an alkylureido group, and examples of groups as R2 and R3 include groups having the following structures. Further, the groups having the following structures are shown in the form having a nitrogen atom to which R2 and R3 are bonded in Formula (1).

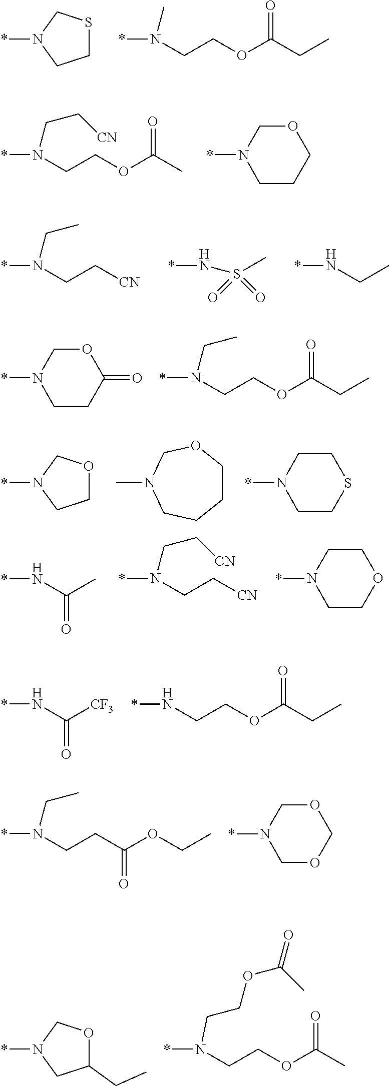

Specific examples of the first dichroic azo coloring agent compound are shown below, but the present invention is not limited thereto.

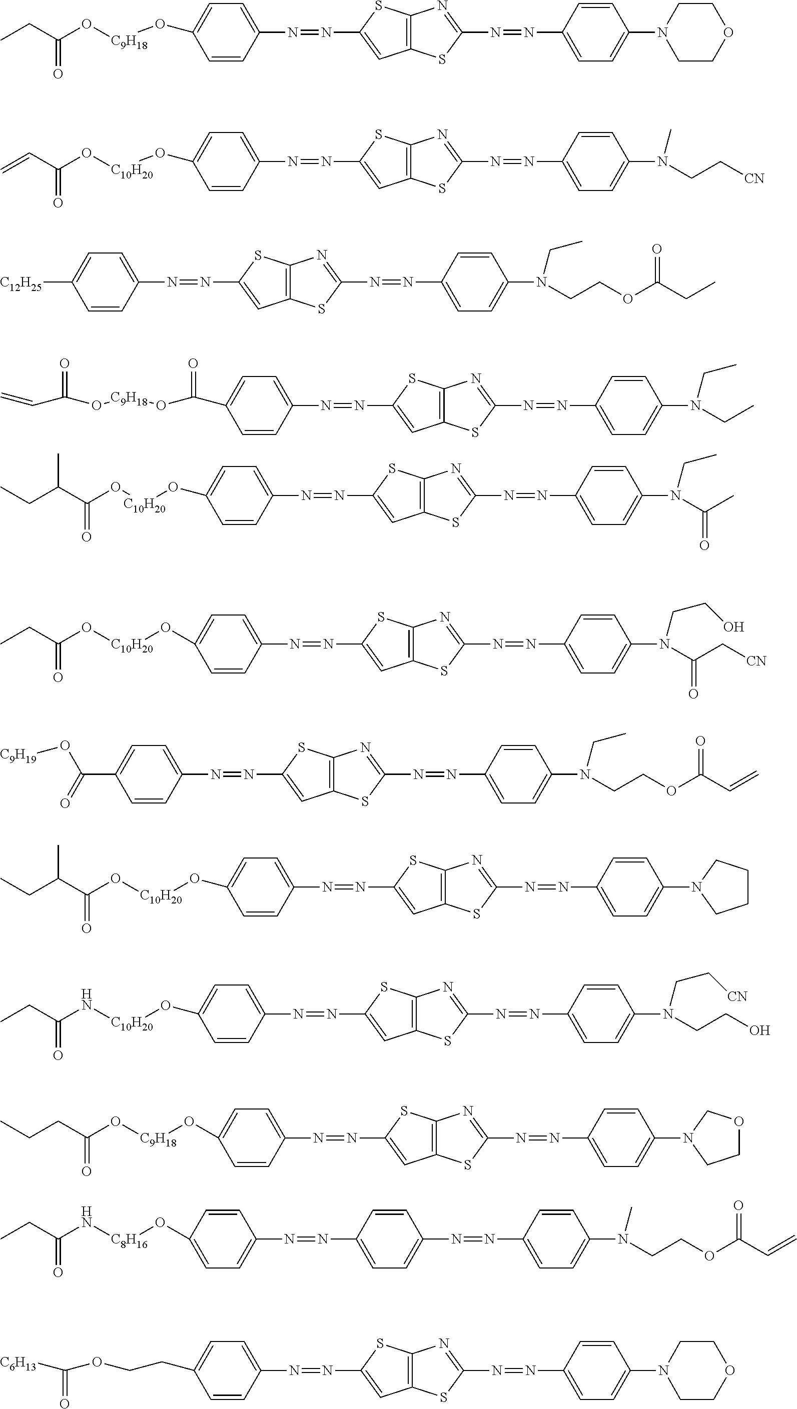

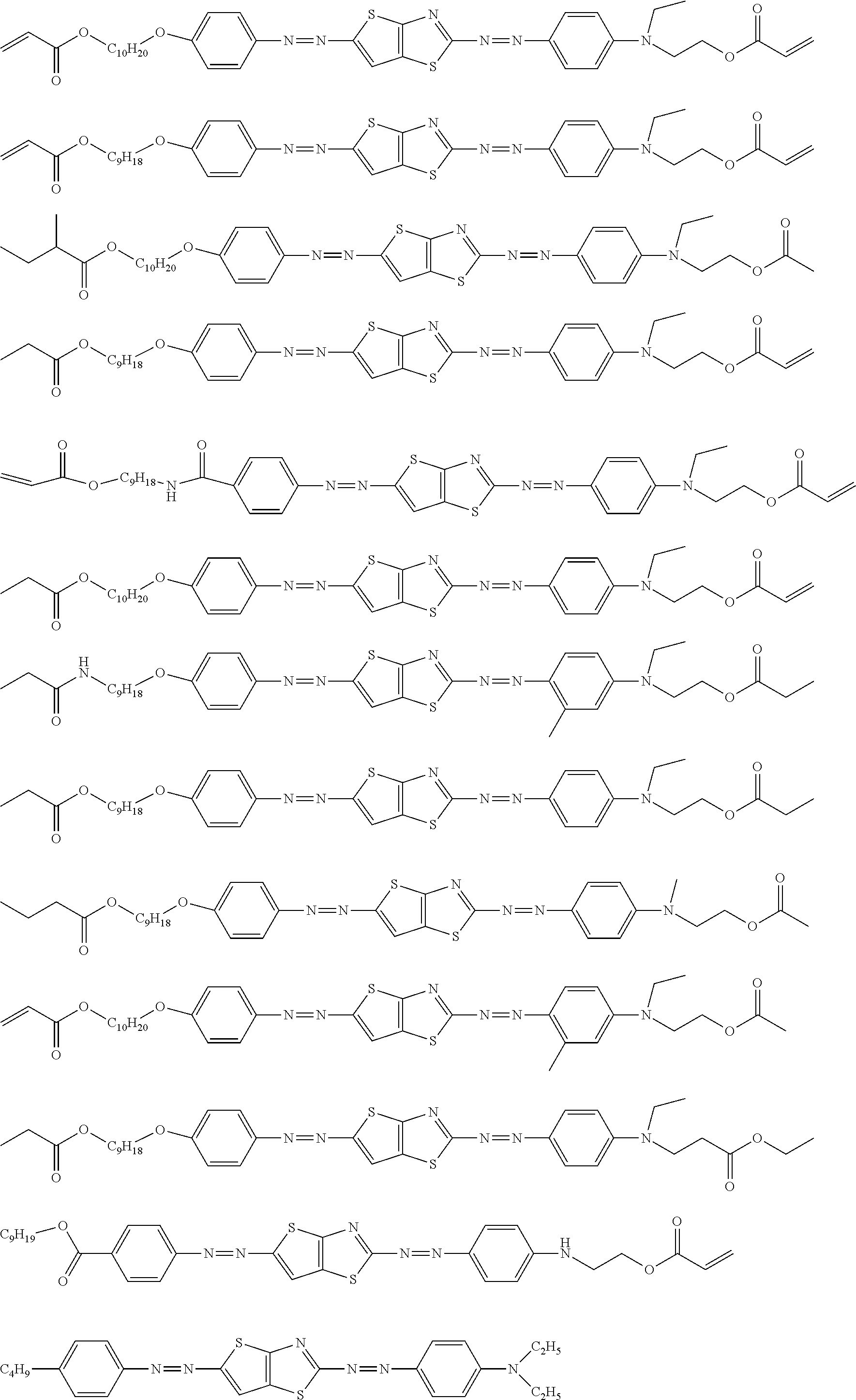

### (Second Dichroic Azo Coloring Agent Compound)

The second dichroic azo coloring agent compound is a compound different from the first dichroic azo coloring agent compound, and specifically, the chemical structure thereof is different from that of the first dichroic azo coloring agent compound.

It is preferable that the second dichroic azo coloring agent compound is a compound having a chromophore which is a nucleus of a dichroic azo coloring agent compound and a side chain bonded to a terminal of the chromophore.

Specific examples of the chromophore include an aromatic ring group (such as an aromatic hydrocarbon group or an aromatic heterocyclic group) and an azo group. In addition, a structure containing both an aromatic hydrocarbon group and an azo group is preferable, and a bisazo or trisazo structure containing an aromatic hydrocarbon group and two or three azo groups is more preferable.

The side chain is not particularly limited, and examples thereof include a group represented by R4, R5, or R6 in Formula (2).

The second dichroic azo coloring agent compound is a dichroic azo coloring agent compound having a maximum absorption wavelength in a wavelength range of 455 nm or greater and less than 560 nm, and from the viewpoint of adjusting the tint of the light absorption anisotropic film, preferably a dichroic azo coloring agent compound having a maximum absorption wavelength in a wavelength range of 455 to 555 nm and more preferably a dichroic azo coloring agent compound having a maximum absorption wavelength in a wavelength range of 455 to 550 nm.

In particular, the tint of the light absorption anisotropic film is easily adjusted by using a first dichroic azo coloring agent compound having a maximum absorption wavelength of 560 to 700 nm and a second dichroic azo coloring agent compound having a maximum absorption wavelength of 455 nm or greater and less than 560 nm.

From the viewpoint of further improving the alignment degree of the light absorption anisotropic film, it is preferable that the second dichroic azo coloring agent compound is a compound represented by Formula (2).

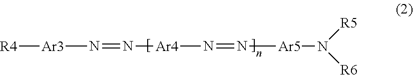

In Formula (2), n represents 1 or 2.

In Formula (2), Ar3, Ar4, and Ar5 each independently represent a phenylene group which may have a substituent, a naphthylene group which may have a substituent, or a heterocyclic group which may have a substituent.

The heterocyclic group may be aromatic or non-aromatic.

The atoms other than carbon constituting the aromatic heterocyclic group include a nitrogen atom, a sulfur atom, and an oxygen atom. In a case where the aromatic heterocyclic group has a plurality of atoms constituting a ring other than carbon, these may be the same as or different from each other.

Specific examples of the aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

In Formula (2), R4 has the same definition as that for R1 in Formula (1).

In Formula (2), R5 and R6 each have the same definition as that for R2 and R3 in Formula (1).

From the viewpoint of the light fastness, it is preferable that R4 represents an electron-withdrawing group and R5 and R6 represent a group having a low electron-donating property.

Among such groups, specific examples of a case where R4 represents an electron-withdrawing group are the same as the specific examples of a case where R1 represents an electron-withdrawing group, and specific examples of a case where R5 and R6 represent a group having a low electron-donating property are the same as the specific examples of a case where R2 and R3 represent a group having a low electron-donating property.

Specific examples of the second dichroic azo coloring agent compound are shown below, but the present invention is not limited thereto.

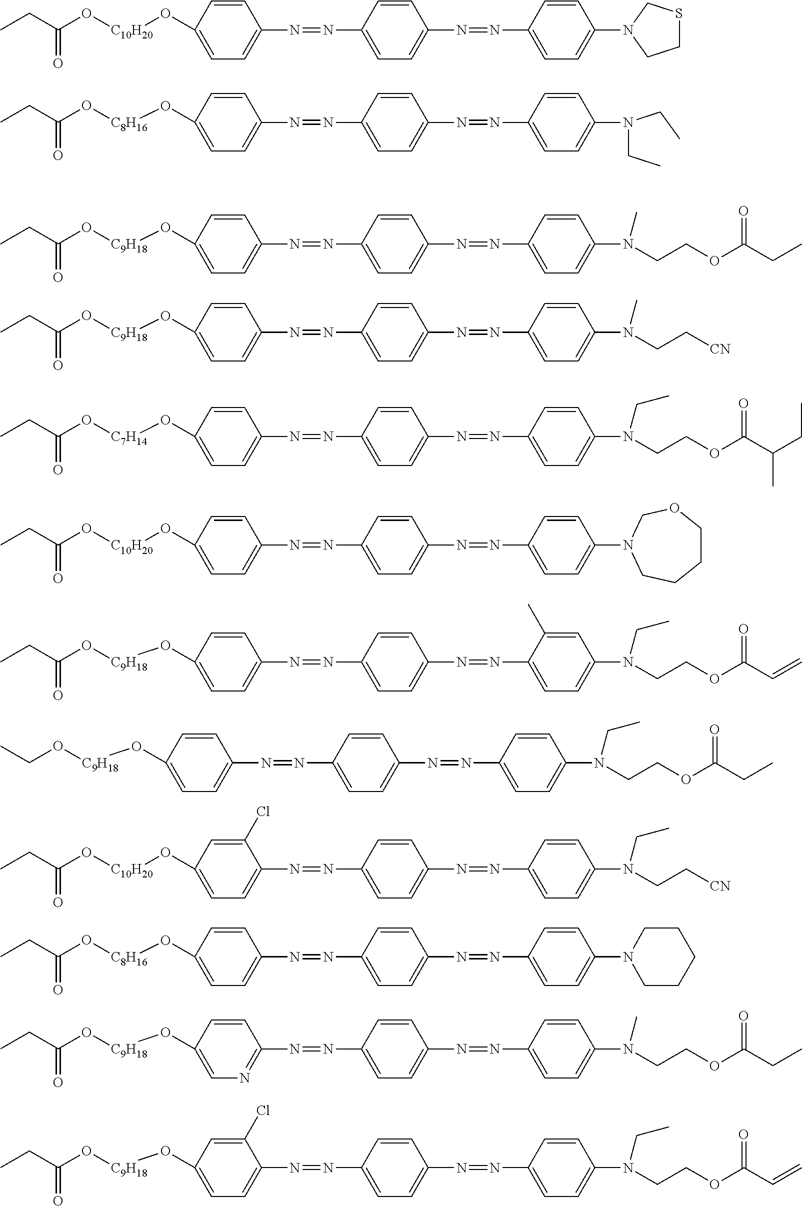

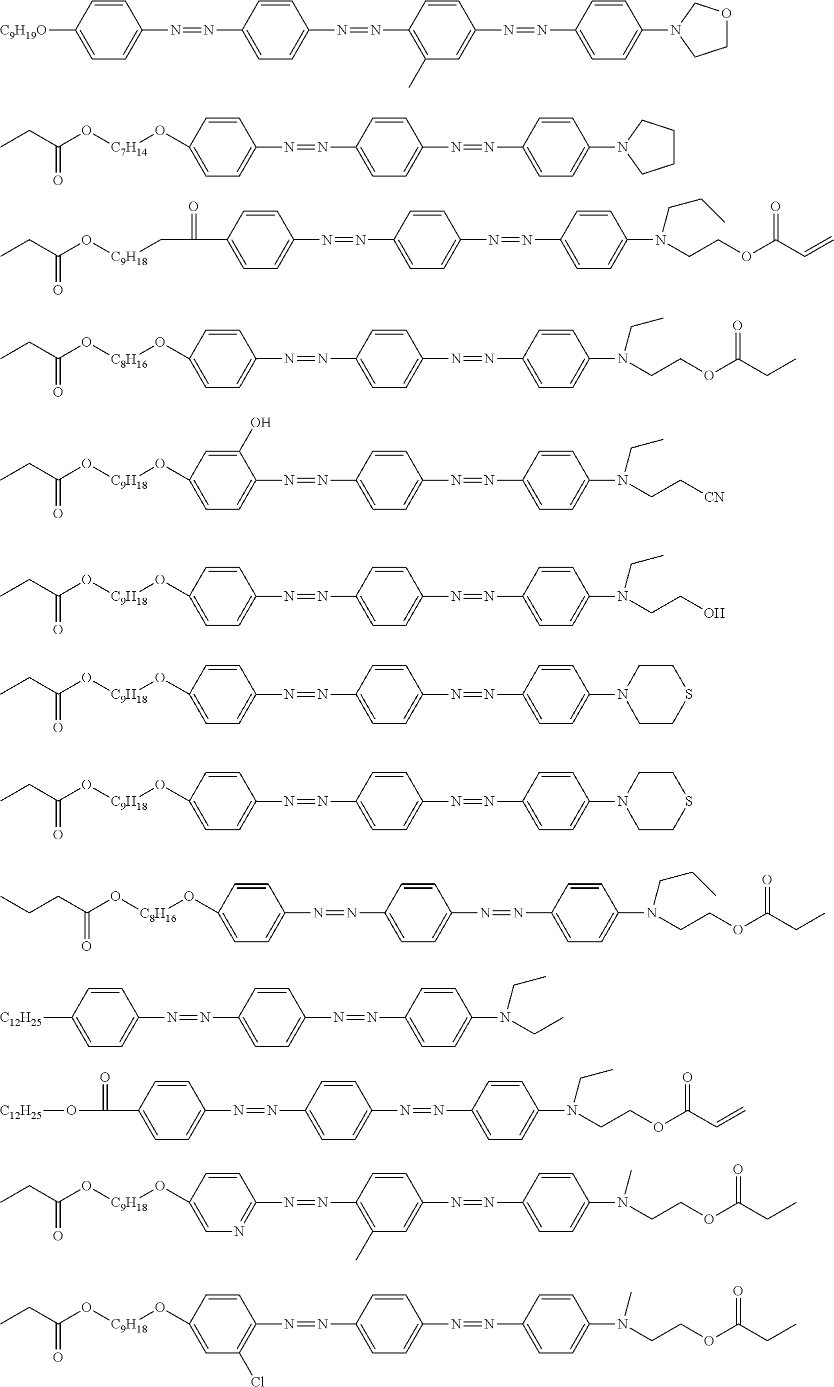

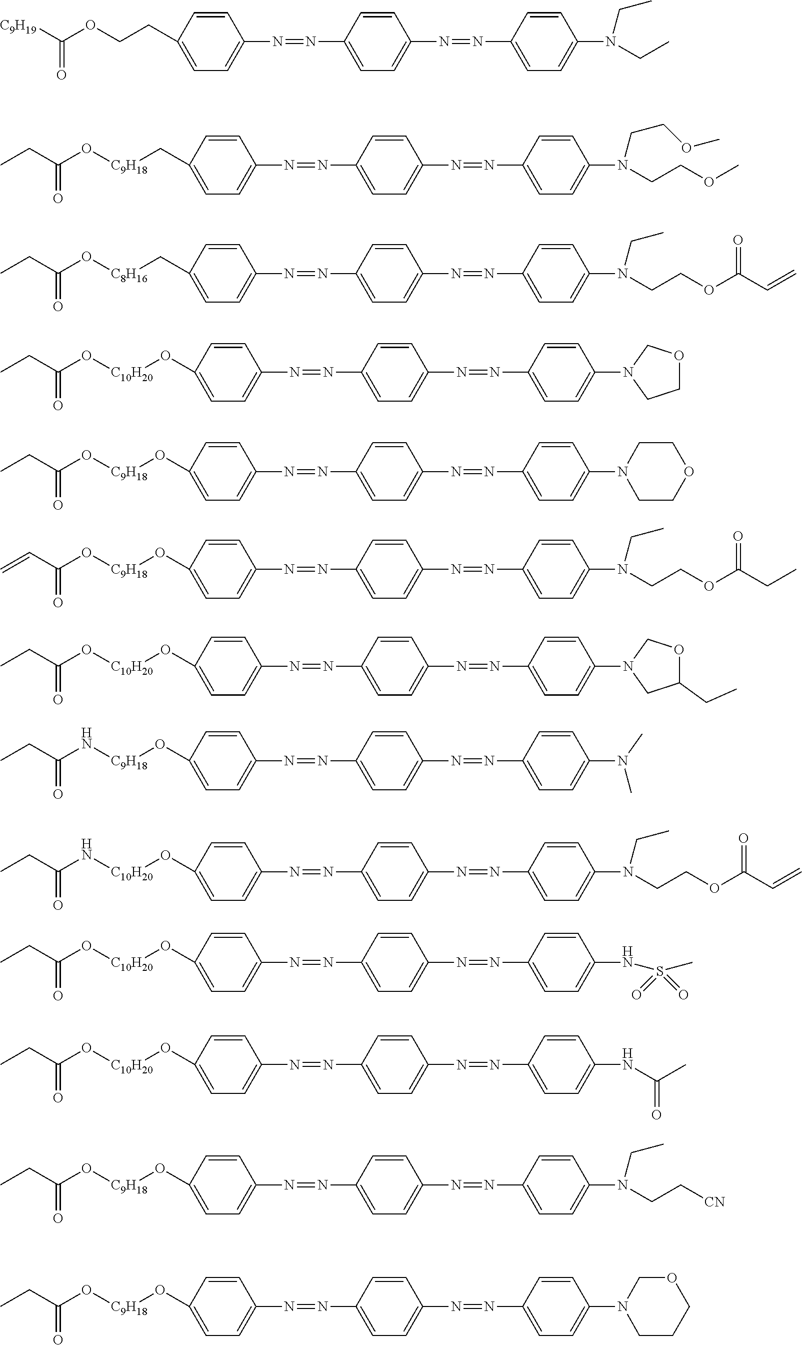

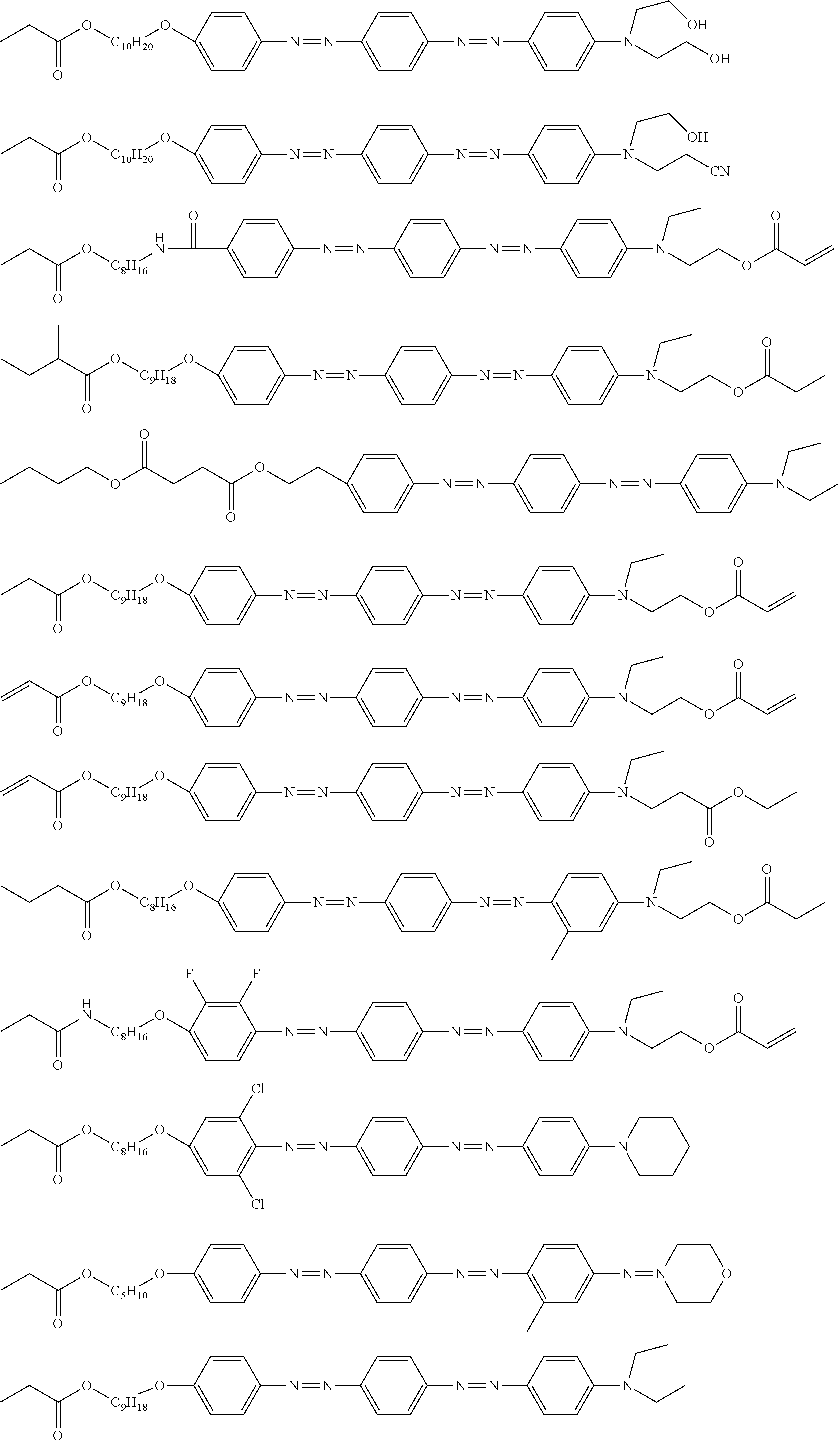

### (Difference in Log P Value)

The log P value is an index expressing the hydrophilicity and the hydrophobicity of a chemical structure. An absolute value of a difference (hereinafter, also referred to as “difference in log P value”) between the log P value of a side chain of the first dichroic azo coloring agent compound and the log P value of a side chain of the second dichroic azo coloring agent compound is preferably 2.30 or less, more preferably 2.0 or less, still more preferably 1.5 or less, and particularly preferably 1.0 or less. In a case where the difference in log P value is 2.30 or less, since the affinity between the first dichroic azo coloring agent compound and the second dichroic azo coloring agent compound is enhanced and an arrangement structure is more easily formed, the alignment degree of the light absorption anisotropic film is further improved.

Further, in a case where the first dichroic azo coloring agent compound or the second dichroic azo coloring agent compound has a plurality of side chains, it is preferable that at least one difference in log P value is in the above-described ranges.

Here, the side chain of the first dichroic azo coloring agent compound and the side chain of the second dichroic azo coloring agent compound denote a group bonded to the terminal of the above-described chromophore. For example, R1, R2, and R3 in Formula (1) represent a side chain in a case where the first dichroic azo coloring agent compound is a compound represented by Formula (1), and R4, R5, and R6 in Formula (2) represent a side chain in a case where the second dichroic azo coloring agent compound is a compound represented by Formula (2). In particularly, in a case where the first dichroic azo coloring agent compound is a compound represented by Formula (1) and the second dichroic azo coloring agent compound is a compound represented by Formula (2), it is preferable that at least one difference in log P value among the difference in log P value between R1 and R4, the difference in log P value between R1 and R5, the difference in log P value between R2 and R4, and the difference in log P value between R2 and R5 is in the above-described ranges.

Here, the log P value is an index for expressing the properties of the hydrophilicity and hydrophobicity of a chemical structure and is also referred to as a hydrophilic-hydrophobic parameter. The log P value can be calculated using software such as ChemBioDraw Ultra or HSPiP (Ver. 4.1.07). Further, the log P value can be acquired experimentally by the method of the OECD Guidelines for the Testing of Chemicals, Sections 1, Test No. 117 or the like. In the present invention, a value calculated by inputting the structural formula of a compound to HSPiP (Ver. 4.1.07) is employed as the log P value unless otherwise specified.

### (Third Dichroic Azo Coloring Agent Compound)

The third dichroic azo coloring agent compound is a dichroic azo coloring agent compound other than the first dichroic azo coloring agent compound and the second dichroic azo coloring agent compound, and specifically, the chemical structure thereof is different from those of the first dichroic azo coloring agent compound and the second dichroic azo coloring agent compound. In a case where the light absorption anisotropic film contains the third dichroic azo coloring agent compound, there is an advantage that the tint of the light absorption anisotropic film is easily adjusted.

The maximum absorption wavelength of the third dichroic azo coloring agent compound is 380 nm or greater and less than 455 nm and preferably in a range of 385 to 454 nm.

Specific examples of the third dichroic azo coloring agent compound include compounds represented by Formula (1) described in WO2017/195833A. Among the compounds, compounds other than the first dichroic azo coloring agent compound and the second dichroic azo coloring agent compound may be exemplified.

Specific examples of the third dichroic azo coloring agent compound are shown below, but the present invention is not limited thereto. In the following specific examples, n represents an integer of 1 to 10. Further, Me represents a methyl group.

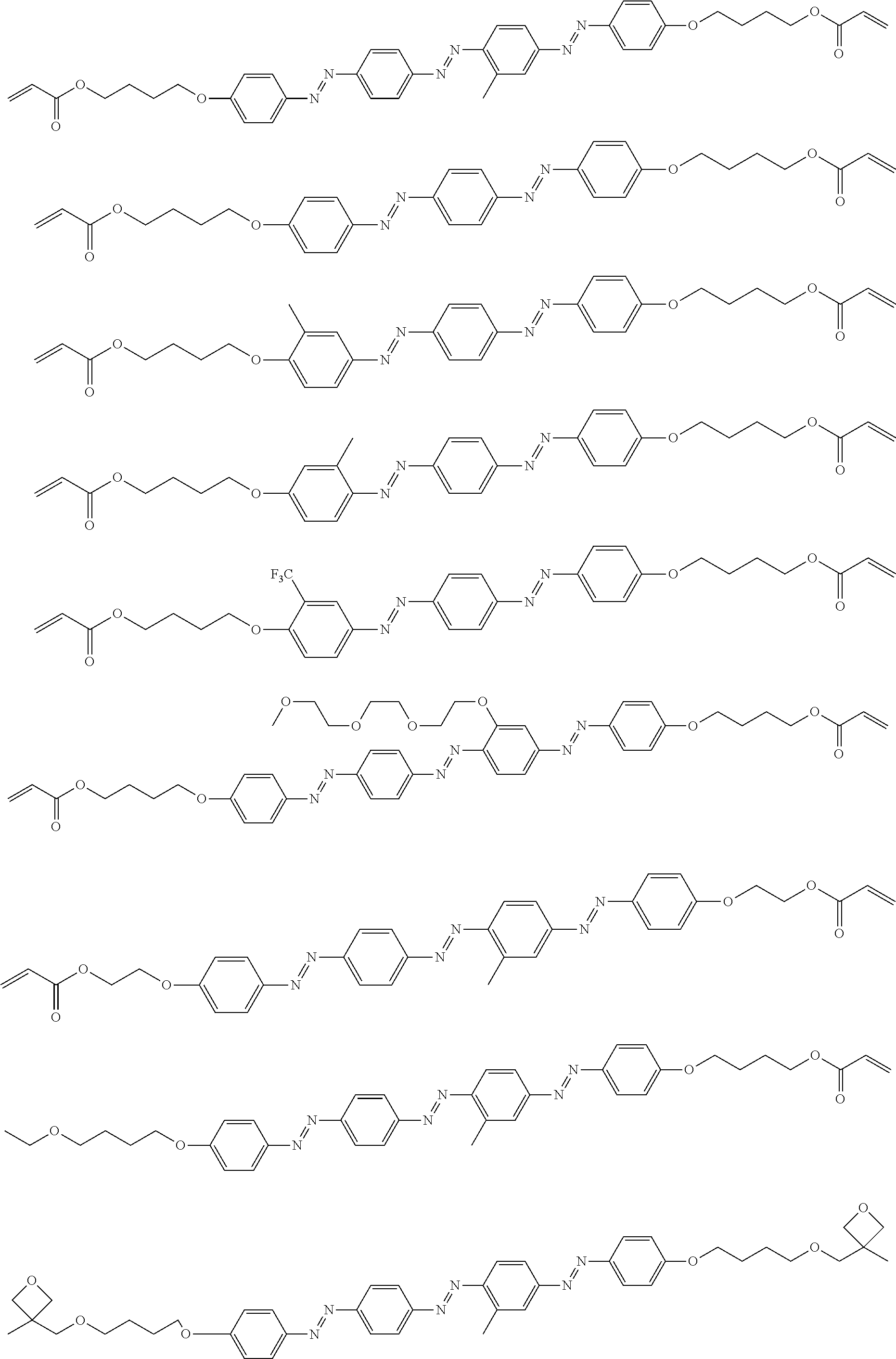

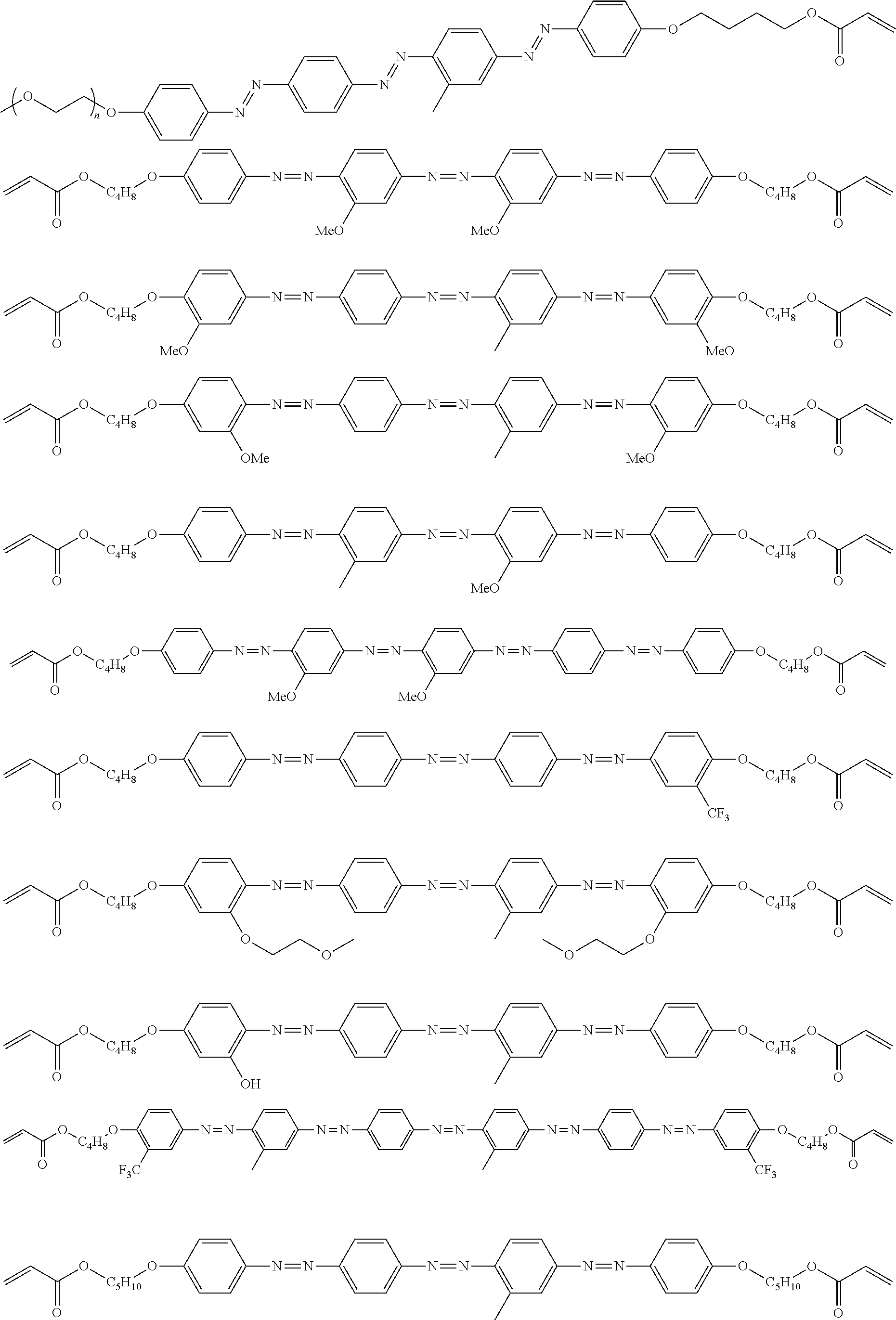

### (Content of Dichroic Substance)

The content of the dichroic substance is preferably in a range of 1% to 70% by mass, more preferably in a range of 2% to 60% by mass, and particularly preferably in a range of 3% to 50% by mass with respect to the total mass of the solid content of the liquid crystal composition. In a case where the content of the dichroic substance is in the above-described range, a light absorption anisotropic film having a high alignment degree can be obtained even in a case where the light absorption anisotropic film is formed into a thin film. Therefore, a light absorption anisotropic film having excellent flexibility is likely to be obtained.

It is preferable that the content of the dichroic substance in the light absorption anisotropic film with respect to the total mass of the light absorption anisotropic film is the same as the content of the dichroic substance with respect to the total mass of the solid content of the liquid crystal composition described above.

The content of the first dichroic azo coloring agent compound is preferably in a range of to 90 parts by mass and more preferably in a range of 45 to 75 parts by mass with respect to 100 parts by mass of the total content of the dichroic substance in the liquid crystal composition.

The content of the second dichroic azo coloring agent compound is preferably in a range of 6 to 50 parts by mass and more preferably in a range of 8 to 35 parts by mass with respect to 100 parts by mass of the total content of the dichroic substance in the liquid crystal composition.

The content of the third dichroic azo coloring agent compound is preferably in a range of 3 to 35 parts by mass and more preferably in a range of 5 to 30 parts by mass with respect to 100 parts by mass of the total content of the dichroic substance in the liquid crystal composition.

The content ratio between the first dichroic azo coloring agent compound, the second dichroic azo coloring agent compound, and the third dichroic azo coloring agent compound used as necessary can be optionally set in order to adjust the tint of the light absorption anisotropic film. Here, the content ratio of the second dichroic azo coloring agent compound to the first dichroic azo coloring agent compound (second dichroic azo coloring agent compound/first dichroic azo coloring agent compound) is preferably in a range of 0.1 to 10, more preferably in a range of 0.2 to 5, and particularly preferably in a range of 0.3 to 0.8 in terms of moles. In a case where the content ratio of the second dichroic azo coloring agent compound to the first dichroic azo coloring agent compound is in the above-described ranges, the alignment degree is increased.

### <Polymerizable Boronic Acid Compound>

The polymerizable boronic acid compound is a compound containing at least one group selected from the group consisting of a boronic acid group, a boronic acid ester group, and a boroxine ring group obtained by dehydrating and condensing a boronic acid group, and a polymerizable group. The boroxine ring group is formed by dehydration trimerization of a boronic acid group.

The polymerizable boronic acid compound may be polymerized in the light absorption anisotropic film.

As the polymerizable group, an acryloyl group, a methacryloyl group, an epoxy group, an oxetanyl group, or a styryl group is preferable, and an acryloyl group or a methacryloyl group is more preferable from the viewpoint that the adhesiveness is more excellent.

The polymerizable boronic acid compound may contain one or two or more polymerizable groups, but it is preferable that the polymerizable boronic acid compound contains one polymerizable group from the viewpoint that at least one of the adhesiveness or the alignment degree is more excellent.

The boronic acid group is a group represented by —B(OH)₂.

Examples of the boronic acid ester group include a group in which at least one of R^{B12} or R^{B13} represents a group other than a hydrogen atom, among the groups represented by —B(—OR^{B12})(—OR^{B13}) in Formula (B-1).

Examples of the boroxine ring group include a group represented by Formula (BX). In Formula (BX), * represents a bonding site with respect to another group.

The polymerizable boronic acid compound may contain one or more or two or more of at least one group selected from the group consisting of a boronic acid group, a boronic acid ester group, and a boroxine ring group, but it is preferable that the polymerizable boronic acid compound contains only one group thereof from the viewpoint that at least one of the adhesiveness or the alignment degree is more excellent.

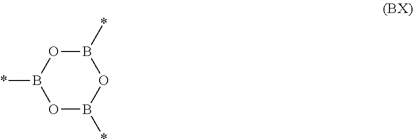 [SMILES: *B1OB(*)OB(*)O1]

It is preferable that the polymerizable boronic acid compound has an aromatic ring from the viewpoint that the alignment degree is more excellent.

Examples of the aromatic ring include an aromatic hydrocarbon group and an aromatic heterocyclic group. Among these, an aromatic hydrocarbon group is preferable from the viewpoint that at least one of the adhesiveness or the alignment degree is more excellent.

The number of carbon atoms of the aromatic hydrocarbon group is not particularly limited, but is preferably in a range of 4 to 20 and more preferably in a range of 6 to 12. Examples of the aromatic hydrocarbon group include a benzene ring group.

The number of carbon atoms of the aromatic heterocyclic group is not particularly limited, but is preferably in a range of 3 to 10 and more preferably in a range of 3 to 5. Examples of atoms other than the carbon atom constituting the aromatic heterocyclic group include an oxygen atom, a nitrogen atom, and a sulfur atom.

The aromatic hydrocarbon group and the aromatic heterocyclic group may be substituted with a substituent.

In a case where the polymerizable boronic acid compound has an aromatic ring, the number of aromatic rings may be one or two or more, but is preferably 1 from the viewpoint that the alignment degree is more excellent.

From the viewpoint that at least one of the adhesiveness or the alignment degree is more excellent, it is preferable that the polymerizable boronic acid compound includes at least one of a compound represented by Formula (B-1) or a compound represented by Formula (BX-1).

The compound represented by Formula (BX-1) is obtained, for example, by dehydrating and condensing the compound represented by Formula (B-1).

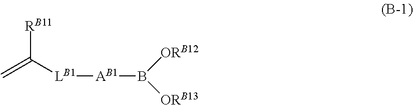

In Formula (B-1), R^{B11} represents a hydrogen atom or a methyl group.

L^{B1} represents a single bond, a divalent aliphatic hydrocarbon group, or a divalent group (hereinafter, also referred to as “divalent linking group B1”) in which one or more —CH₂—'s constituting a divalent aliphatic hydrocarbon group is substituted with at least one group selected from the group consisting of —O—, —C(═O)—, and —N(R^{B14})— (hereinafter, also referred to as “specific group B1”). Among these, the divalent linking group B1 is preferable from the viewpoint that the alignment degree and the adhesiveness are more excellent.

R^{B∝}represents a hydrogen atom or an alkyl group and preferably a hydrogen atom. The number of carbon atoms of the alkyl group is not particularly limited, but is preferably in a range of 1 to 3 and particularly preferably 1.

The divalent aliphatic hydrocarbon group may be saturated or unsaturated, but is preferably saturated. The divalent aliphatic hydrocarbon group may be linear, branched, or cyclic, but is preferably linear or branched. From the viewpoint that the alignment degree and the adhesiveness are more excellent, an alkylene group is preferable as the divalent aliphatic hydrocarbon group. The number of carbon atoms of the divalent aliphatic hydrocarbon group is preferably in a range of 1 to 10 and particularly preferably in a range of 1 to 5.

In the divalent linking group B1, only one —CH₂— constituting the divalent aliphatic hydrocarbon group may be substituted with the specific group B1, and two or more —CH₂—'s may be substituted with the specific group B1.

Preferred embodiments of the divalent linking group B1 include —C(═O)—O-alkylene group-, —C(═O)—O-alkylene group-N(R^{B14})—C(═O)—O—, —C(═O)—O-alkylene group-O—, —C(═O)—N(R^{B14})—, -alkylene group-N(R^{B14})—C(═O)—O—, and -alkylene group-O—.

A^{B1} represents an arylene group which may have a substituent or a heteroarylene group which may have a substituent. Among these, from the viewpoint that at least one of the adhesiveness or the alignment degree is more excellent, an arylene group which may have a substituent is preferable, and an arylene group (that is, an arylene group which does not have a substituent) is particularly preferable.

The number of carbon atoms of the arylene group is not particularly limited, but is preferably in a range of 4 to 20 and more preferably in a range of 6 to 12. Examples of the arylene group include a phenylene group.

The number of carbon atoms of the heteroarylene group is not particularly limited, but is preferably in a range of 3 to 10 and more preferably in a range of 3 to 5. Examples of the heteroatom of the heteroaryl group include an oxygen atom, a nitrogen atom, and a sulfur atom.

R^{B12} and R^{B13} each independently represent a hydrogen atom, an alkyl group which may have a substituent, an aryl group which may have a substituent, or a heteroaryl group which may have a substituent. Among these, from the viewpoint that at least one of the adhesiveness or the alignment degree is more excellent, a hydrogen atom or an alkyl group which may have a substituent is preferable, and a hydrogen atom is more preferable.

The number of carbon atoms of the alkyl group is not particularly limited, but is preferably in a range of 1 to 10 and more preferably in a range of 1 to 5. Examples of the alkyl group include a methyl group, an ethyl group, and a propyl group.

The number of carbon atoms of the aryl group is not particularly limited, but is preferably in a range of 4 to 20 and more preferably in a range of 6 to 12. Examples of the aryl group include a phenyl group.

The number of carbon atoms of the heteroaryl group is not particularly limited, but is preferably in a range of 3 to 10 and more preferably in a range of 3 to 5. Examples of the heteroatom of the heteroaryl group include an oxygen atom, a nitrogen atom, and a sulfur atom.

R^{B12} and R^{B13} may be bonded to each other to form a ring. Examples of the ring to be formed include an aliphatic hydrocarbon ring having a boron atom.

From the viewpoint that at least one of the adhesiveness or the alignment degree is more excellent, a compound represented by Formula (B-2) is preferable as the compound represented by Formula (B-1).

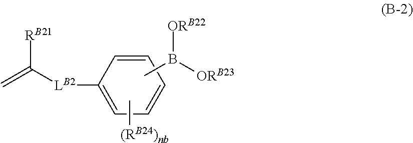

In Formula (B-2), R^{B21} represents a hydrogen atom or a methyl group.

L^{B2} represents a single bond, a divalent aliphatic hydrocarbon group, or a divalent group (hereinafter, also referred to as “divalent linking group B2”) in which one or more —CH₂—'s constituting a divalent aliphatic hydrocarbon group is substituted with at least one group selected from the group consisting of —O—, —C(═O)—, and —N(R^{B25})— (hereinafter, also referred to as “specific group B2”). Among these, the divalent linking group B2 is preferable from the viewpoint that the alignment degree and the adhesiveness are more excellent.

R^{B≡}represents a hydrogen atom or an alkyl group and preferably a hydrogen atom. The number of carbon atoms of the alkyl group is not particularly limited, but is preferably in a range of 1 to 3 and particularly preferably 1.

The divalent aliphatic hydrocarbon group, the divalent linking group B2, and the specific group B2 in L^{B2} each have the same definition as that for the divalent aliphatic hydrocarbon group, the divalent linking group B1, and the specific group B1 in L^{B1} of Formula (B-1), and thus the description thereof will not be repeated.

R^{B22} and R^{B23} each independently represent a hydrogen atom, an alkyl group which may have a substituent, an aryl group which may have a substituent, or a heteroaryl group which may have a substituent. Among these, from the viewpoint that at least one of the adhesiveness or the alignment degree is more excellent, a hydrogen atom or an alkyl group which may have a substituent is preferable, and a hydrogen atom is more preferable.

Each group as R^{B22} has the same definition as that for each group as R^{B12} of Formula (B-1), and thus the description thereof will not be repeated.

Each group as R^{B23} has the same definition as that for each group as R^{B13} of Formula (B-1), and thus the description thereof will not be repeated.

R^{B22} and R^{B23} may be bonded to each other to form a ring. Examples of the ring to be formed include an aliphatic hydrocarbon ring having a boron atom.

R^{B24} represents a monovalent substituent. Specific examples of the monovalent substituent will be described below. As the monovalent substituent, an alkyl group, a halogen atom, an alkoxy group, or an aryl group is preferable.

nb represents an integer of 0 to 4. Among these, from the viewpoint that at least one of the adhesiveness or the alignment degree is more excellent, nb represents preferably 0 or 1 and more preferably 0.

In a case where nb represents 2 or greater, a plurality of R^{B24}'s may be the same as or different from each other.

The position of a group represented by —B(OR^{B22})(OR^{B23}) in the compound represented by Formula (B-2) is not particularly limited, but it is preferable that the group is positioned at the meta position or the para position with respect to the bonding position of L^{B2} from the viewpoint that at least one of the adhesiveness or the alignment degree is more excellent.

Specific examples of the compound represented by Formula (B-1) are shown below, but the present invention is not limited thereto. In the formulae, Me represents a methyl group.

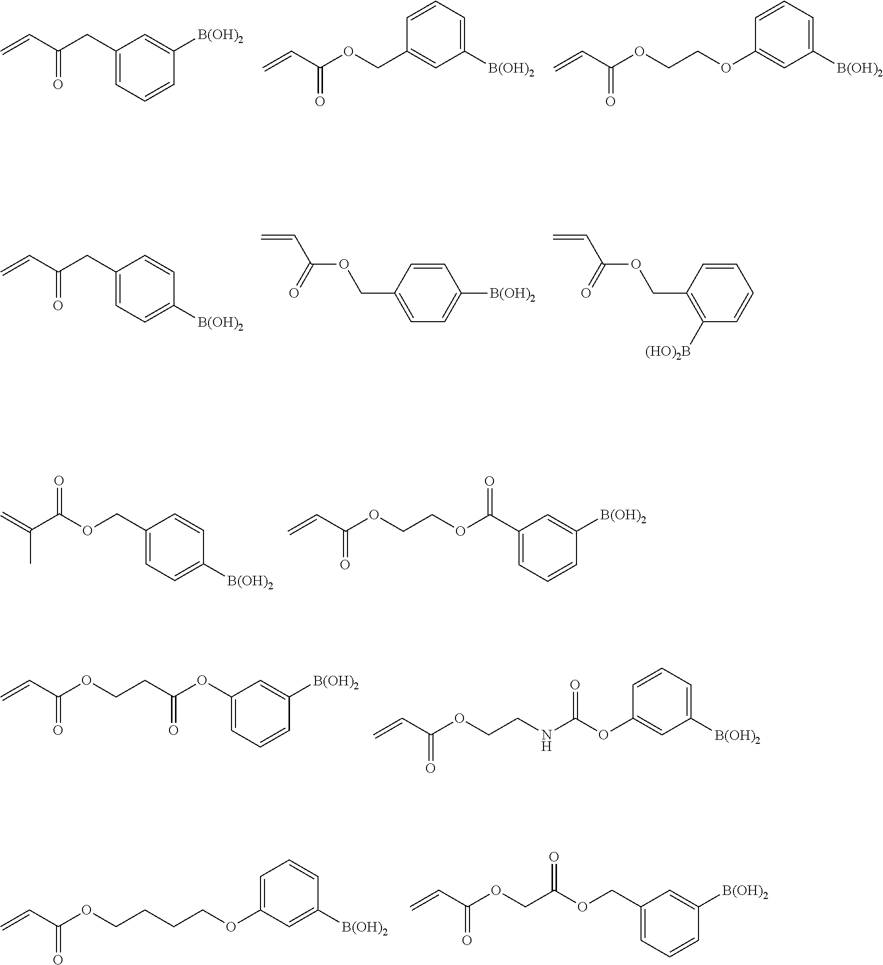

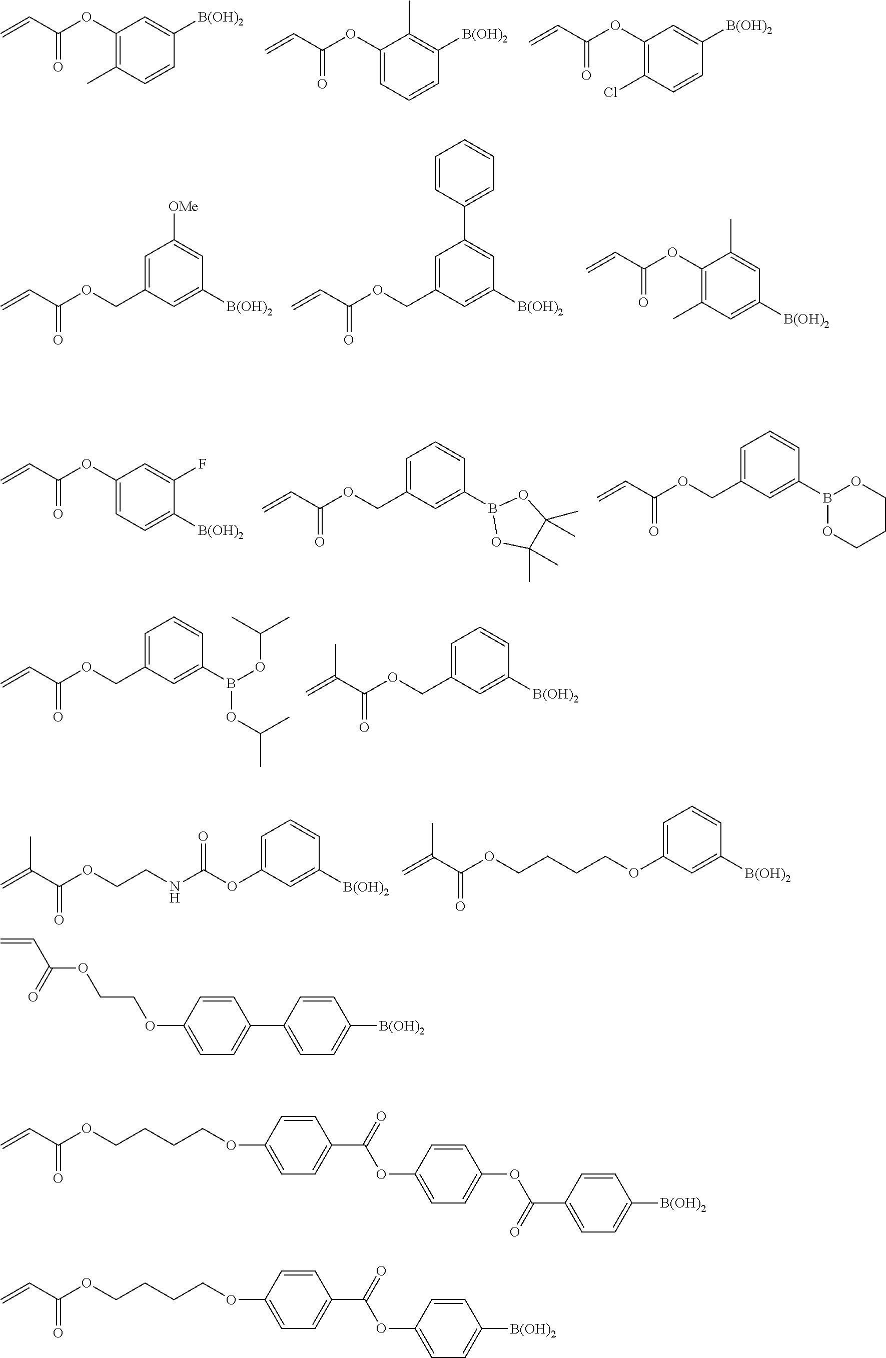

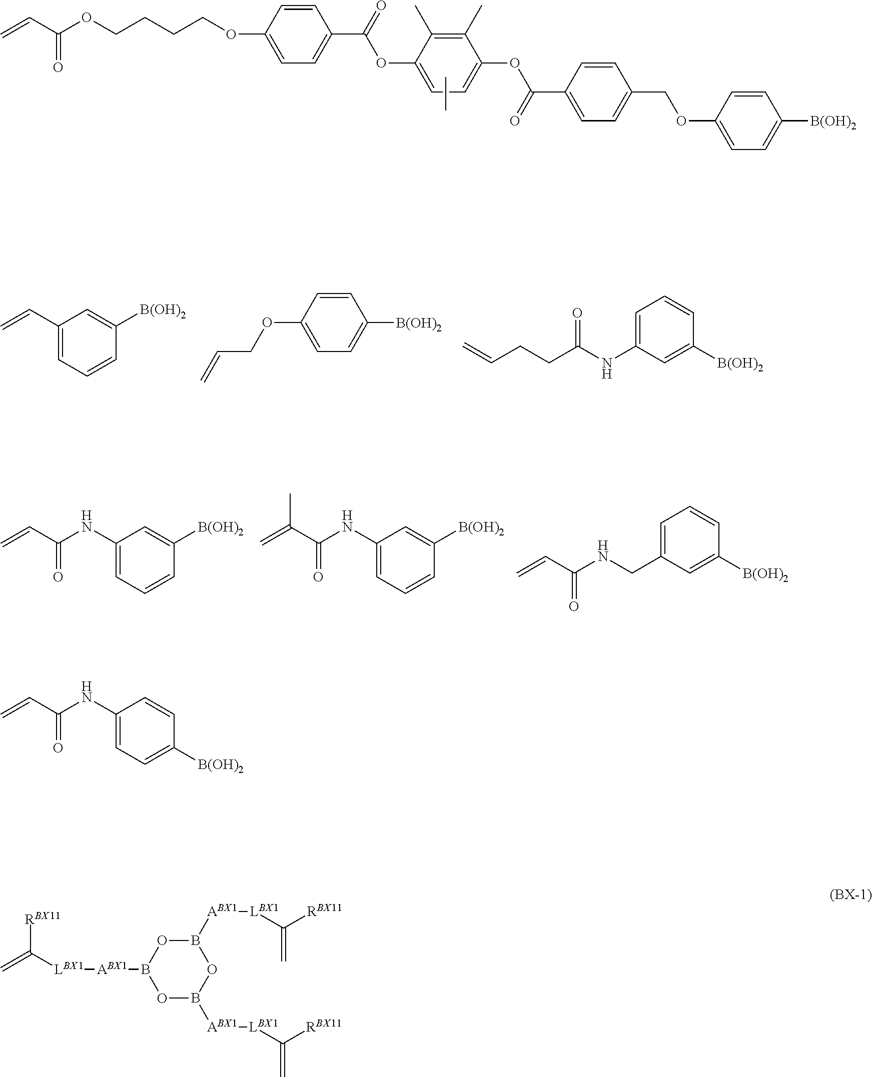

In Formula (BX-1), R^{BX11} represents a hydrogen atom or a methyl group. A plurality of R^{BX11}'s may be the same as or different from each other, but it is preferable that the plurality of R^{BX11}'s are the same as each other from the viewpoint that at least one of the adhesiveness or the alignment degree is more excellent.

L^{BX1} represents a single bond, a divalent aliphatic hydrocarbon group, or a divalent group (hereinafter, also referred to as “divalent linking group BX1”) in which one or more of —CH₂—'s constituting a divalent aliphatic hydrocarbon group is substituted with at least one group selected from the group consisting of —O—, —C(═O)—, and —N(R^{BX14})— (hereinafter, also referred to as “specific group BX1”). Among these, the divalent linking group BX1 is preferable from the viewpoint that the alignment degree and the adhesiveness are more excellent. A plurality of L^{BX1}'s may be the same as or different from each other, but it is preferable that the plurality of R^{BX1}'s are the same as each other from the viewpoint that at least one of the adhesiveness or the alignment degree is more excellent.

R^{BX14} represents a hydrogen atom or an alkyl group and preferably a hydrogen atom. The number of carbon atoms of the alkyl group is not particularly limited, but is preferably in a range of 1 to 3 and particularly preferably 1. In a case where a plurality of R^{BX14}'s are present, the plurality of R^{BX14}'s may be the same as or different from each other, but it is preferable that the plurality of R^{BX14}'s are the same as each other from the viewpoint that at least one of the adhesiveness or the alignment degree is more excellent.

The divalent aliphatic hydrocarbon group, the divalent linking group BX1, and the specific group BX1 in L^{BX1} each have the same definition as that for the divalent aliphatic hydrocarbon group, the divalent linking group B1, and the specific group B1 in L^{B1} of Formula (B-1), and thus the description thereof will not be repeated.

A^{BX1} represents an arylene group which may have a substituent or a heteroarylene group which may have a substituent. Among these, from the viewpoint that at least one of the adhesiveness or the alignment degree is more excellent, an arylene group which may have a substituent is preferable, and an arylene group (that is, an arylene group which does not have a substituent) is particularly preferable.

A plurality of A^{BX1}'s may be the same as or different from each other, but it is preferable that the plurality of A^{BX1}'s are the same as each other from the viewpoint that at least one of the adhesiveness or the alignment degree is more excellent.

The number of carbon atoms of the arylene group is not particularly limited, but is preferably in a range of 4 to 20 and more preferably in a range of 6 to 12. Examples of the arylene group include a phenylene group and a naphthalene group.

The number of carbon atoms of the heteroarylene group is not particularly limited, but is preferably in a range of 3 to 10 and more preferably in a range of 3 to 5. Examples of the heteroatom of the heteroaryl group include an oxygen atom, a nitrogen atom, and a sulfur atom.

From the viewpoint that at least one of the adhesiveness or the alignment degree is more excellent, a compound represented by Formula (BX-2) is preferable as the compound represented by Formula (BX-1).

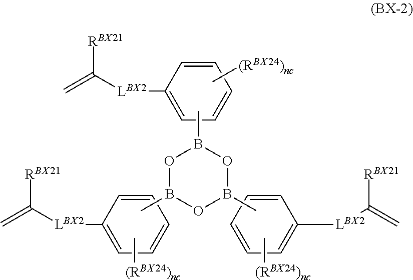

In Formula (BX-2), R^{BX21} represents a hydrogen atom or a methyl group. A plurality of R^{BX21}'s may be the same as or different from each other, but it is preferable that the plurality of R^{BX21}'s are the same as each other from the viewpoint that at least one of the adhesiveness or the alignment degree is more excellent.

L^{BX2} represents a single bond, a divalent aliphatic hydrocarbon group, or a divalent group (hereinafter, also referred to as “divalent linking group BX2”) in which one or more of —CH₂—'s constituting a divalent aliphatic hydrocarbon group is substituted with at least one group selected from the group consisting of —O—, —C(═O)—, and —N(R^{BX25})— (hereinafter, also referred to as “specific group BX2”). Among these, the divalent linking group BX2 is preferable from the viewpoint that the alignment degree and the adhesiveness are more excellent. The plurality of L^{BX2}'s may be the same as or different from each other, but it is preferable that the plurality of L^{BX2}'s are the same as each other from the viewpoint that at least one of the adhesiveness or the alignment degree is more excellent.

R^{BX25} represents a hydrogen atom or an alkyl group and preferably a hydrogen atom. The number of carbon atoms of the alkyl group is not particularly limited, but is preferably in a range of 1 to 3 and particularly preferably 1. In a case where a plurality of R^{BX25}'s are present, the plurality of R^{BX}25's may be the same as or different from each other, but it is preferable that the plurality of R^{BX25}'s are the same as each other from the viewpoint that at least one of the adhesiveness or the alignment degree is more excellent.

The divalent aliphatic hydrocarbon group, the divalent linking group BX2, and the specific group BX2 in L^{BX2} each have the same definition as that for the divalent aliphatic hydrocarbon group, the divalent linking group B1, and the specific group B1 in L^{B1} of Formula (B-1), and thus the description thereof will not be repeated.

R^{BX24} represents a monovalent substituent. In a case where a plurality of R^{BX24}'s are present, the plurality of R^{BX24}'s may be the same as or different from each other, but it is preferable that the plurality of R^{BX24}'s are the same as each other from the viewpoint that at least one of the adhesiveness or the alignment degree is more excellent.

Specific examples of the monovalent substituent as R^{BX24} will be described below. As the monovalent substituent, an alkyl group, a halogen atom, an alkoxy group, or an aryl group is preferable.

nc represents an integer of 0 to 4. Among these, from the viewpoint that at least one of the adhesiveness or the alignment degree is more excellent, nb represents preferably 0 or 1 and more preferably 0. A plurality of nc's may be the same as or different from each other, but it is preferable that the plurality of nc's are the same as each other from the viewpoint that at least one of the adhesiveness or the alignment degree is more excellent.

Specific examples of the compound represented by Formula (BX-1) are shown below, but the present invention is not limited thereto. In the formulae, Me represents a methyl group.

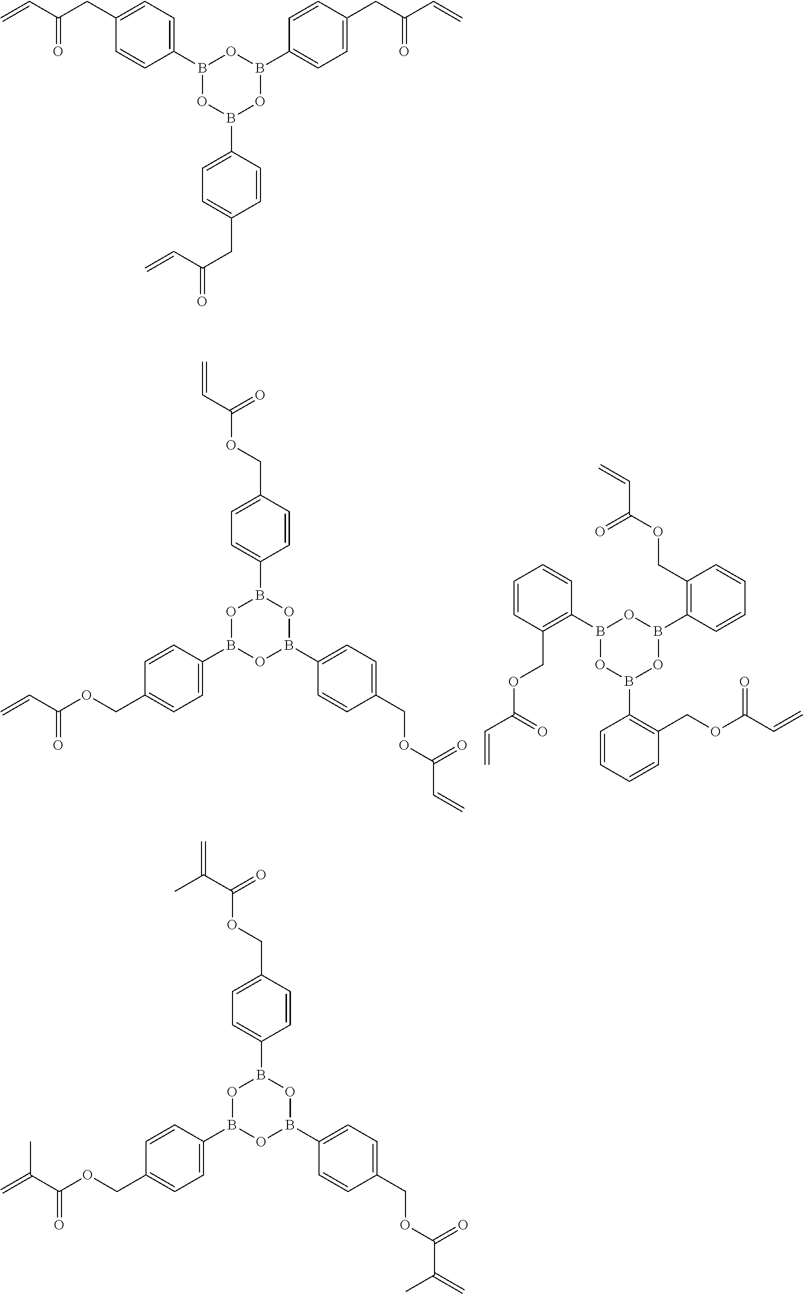

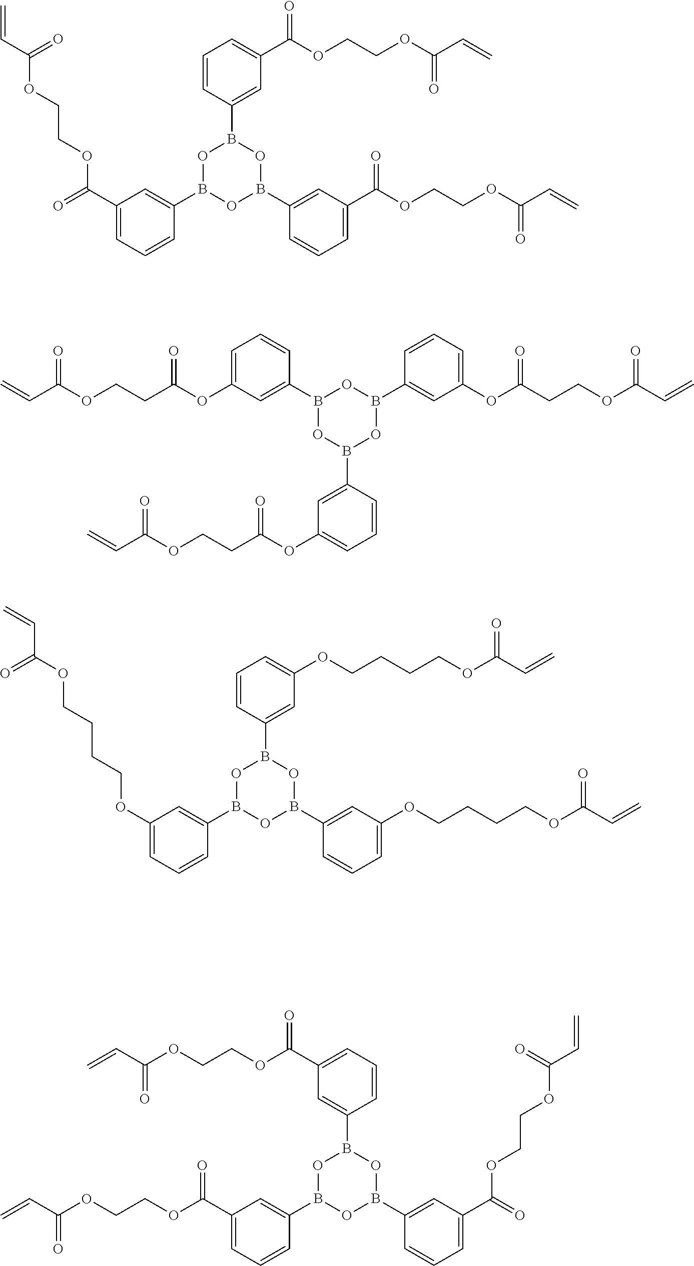

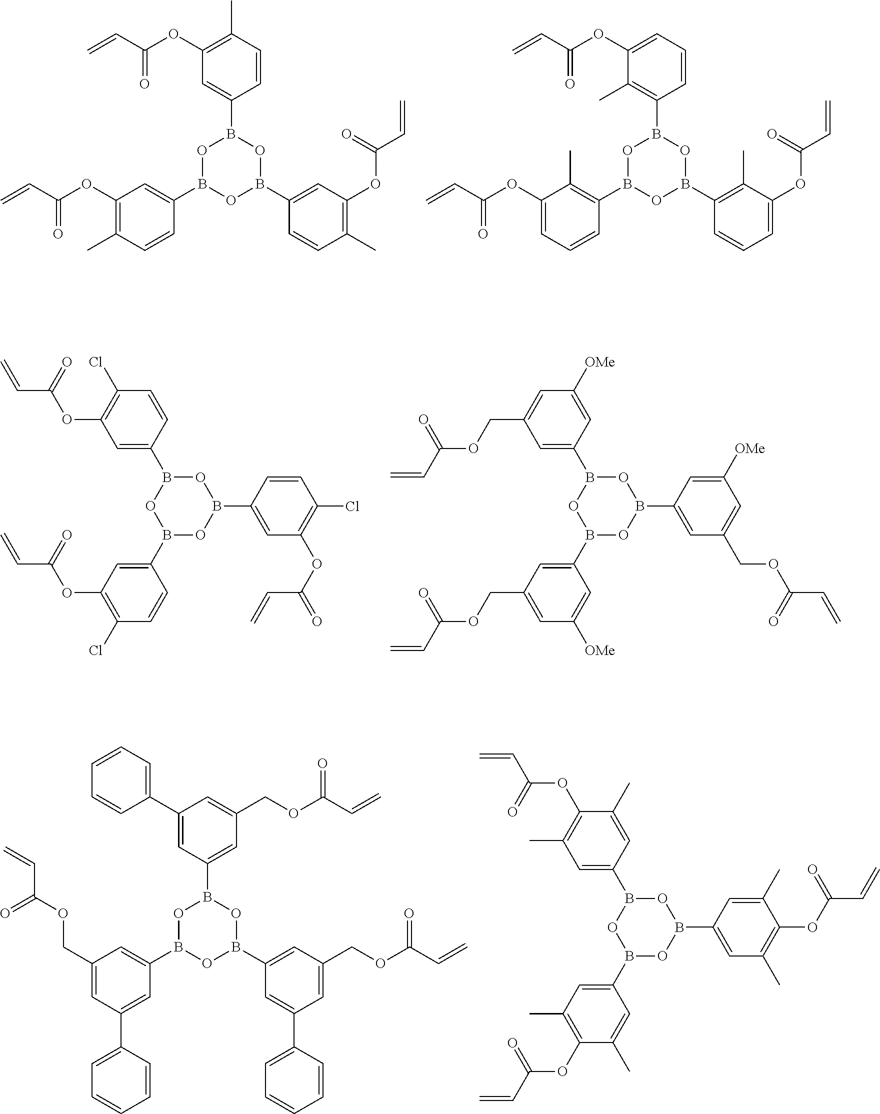

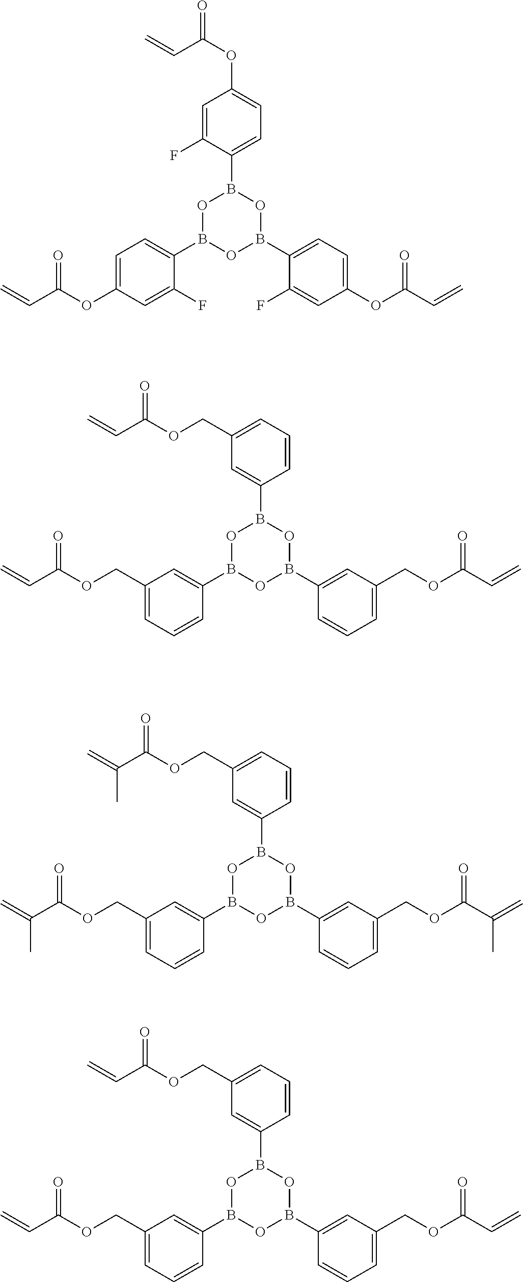

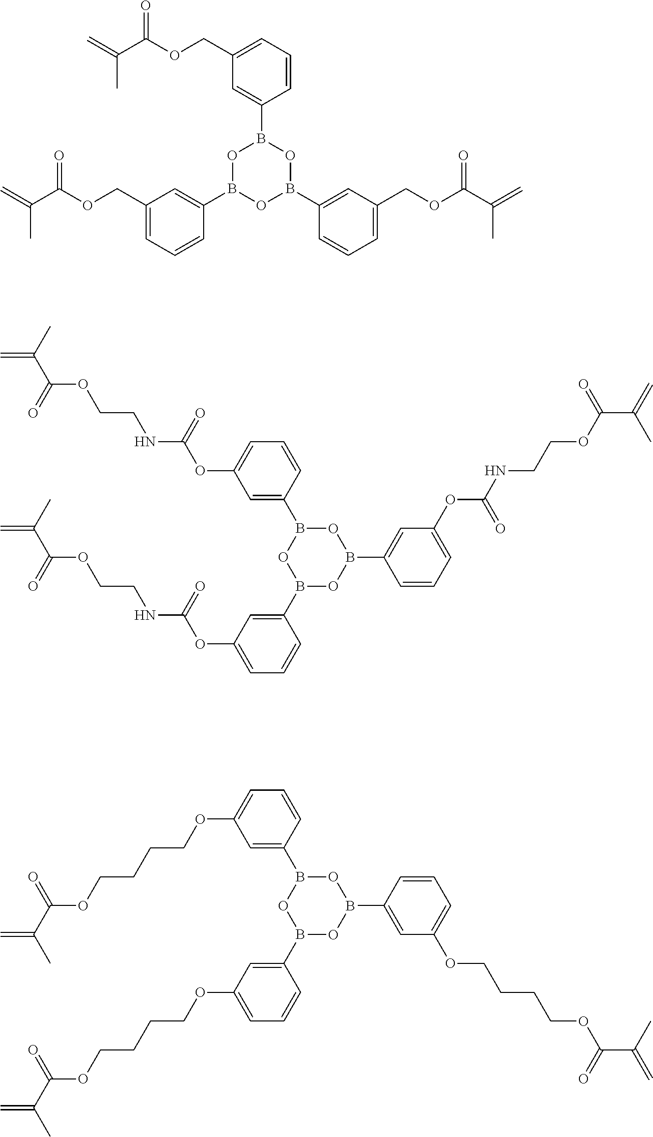

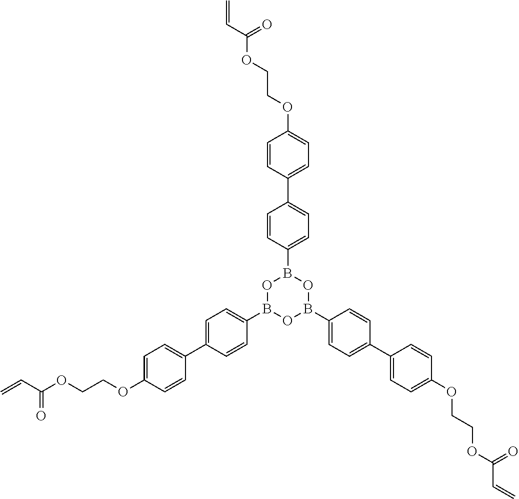 [SMILES: C=CC(=O)OCCOc1ccc(-c2ccc(B3OB(c4ccc(-c5ccc(OCCOC(=O)C=C)cc5)cc4)OB(c4ccc(-c5ccc(OCCOC(=O)C=C)cc5)cc4)O3)cc2)cc1]

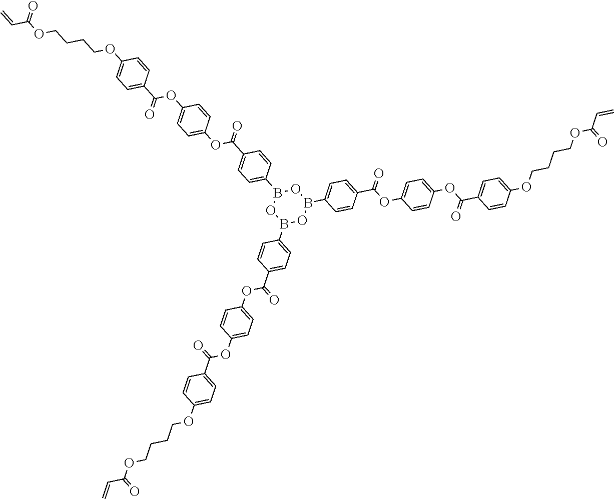 [SMILES: C=CC(=O)OCCCCOc1ccc(C(=O)Oc2ccc(OC(=O)c3ccc(B4OB(c5ccc(C(=O)Oc6ccc(OC(=O)c7ccc(OCCCCOC(=O)C=C)cc7)cc6)cc5)OB(c5ccc(C(=O)Oc6ccc(OC(=O)c7ccc(OCCCCOC(=O)C=C)cc7)cc6)cc5)O4)cc3)cc2)cc1]

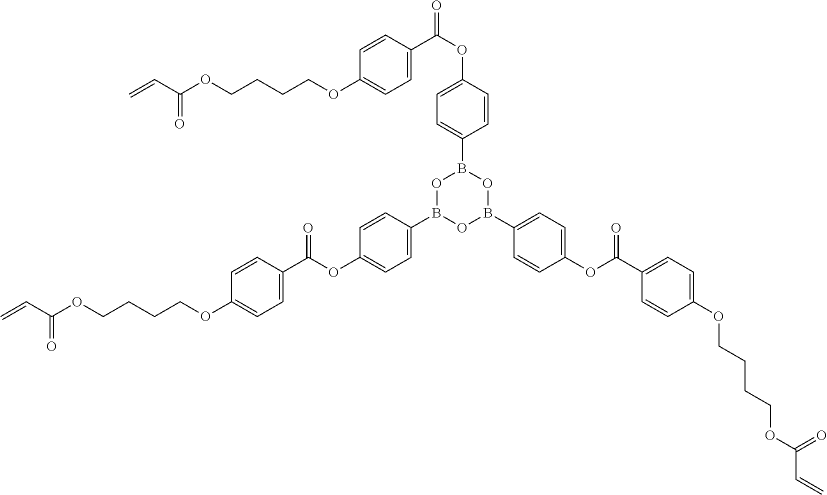 [SMILES: C=CC(=O)OCCCCOc1ccc(C(=O)Oc2ccc(B3OB(c4ccc(OC(=O)c5ccc(OCCCCOC(=O)C=C)cc5)cc4)OB(c4ccc(OC(=O)c5ccc(OCCCCOC(=O)C=C)cc5)cc4)O3)cc2)cc1]

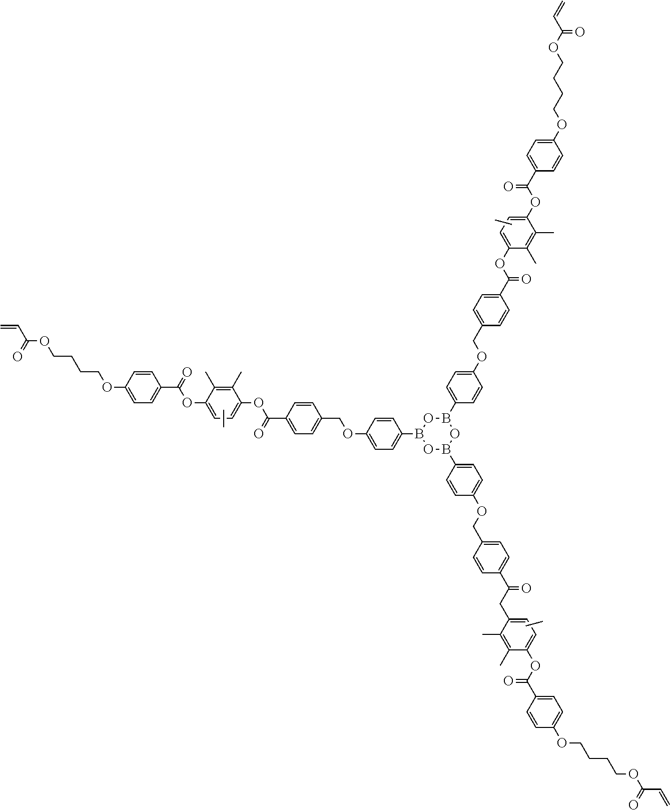

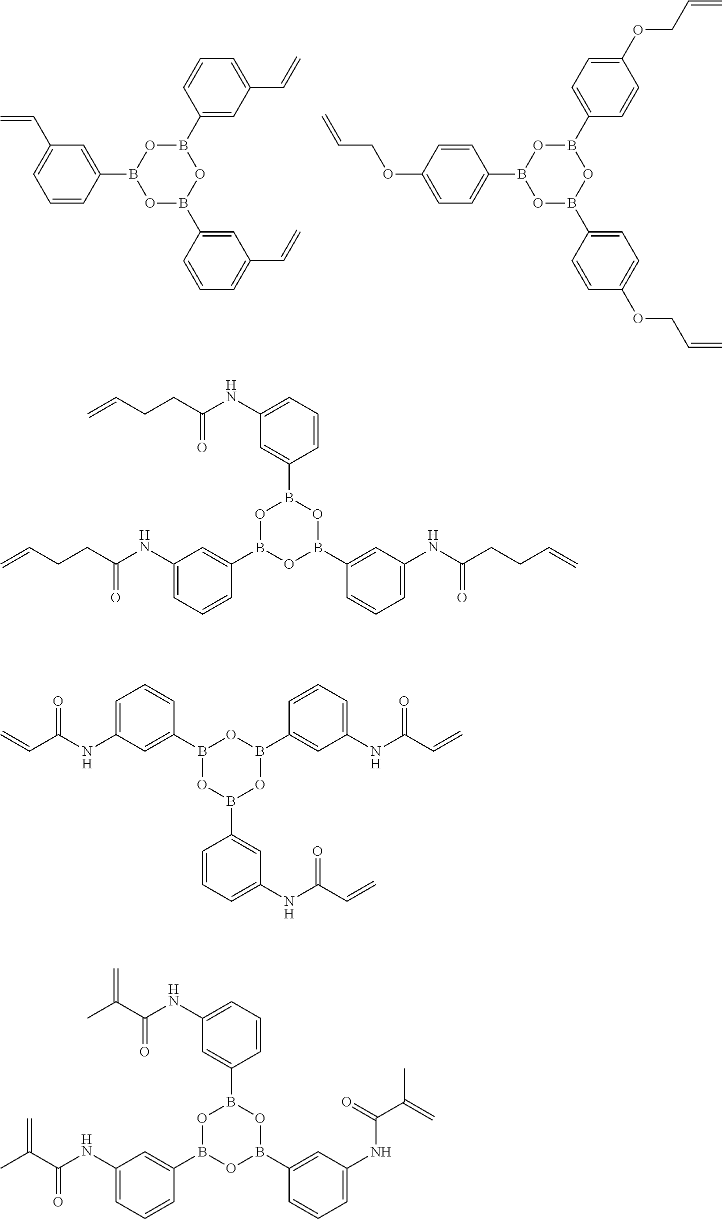

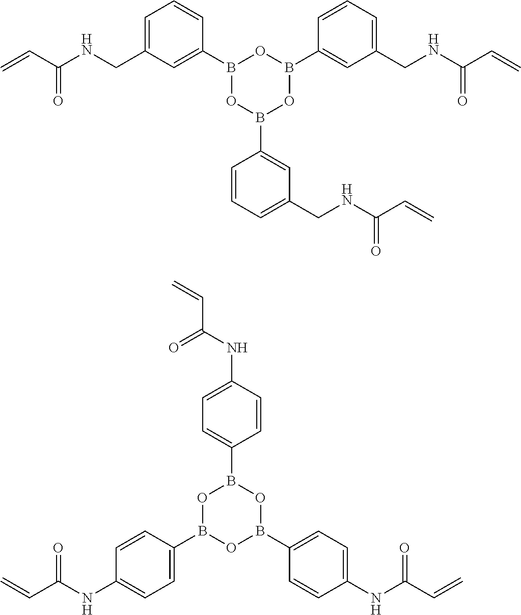

The content of the polymerizable boronic acid compound is preferably in a range of 0.1% to 10% by mass, more preferably in a range of 0.2% to 8% by mass, and particularly preferably in a range of 0.3% to 6% by mass with respect to the total solid content mass of the liquid crystal composition. In a case where the content of the polymerizable boronic acid compound is greater than or equal to the lower limit, the adhesiveness of the light absorption anisotropic film is more excellent. In a case where the content of the polymerizable boronic acid compound is less than or equal to the upper limit, the alignment degree of the light absorption anisotropic film is more excellent.

The polymerizable boronic acid compound may be used alone or in combination of two or more kinds thereof. In a case where the liquid crystal composition contains two or more kinds of the polymerizable boronic acid compounds, it is preferable that the total amount of the polymerizable boronic acid compounds is in the above-described ranges.

It is preferable that the content of the polymerizable boronic acid compound in the light absorption anisotropic film with respect to the total mass of the light absorption anisotropic film is the same as the content of the polymerizable boronic acid compound with respect to the total mass of the solid content of the above-described liquid crystal composition.

From the viewpoint that the stability of the liquid crystal composition is excellent, it is preferable that the liquid crystal composition includes both a compound represented by Formula (B-1) (preferably a compound represented by Formula (B-2)) and a compound represented by Formula (BX-1) (preferably a compound represented by Formula (BX-2)).

In this case, from the viewpoint that the stability of the liquid crystal composition is more excellent, the mass ratio of the content of the compound represented by Formula (B-1) to the content of the compound represented by Formula (BX-1) (content of compound represented by Formula (B-1)/content of compound represented by Formula (BX-1)) is preferably in a range of 0.1 to 2000, more preferably in a range of 1 to 1000, and still more preferably in a range of 5 to 500.

### <Solvent>

From the viewpoint of workability and the like, it is preferable that the liquid crystal composition contains a solvent.

Examples of the solvent include organic solvents such as ketones (such as acetone, 2-butanone, methyl isobutyl ketone, cyclopentanone, and cyclohexanone), ethers (such as dioxane, tetrahydrofuran, tetrahydropyran, dioxolane, tetrahydrofurfuryl alcohol, and cyclopentyl methyl ether), aliphatic hydrocarbons (such as hexane), alicyclic hydrocarbons (such as cyclohexane), aromatic hydrocarbons (such as benzene, toluene, xylene, and trimethylbenzene), halogenated carbons (such as dichloromethane, trichloromethane (chloroform), dichloroethane, dichlorobenzene, and chlorotoluene), esters (such as methyl acetate, ethyl acetate, butyl acetate, and diethyl carbonate), alcohols (such as ethanol, isopropanol, butanol, and cyclohexanol), cellosolves (such as methyl cellosolve, ethyl cellosolve, and 1,2-dimethoxyethane), cellosolve acetates, sulfoxides (such as dimethyl sulfoxide), amides (such as dimethylformamide, dimethylacetamide, N-methylpyrrolidone, N-ethylpyrrolidone, and 1,3-dimethyl-2-imidazolidinone), and heterocyclic compounds (such as pyridine), and water. These solvents may be used alone or in combination of two or more kinds thereof.

Among these solvents, it is preferable to use an organic solvent and more preferable to use halogenated carbons or ketones from the viewpoint that the effects of the present invention are more excellent.

In a case where the liquid crystal composition contains a solvent, the content of the solvent is preferably in a range of 80% to 99% by mass, more preferably in a range of 83% to 97% by mass, and particularly preferably in a range of 85% to 95% by mass with respect to the total mass of the liquid crystal composition.

These solvents may be used alone or in combination of two or more kinds thereof In a case where the composition contains two or more kinds of solvents, it is preferable that the total amount of the solvents is in the above-described range.

### <Interface Improver>

It is preferable that the liquid crystal composition contains an interface improver (hereinafter, also referred to as “surfactant”). In a case where the liquid crystal composition contains an interface improver, the smoothness of the coated surface is improved, the alignment degree is improved, and cissing and unevenness are suppressed so that the in-plane uniformity is expected to be improved.

As the interface improver, interface improvers that allow liquid crystal compounds to be horizontally aligned are preferable, and compounds (horizontal alignment agents) described in paragraphs [0253] to [0293] of JP2011-237513A can be used. Further, fluorine (meth)acrylate-based polymers described in [0018] to [0043] of JP2007-272185A can also be used. Compounds other than the compounds described above may be used as the interface improver.

In a case where the liquid crystal composition contains an interface improver, the content of the interface improver in the liquid crystal composition is preferably in a range of to 2.0% by mass and more preferably in a range of 0.1% to 1.0% by mass with respect to the total mass of the solid content of the liquid crystal composition.

The interface improver may be used alone or in combination of two or more kinds thereof In a case where the composition contains two or more kinds of interface improvers, it is preferable that the total amount of the interface improvers is in the above-described range.

In a case where the light absorption anisotropic film contains an interface improver, it is preferable that the content of the interface improver with respect to the total mass of the light absorption anisotropic film is the same as the content of the interface improver with respect to the total mass of the solid content of the liquid crystal composition.

### <Polymerization Initiator>

It is preferable that the liquid crystal composition contains a polymerization initiator.

It is preferable that the polymerization initiator to be used is a photopolymerization initiator capable of initiating a polymerization reaction by irradiation with ultraviolet rays.

Examples of the photopolymerization initiator include α-carbonyl compounds (described in the specifications of U.S. Pat. Nos. 2,367,661A and 2,367,670A), acyloin ether (described in the specification of U.S. Pat. No. 2,448,828A), α-hydrocarbon-substituted aromatic acyloin compounds (described in the specification of U.S. Pat. No. 2,722,512A), polynuclear quinone compounds (described in the specifications of U.S. Pat. Nos. 3,046,127A and 2,951,758A), a combination of a triarylimidazole dimer and a p-aminophenyl ketone (described in the specification of U.S. Pat. No. 3,549,367A), acridine and phenazine compounds (described in the specifications of JP1985-105667A (JP-S60-105667A) and U.S. Pat. No. 4,239,850A), oxadiazole compounds (described in the specification of U.S. Pat. No. 4,212,970A), and acylphosphine oxide compounds (described in JP1988-40799B (JP-S63-40799B), JP1993-29234B (JP-H5-29234B), JP1998-95788A (JP-H10-95788A), and JP1998-29997A (JP-H10-29997A)).

Further, in the present invention, it is also preferable that the polymerization initiator is an oxime-type polymerization initiator, and specific examples thereof include the initiators described in paragraphs to of WO2017/170443A.

In a case where the liquid crystal composition contains a polymerization initiator, the content of the polymerization initiator is preferably in a range of 0.01 to 30 parts by mass and more preferably in a range of 0.1 to 15 parts by mass with respect to 100 parts by mass which is the total amount of the dichroic substance and the liquid crystal compound in the liquid crystal composition. The durability of the light absorption anisotropic film is enhanced in a case where the content of the polymerization initiator is 0.01 parts by mass or greater, and the alignment degree of the light absorption anisotropic film is enhanced in a case where the content thereof is 30 parts by mass or less.

The polymerization initiator may be used alone or in combination of two or more kinds thereof In a case where the composition contains two or more kinds of polymerization initiators, it is preferable that the total amount of the polymerization initiators is in the above-described ranges.

### <Substituent>

The substituents in the present specification indicate the following groups unless otherwise specified.

Examples of the substituent include an alkyl group (preferably an alkyl group having 1 to 20 carbon atoms, more preferably an alkyl group having 1 to 12 carbon atoms, and particularly preferably an alkyl group having 1 to 8 carbon atoms, and examples thereof include a methyl group, an ethyl group, an isopropyl group, a tert-butyl group, an n-octyl group, an n-decyl group, an n-hexadecyl group, a cyclopropyl group, a cyclopentyl group, and a cyclohexyl group), an alkenyl group (preferably an alkenyl group having 2 to 20 carbon atoms, more preferably an alkenyl group having 2 to 12 carbon atoms, and particularly preferably an alkenyl group having 2 to 8 carbon atoms, and examples thereof include a vinyl group, an aryl group, a 2-butenyl group, and a 3-pentenyl group), an alkynyl group (preferably an alkynyl group having 2 to 20 carbon atoms, more preferably an alkynyl group 2 to 12 carbon atoms, and particularly preferably an alkynyl group having 2 to 8 carbon atoms, and examples thereof include a propargyl group and a 3-pentynyl group), an aryl group (preferably an aryl group having 6 to 30 carbon atoms, more preferably an aryl group having 6 to 20 carbon atoms, and particularly preferably an aryl group having 6 to 12 carbon atoms, and examples thereof include a phenyl group, a 2,6-diethylphenyl group, a 3,5-ditrifluoromethylphenyl group, a styryl group, a naphthyl group, and a biphenyl group), a substituted or unsubstituted amino group (preferably an amino group having 0 to 20 carbon atoms, more preferably an amino group having 0 to 10 carbon atoms, and particularly preferably an amino group having 0 to 6 carbon atoms, and examples thereof include an unsubstituted amino group, a methylamino group, a dimethylamino group, a diethylamino group, and an anilino group), an alkoxy group (preferably an alkoxy group having 1 to 20 carbon atoms and more preferably an alkoxy group having 1 to 15 carbon atoms, and examples thereof include a methoxy group, an ethoxy group, and a butoxy group), an oxycarbonyl group (preferably an oxycarbonyl group having 2 to 20 carbon atoms, more preferably an oxycarbonyl group having 2 to 15 carbon atoms, and particularly preferably an oxycarbonyl group having 2 to 10 carbon atoms, and examples thereof include a methoxycarbonyl group, an ethoxycarbonyl group, and a phenoxycarbonyl group), an acyloxy group (preferably an acyloxy group having 2 to 20 carbon atoms, more preferably an acyloxy group having 2 to 10 carbon atoms, and particularly preferably an acyloxy group having 2 to 6 carbon atoms, and examples thereof include an acetoxy group, a benzoyloxy group, an acryloyl group, and a methacryloyl group), an acylamino group (preferably an acylamino group having 2 to 20 carbon atoms, more preferably an acylamino group having 2 to 10 carbon atoms, and particularly preferably an acylamino group having 2 to 6 carbon atoms, and examples thereof include an acetylamino group and a benzoylamino group), an alkoxycarbonylamino group (preferably an alkoxycarbonylamino group having 2 to 20 carbon atoms, more preferably an alkoxycarbonylamino group having 2 to 10 carbon atoms, and particularly preferably an alkoxycarbonylamino group having 2 to 6 carbon atoms, and examples thereof include a methoxycarbonylamino group), an aryloxycarbonylamino group (preferably an aryloxycarbonylamino group having 7 to 20 carbon atoms, more preferably an aryloxycarbonylamino group having 7 to 16 carbon atoms, and particularly preferably an aryloxycarbonylamino group having 7 to 12 carbon atoms, and examples thereof include a phenyloxycarbonylamino group), a sulfonylamino group (preferably a sulfonylamino group having 1 to 20 carbon atoms, more preferably a sulfonylamino group having 1 to 10 carbon atoms, and particularly preferably a sulfonylamino group having 1 to 6 carbon atoms, and examples thereof include a methanesulfonylamino group and a benzenesulfonylamino group), a sulfamoyl group (preferably a sulfamoyl group having 0 to 20 carbon atoms, more preferably a sulfamoyl group having 0 to 10 carbon atoms, and particularly preferably a sulfamoyl group having 0 to 6 carbon atoms, and examples thereof include a sulfamoyl group, a methylsulfamoyl group, a dimethylsulfamoyl group, and a phenylsulfamoyl group), a carbamoyl group (preferably a carbamoyl group having 1 to 20 carbon atoms, more preferably a carbamoyl group having 1 to 10 carbon atoms, and particularly preferably a carbamoyl group having 1 to 6 carbon atoms, and examples thereof include an unsubstituted carbamoyl group, a methylcarbamoyl group, a diethylcarbamoyl group, and a phenylcarbamoyl group), an alkylthio group (preferably an alkylthio group having 1 to 20 carbon atoms, more preferably an alkylthio group having 1 to carbon atoms, and particularly preferably an alkylthio group having 1 to 6 carbon atoms, and examples thereof include a methylthio group and an ethylthio group), an arylthio group (preferably an arylthio group having 6 to 20 carbon atoms, more preferably an arylthio group having 6 to 16 carbon atoms, and particularly preferably an arylthio group having 6 to 12 carbon atoms, and examples thereof include a phenylthio group), a sulfonyl group (preferably a sulfonyl group having 1 to 20 carbon atoms, more preferably a sulfonyl group having 1 to 10 carbon atoms, and particularly preferably a sulfonyl group having 1 to 6 carbon atoms, and examples thereof include a mesyl group and a tosyl group), a sulfinyl group (preferably a sulfinyl group having 1 to 20 carbon atoms, more preferably a sulfinyl group having 1 to 10 carbon atoms, and particularly preferably a sulfinyl group having 1 to 6 carbon atoms, and examples thereof include a methanesulfinyl group and a benzenesulfinyl group), a ureido group (preferably a ureido group having 1 to 20 carbon atoms, more preferably a ureido group having 1 to 10 carbon atoms, and particularly preferably a ureido group having 1 to 6 carbon atoms, and examples thereof include an unsubstituted ureido group, a methylureido group, and a phenylureido group), a phosphoric acid amide group (preferably a phosphoric acid amide group having 1 to 20 carbon atoms, more preferably a phosphoric acid amide group having 1 to 10 carbon atoms, and particularly preferably a phosphoric acid amide group having 1 to 6 carbon atoms, and examples thereof include a diethylphosphoric acid amide group and a phenylphosphoric acid amide group), a hydroxy group, a mercapto group, a halogen atom (such as a fluorine atom, a chlorine atom, a bromine atom, and an iodine atom), a cyano group, a nitro group, a hydroxamic acid group, a sulfino group, a hydrazino group, an imino group, an azo group, a heterocyclic group (preferably a heterocyclic group having 1 to 30 carbon atoms and more preferably a heterocyclic group having 1 to 12 carbon atoms, and examples thereof include a heterocyclic group having a heteroatom such as a nitrogen atom, an oxygen atom, or a sulfur atom, and examples of the heterocyclic group having a heteroatom include an epoxy group, an oxetanyl group, an imidazolyl group, a pyridyl group, a quinolyl group, a furyl group, a piperidyl group, a morpholino group, a maleimide group, a benzoxazolyl group, a benzimidazolyl group, and a benzothiazolyl group), a silyl group (preferably a silyl group having 3 to 40 carbon atoms, more preferably a silyl group having 3 to 30 carbon atoms, and particularly preferably a silyl group having 3 to 24 carbon atoms, and examples thereof include a trimethylsilyl group and a triphenylsilyl group), a carboxy group, a sulfonic acid group, and a phosphoric acid group.

### [Horizontal Alignment]

As described above, in the light absorption anisotropic film according to the embodiment of the present invention, the liquid crystal compound is horizontally aligned. Further, in the light absorption anisotropic film according to the embodiment of the present invention, it is preferable that the dichroic substance is also horizontally aligned along the liquid crystal compound.

Here, the horizontal alignment denotes that a molecular axis of the liquid crystal compound (for example, a major axis corresponds to the molecular axis in a case of a rod-like liquid crystal compound) is parallel to the main surface of the light absorption anisotropic film, but the axis is not required to be strictly parallel to the surface, and the tilt angle between an average molecular axis of the liquid crystal compound in the light absorption anisotropic film and the main surface of the light absorption anisotropic film is less than ±10°. Further, the tilt angle can be measured using AxoScan OPMF-1 (manufactured by Opto Science, Inc.).

Specifically, an extinction coefficient ko [λ] (in-plane direction) and an extinction coefficient ke [X] (thickness direction) are calculated using AxoScan OPMF-1 (manufactured by Opto science, Inc.) by measuring the Mueller matrix of the light absorption anisotropic film at a wavelength λ and at room temperature while the polar angle is changed from −50° to 50° by 10°, removing the influence of the surface reflection, and fitting the result to the following theoretical formula in consideration of the Snell's formula and Fresnel's equations. Unless otherwise specified, the wavelength λ is 550 nm.

k=−log(T)×λ/(4πd)

Here, T represents the transmittance, and d represents the thickness of the polarizer.

By calculating the absorbance and the dichroic ratio in the in-plane direction and the thickness direction based on the calculated ko [λ] and ke [λ], it can be confirmed whether the liquid crystal compound and the dichroic substance are horizontally aligned.

### [Method of Producing Light Absorption Anisotropic Film]

The method of producing the light absorption anisotropic film according to the embodiment of the present invention is not particularly limited, but a method of sequentially performing a step of coating an alignment film with the above-described liquid crystal composition to form a coating film (hereinafter, also referred to as “coating film forming step”) and a step of aligning liquid crystal components contained in the coating film (hereinafter, also referred to as “aligning step”) in this order (hereinafter, also referred to as “present production method”) is preferable from the viewpoint that the alignment degree of the light absorption anisotropic film to be obtained is further increased.

Further, the liquid crystal component is a component that contains not only the liquid crystal compound described above but also a dichroic substance having liquid crystallinity.

Hereinafter, each step will be described.

### <Coating Film Forming Step>

The coating film forming step is a step of coating the alignment film with the above-described liquid crystal composition to form a coating film. The liquid crystal compound in the coating film is horizontally aligned due to an interaction between the alignment film and an interface improver (in a case where the liquid crystal composition contains an interface improver).

The alignment film is easily coated with the liquid crystal composition by using the liquid crystal composition containing the above-described solvent or using a liquid-like material such as a melt obtained by heating the liquid crystal composition.

Examples of the method of coating the base material with the liquid crystal composition include known methods such as a roll coating method, a gravure printing method, a spin coating method, a wire bar coating method, an extrusion coating method, a direct gravure coating method, a reverse gravure coating method, a die coating method, a spraying method, and an ink jet method.

### (Alignment Film)

An alignment film may be any film as long as the film allows the liquid crystal compound contained in the liquid crystal composition to be horizontally aligned.

An alignment film can be provided by means such as a rubbing treatment performed on a film surface of an organic compound (preferably a polymer), oblique vapor deposition of an inorganic compound, formation of a layer having microgrooves, or accumulation of an organic compound (such as -tricosanoic acid, dioctadecylmethylammonium chloride, or methyl stearylate) using a Langmuir-Blodgett method (LB film). Further, an alignment film in which an alignment function is generated by application of an electric field, application of a magnetic field, or irradiation with light is also known. Among these, in the present invention, an alignment film formed by performing a rubbing treatment is preferable from the viewpoint of easily controlling the pretilt angle of the alignment film, and a photo-alignment film formed by irradiation with light is also preferable from the viewpoint of the uniformity of alignment.

### (1) Rubbing Treatment Alignment Film

A polymer material used for the alignment film formed by performing a rubbing treatment is described in a plurality of documents, and a plurality of commercially available products can be used. In the present invention, polyvinyl alcohol or polyimide and derivatives thereof are preferably used. The alignment film can refer to the description on page 43, line 24 to page 49, line 8 of WO2001/88574A1. The thickness of the alignment film is preferably in a range of 0.01 to 10 μm and more preferably in a range of 0.01 to 1 μm.

### (2) Photo-Alignment Film

A photo-alignment material used for an alignment film formed by irradiation with light is described in a plurality of documents. In the present invention, preferred examples thereof include azo compounds described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B, aromatic ester compounds described in JP2002-229039A, maleimide and/or alkenyl-substituted nadiimide compounds having a photo-alignment unit described in JP2002-265541A and JP2002-317013A, photocrosslinkable silane derivatives described in JP4205195B and JP4205198B, and photocrosslinkable polyimides, polyamides, or esters described in JP2003-520878A, JP2004-529220A, and JP4162850B. Among these, the azo compounds, the photocrosslinkable polyimides, the polyamides, or the esters are more preferable.

The photo-alignment film formed of the above-described material is irradiated with linearly polarized light or non-polarized light to produce a photo-alignment film.

In the present specification, the “irradiation with linearly polarized light” and the “irradiation with non-polarized light” are operations for causing a photoreaction in the photo-alignment material. The wavelength of the light to be used varies depending on the photo-alignment material to be used and is not particularly limited as long as the wavelength is required for the photoreaction. The peak wavelength of light to be used for irradiation with light is preferably in a range of 200 nm to 700 nm, and ultraviolet light having a peak wavelength of 400 nm or less is more preferable.

Examples of the light source used for light irradiation include commonly used light sources, for example, lamps such as a tungsten lamp, a halogen lamp, a xenon lamp, a xenon flash lamp, a mercury lamp, a mercury xenon lamp, or a carbon arc lamp, various lasers [such as a semiconductor laser, a helium neon laser, an argon ion laser, a helium cadmium laser, and a yttrium aluminum garnet (YAG) laser], a light emitting diode, and a cathode ray tube.

As means for obtaining linearly polarized light, a method of using a polarizing plate (for example, an iodine polarizing plate, a dichroic substance polarizing plate, or a wire grid polarizing plate), a method of using a prism-based element (for example, a Glan-Thompson prism) or a reflective type polarizer for which a Brewster's angle is used, or a method of using light emitted from a laser light source having polarized light can be employed. Further, only light having a required wavelength may be selectively applied using a filter, a wavelength conversion element, or the like.

In a case where light to be applied is linearly polarized light, a method of applying light vertically or obliquely to the upper surface of the alignment film or the surface of the alignment film from the rear surface is employed. The incidence angle of light varies depending on the photo-alignment material, but is preferably in a range of 0° to 90° (vertical) and more preferably in a range of 40° to 90°.

In a case where light to be applied is non-polarized light, the alignment film is irradiated with non-polarized light obliquely. The incidence angle is preferably in a range of 10° to 80°, more preferably in a range of 20° to 60°, and particularly preferably in a range of 30° to 50°.

The irradiation time is preferably in a range of 1 minute to 60 minutes and more preferably in a range of 1 minute to 10 minutes.

In a case where patterning is required, a method of performing irradiation with light using a photomask as many times as necessary for pattern preparation or a method of writing a pattern by laser light scanning can be employed.

### <Aligning Step>

The aligning step is a step of aligning the dichroic substance contained in the coating film. In this manner, the light absorption anisotropic film according to the embodiment of the present invention can be obtained. In the aligning step, the dichroic substance is considered to be aligned along the liquid crystal compound aligned by the alignment film.

The aligning step may include a drying treatment. Components such as a solvent can be removed from the coating film by performing the drying treatment. The drying treatment may be performed by a method of allowing the coating film to stand at room temperature for a predetermined time (for example, natural drying) or a method of heating the coating film and/or blowing air to the coating film.

Here, the dichroic substance contained in the liquid crystal composition may be aligned by performing the above-described coating film forming step or drying treatment. For example, in an embodiment in which the liquid crystal composition is prepared as a coating solution containing a solvent, the light absorption anisotropic film according to the embodiment of the present invention may be obtained by drying the coating film and removing the solvent from the coating film so that the dichroic substance contained in the coating film is aligned.

It is preferable that the aligning step includes a heat treatment. In this manner, the dichroic substance contained in the coating film is more aligned, and the alignment degree of the light absorption anisotropic film to be obtained is further increased.

From the viewpoint of the manufacturing suitability, the heating temperature is preferably in a range of 10° C. to 250° C. and more preferably 25° C. to 190° C. Further, the heating time is preferably in a range of 1 to 300 seconds and more preferably in a range of 1 to 60 seconds.

The aligning step may include a cooling treatment performed after the heat treatment. The cooling treatment is a treatment of cooling the coating film after being heated to room temperature (20° C. to 25° C.). In this manner, the alignment of the dichroic substance contained in the coating film is further fixed, and the alignment degree of the light absorption anisotropic film to be obtained is further increased. The cooling means is not particularly limited and can be performed according to a known method.

The light absorption anisotropic film according to the embodiment of the present invention can be obtained by performing the above-described steps.

### [Other Steps]

The present production method may include a step of curing the light absorption anisotropic film after the aligning step (hereinafter, also referred to as “curing step”).

The curing step is performed by, for example, heating the film and/or irradiating (exposing) the film with light. Between these, it is preferable that the curing step is performed by irradiating the film with light.

Various light sources such as infrared rays, visible light, and ultraviolet rays can be used as the light source for curing, but ultraviolet rays are preferable. In addition, ultraviolet rays may be applied while the film is heated during curing, or ultraviolet rays may be applied through a filter that transmits only a specific wavelength.

Further, the exposure may be performed under a nitrogen atmosphere. In a case where the curing of the light absorption anisotropic film proceeds by radical polymerization, since the inhibition of polymerization by oxygen is reduced, it is preferable that exposure is performed in a nitrogen atmosphere. ps [Liquid Crystal Composition]

The liquid crystal composition according to the embodiment of the present invention is a liquid crystal composition containing a liquid crystal compound, a dichroic substance, and a boronic acid compound containing a polymerizable group, and the boronic acid compound containing a polymerizable group is a compound represented by Formula (B-2).

The components that are contained or can be contained in the liquid crystal composition according to the embodiment of the present invention are the same as the components that are contained or can be contained in the above-described liquid crystal composition used to form the light absorption anisotropic film according to the embodiment of the present invention and preferred embodiments thereof are the same as described above. Therefore, description thereof will not be repeated.

The liquid crystal composition according to the embodiment of the present invention is suitably used to form the above-described light absorption anisotropic film.

### [Laminate]

The laminate according to the embodiment of the present invention includes the above-described light absorption anisotropic film according to the embodiment of the present invention and a layer containing a polyvinyl alcohol-based resin disposed in contact with the above-described light absorption anisotropic film.

Further, the laminate according to the embodiment of the present invention may include a λ/4 plate on a side of the light absorption anisotropic film opposite to the layer containing a polyvinyl alcohol-based resin. Further, the laminate according to the embodiment of the present invention may include a barrier layer between the light absorption anisotropic film and the λ/4 plate.

In addition, the laminate according to the embodiment of the present invention may include a base material on a side of the light absorption anisotropic film opposite to the layer containing a polyvinyl alcohol-based resin.

Hereinafter, each layer constituting the laminate according to the embodiment of the present invention will be described.

### [Base Material]

The base material can be appropriately selected, and examples thereof include glass and a polymer film. The light transmittance of the base material is preferably 80% or greater.

In a case where a polymer film is used as the base material, it is preferable to use an optically isotropic polymer film. As specific examples and preferred embodiments of the polymer, the description in paragraph of JP2002-22942A can be applied. Further, even in a case of a polymer easily exhibiting the birefringence such as polycarbonate and polysulfone which has been known in the related art, a polymer with the exhibiting property which has been decreased by modifying the molecules described in WO2000/26705A can be used.

### [Layer Containing Polyvinyl Alcohol-Based Resin]

It is preferable that the layer containing a polyvinyl alcohol-based resin is an alignment film. Since the alignment film is as described above, the description thereof will not be repeated.

The polyvinyl alcohol-based resin is a resin having a repeating unit of —CH₂—CHOH—, and examples thereof include polyvinyl alcohol and an ethylene-vinyl alcohol copolymer.

The polyvinyl alcohol-based resin can be obtained, for example, by saponifying a polyvinyl acetate-based resin. Examples of the polyvinyl acetate-based resin include polyvinyl acetate which is a homopolymer of vinyl acetate, and a copolymer of vinyl acetate and other monomers copolymerizable with the vinyl acetate.

Examples of the other monomers copolymerizable with vinyl acetate include unsaturated carboxylic acids, olefins, vinyl ethers, unsaturated sulfonic acids, and acrylamides containing an ammonium group.

At least one hydroxy group of the polyvinyl alcohol-based resin may be modified with a functional group such as an acetoacetyl group, a sulfonic acid group, a carboxy group, and an oxyalkylene group. That is, the polyvinyl alcohol-based resin may be a so-called modified polyvinyl alcohol-based resin.

Further, examples of the modified polyvinyl alcohol-based resin include a polyvinyl alcohol-based resin containing a polymerizable group (for example, a (meth)acryloyl group or a vinyl group).

Therefore, the polyvinyl alcohol-based resin includes an unmodified polyvinyl alcohol-based resin and a modified polyvinyl alcohol-based resin.

The content of the polyvinyl alcohol-based resin in the alignment film is not particularly limited, but it is preferable that the polyvinyl alcohol-based resin is contained in the alignment film as a main component. The main component denotes that the content of the polyvinyl alcohol-based resin is 50% by mass or greater with respect to the total mass of the alignment film. The content of the polyvinyl alcohol-based resin is preferably 90% by mass or greater with respect to the total mass of the alignment film. The upper limit thereof is not particularly limited, but is 99.9% by mass or less in many cases.

### [Light Absorption Anisotropic Film]

Since the light absorption anisotropic film (light absorption anisotropic layer) according to the embodiment of the present invention is as described above, the description thereof will not be repeated. In the present invention, the light absorption anisotropic film may be referred to as a polarizer.

### [λ/4 Plate]

A “λ/4 plate” is a plate having a λ/4 function, specifically, a plate having a function of converting linearly polarized light having a specific wavelength into circularly polarized light (or converting circularly polarized light into linearly polarized light).

Specific examples of an aspect in which a λ/4 plate has a single-layer structure include a stretched polymer film and a retardation film in which a light absorption anisotropic film having a λ/4 function is provided on a support. Further, specific examples of an aspect in which a λ/4 plate has a multilayer structure include a broadband λ/4 plate obtained by laminating a k/4 plate and a λ/2 plate.

The λ/4 plate and the polarizer according to the embodiment of the present invention may be provided by coming into contact with each other, or another layer may be provided between the λ/4 plate and the light absorption anisotropic film according to the embodiment of the present invention. Examples of such a layer include a pressure sensitive adhesive layer or an adhesive layer for ensuring the adhesiveness, and a barrier layer.

### [Barrier Layer]

In a case where the laminate of the present invention comprises a barrier layer, the barrier layer is provided between the polarizer according to the embodiment of the present invention and the λ/4 plate. Further, in a case where a layer other than the barrier layer (for example, a pressure sensitive adhesive layer or an adhesive layer) is provided between the polarizer according to the embodiment of the present invention and the λ/4 plate, the barrier layer can be provided, for example, between the light absorption anisotropic film according to the embodiment of the present invention and the layer other than the barrier layer.

The barrier layer is also referred to as a gas-shielding layer (oxygen-shielding layer) and has a function of protecting the light absorption anisotropic film according to the embodiment of the present invention from gas such as oxygen in the atmosphere, the moisture, or the compound contained in an adjacent layer.

The barrier layer can refer to, for example, the description in paragraphs [0014] to [0054] of JP2014-159124A, paragraphs [0042] to [0075] of JP2017-121721A, paragraphs [0045] to [0054] of JP2017-115076A, paragraphs [0010] to [0061] of JP2012-213938A, and paragraphs [0021] to [0031] of JP2005-169994A.

### [Applications]

The laminate of the present invention can be used as a polarizer (polarizing plate) or the like, for example, as a linear polarizing plate or a circularly polarizing plate.

In a case where the laminate of the present invention does not include an optically anisotropic layer such as the λ/4 plate, the laminate can be used as a linear polarizing plate.

Meanwhile, in a case where the laminate according to the embodiment of the present invention includes the λ/4 plate, the laminate can be used as a circularly polarizing plate.

### [Image Display Device]

An image display device according to the embodiment of the present invention includes the above-described light absorption anisotropic film according to the embodiment of the present invention or the above-described laminate according to the embodiment of the present invention.

The display element used in the image display device according to the embodiment of the present invention is not particularly limited, and examples thereof include a liquid crystal cell, an organic electroluminescence (hereinafter, abbreviated as “EL”) display panel, and a plasma display panel.

Among these, a liquid crystal cell or an organic EL display panel is preferable, and a liquid crystal cell is more preferable. That is, in the image display device according to the embodiment of the present invention, a liquid crystal display device formed of a liquid crystal cell as a display element or an organic EL display device formed of an organic EL display panel as a display element is preferable, and a liquid crystal display device is more preferable.

### [Liquid Crystal Display Device]

As a liquid crystal display device which is an example of the image display device according to the embodiment of the present invention, an aspect of a liquid crystal display device including the above-described light absorption anisotropic film according to the embodiment of the present invention and a liquid crystal cell is preferably exemplified. A liquid crystal display device including the above-described laminate of the present invention (here, the laminate does not include a λ/4 plate) and a liquid crystal cell is more suitable.

In the present invention, between the polarizers provided on both sides of the liquid crystal cell, it is preferable that the laminate of the present invention is used as a front-side polarizer and more preferable that the laminate of the present invention is used as a front-side polarizer and a rear-side polarizer.

Hereinafter, the liquid crystal cell constituting the liquid crystal display device will be described in detail.

### <Liquid Crystal Cell>

It is preferable that the liquid crystal cell used for the liquid crystal display device is in a vertical alignment (VA) mode, an optically compensated bend (OCB) mode, an in-plane- switching (IPS) mode, or a twisted nematic (TN) mode, but the present invention is not limited thereto.

In the liquid crystal cell in a TN mode, rod-like liquid crystal molecules are substantially horizontally aligned at the time of no voltage application and further twisted aligned at 60° to 120°. The liquid crystal cell in a TN mode is most likely used as a color thin film transistor (TFT) liquid crystal display device and is described in multiple documents.

In the liquid crystal cell in a VA mode, rod-like liquid crystal molecules are substantially vertically aligned at the time of no voltage application. The concept of the liquid crystal cell in a VA mode includes (1) a liquid crystal cell in a VA mode in a narrow sense where rod-like liquid crystal molecules are aligned substantially vertically at the time of no voltage application and substantially horizontally at the time of voltage application (described in JP1990-176625A (JP-H02-176625A)), (2) a liquid crystal cell (in an MVA mode) (SID97, described in Digest of tech. Papers (proceedings) 28 (1997) 845) in which the VA mode is formed to have multi-domain in order to expand the viewing angle, (3) a liquid crystal cell in a mode (n-ASM mode) in which rod-like liquid crystal molecules are substantially vertically aligned at the time of no voltage application and twistedly multi-domain aligned at the time of voltage application (described in proceedings of Japanese Liquid Crystal Conference, pp. 58 to 59 (1998)), and (4) a liquid crystal cell in a SURVIVAL mode (presented at LCD International 98). Further, the liquid crystal cell may be of any of a patterned vertical alignment (PVA) type, a photo-alignment (optical alignment) type, or a polymer-sustained alignment (PSA) type. The details of these modes are described in JP2006-215326A and JP2008-538819A.

In the liquid crystal cell in an IPS mode, rod-like liquid crystal molecules are aligned substantially parallel to the substrate, and the liquid crystal molecules respond planarly through application of an electric field parallel to the substrate surface. In the IPS mode, black display is carried out in a state where no electric field is applied, and absorption axes of a pair of upper and lower polarizing plates are orthogonal to each other. A method of reducing leakage light during black display in an oblique direction and improve the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), and JP1998-307291A (JP-H10-307291A).

### [Organic EL Display Device]

As an organic EL display device which is an example of the image display device according to the embodiment of the present invention, an aspect of an organic EL display device including the above-described light absorption anisotropic film according to the embodiment of the present invention, a λ/4 plate, and an organic EL display panel in this order from the viewing side is suitably exemplified.

A form of a display device including the above-described laminate of the present invention which includes a λ/4 plate and an organic EL display panel in this order from the viewing side is more suitably exemplified. In this case, the laminate is formed such that a base material provided as necessary, an alignment film (layer containing a polyvinyl alcohol-based resin), the light absorption anisotropic film according to the embodiment of the present invention, a barrier layer provided as necessary, and a λ/4 plate are disposed in this order from the viewing side.

Further, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### EXAMPLES

Hereinafter, the present invention will be described in more detail with reference to examples. The materials, the used amounts, the ratios, the treatment contents, the treatment procedures, and the like described in the following examples can be appropriately changed without departing from the spirit of the present invention. Therefore, the scope of the present invention should not be limitatively interpreted by the following examples.

### Example 1

The laminate A of Example 1 was produced as follows.

### [Preparation of Cellulose Acylate Film 1]

A cellulose acylate film 1 was prepared in the following manner.

### <Preparation of Core Layer Cellulose Acylate Dope>

The following composition was put into a mixing tank and stirred to dissolve each component, thereby preparing a cellulose acetate solution used as a core layer cellulose acylate dope.

### Core Layer Cellulose Acylate Dope

Cellulose acetate having acetyl substitution degree of 2.88: 100 parts by mass
Polyester compound B described in example of JP2015-227955A: 12 parts by mass
Compound F shown below: 2 parts by mass
Methylene chloride (first solvent): 430 parts by mass
Methanol (second solvent): 64 parts by mass

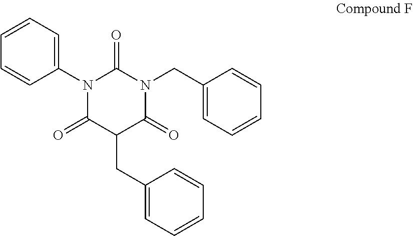 [SMILES: O=C1C(Cc2ccccc2)C(=O)N(c2ccccc2)C(=O)N1Cc1ccccc1]

### <Preparation of Outer Layer Cellulose Acylate Dope>

10 parts by mass of the following matting agent solution was added to 90 parts by mass of the above-described core layer cellulose acylate dope, thereby preparing a cellulose acetate solution used as an outer layer cellulose acylate dope.

### Matting Agent Solution

Silica particles with average particle size of 20 nm (AEROSIL R972, manufactured by Nippon Aerosil Co., Ltd.): 2 parts by mass
Methylene chloride (first solvent): 76 parts by mass
Methanol (second solvent): 11 parts by mass
Core layer cellulose acylate dope described above: 1 parts by mass

### <Preparation of Cellulose Acylate Film 1>

The core layer cellulose acylate dope and the outer layer cellulose acylate dope were filtered through filter paper having an average pore size of 34 μm and a sintered metal filter having an average pore size of 10 μm, and three layers which were the core layer cellulose acylate dope and the outer layer cellulose acylate dopes provided on both sides of the core layer cellulose acylate dope were simultaneously cast from a casting port onto a drum at 20° C. (band casting machine).

Next, the film was peeled off in a state where the solvent content was approximately 20% by mass, both ends of the film in the width direction were fixed by tenter clips, and the film was dried while being stretched at a stretching ratio of 1.1 times in the lateral direction.

Thereafter, the film was further dried by being transported between the rolls of the heat treatment device to prepare an optical film having a thickness of 40 μm, and the optical film was used as a cellulose acylate film 1. The in-plane retardation of the obtained cellulose acylate film 1 was 0 nm.

### [Preparation of Laminate A]

As described below, a laminate A including the cellulose acylate film 1, the photo-alignment layer PA1, the light absorption anisotropic layer P1, and the oxygen-shielding layer B1 adjacent to each other in this order was prepared.

### <Preparation of TAC Film Provided With Photo-Alignment Layer>

The cellulose acylate film 1 was continuously coated with a coating solution PA1 for forming an alignment layer described below with a wire bar. The support on which a coating film was formed was dried with hot air at 140° C. for 120 seconds, and the coating film was irradiated with polarized ultraviolet rays (10 mJ/cm 2 , using an ultra-high pressure mercury lamp) to form a photo-alignment layer PA1, thereby obtaining a TAC film provided with a photo-alignment layer.

### (Coating Solution PA1 for Forming Alignment Layer)

Polymer PAI shown below: 100.00 parts by mass
Acid generator SAN-AID SI-B3A: 12.00 parts by mass
DIPEA (N,N-diisopropylethylamine): 0.6 parts by mass
Methyl ethyl ketone: 665.00 parts by mass
Butyl acetate: 166.00 parts by mass

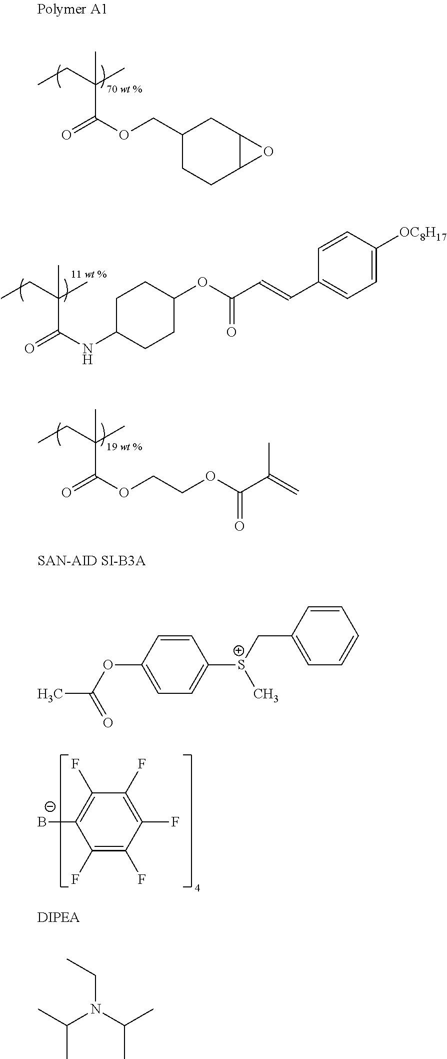

### <Formation of Light Absorption Anisotropic Layer P1>

A coating layer P1 was formed by continuously coating the photo-alignment layer PA1 of the obtained TAC film provided with a photo-alignment layer with the following liquid crystal composition P1 using a wire bar.

Next, the coating layer P1 was heated at 140° C. for 30 seconds, and the coating layer P1 was cooled to room temperature (23° C.).

Next, the coating layer P1 was heated at 80° C. for 60 seconds and cooled to room temperature again.

Thereafter, a light absorption anisotropic layer P1 (light absorption anisotropic film) was formed on the photo-alignment layer PA1 by irradiating the coating layer with light (central wavelength of 365 nm) of a light emitting diode (LED) for 2 seconds under an irradiation condition of an illuminance of 200 mW/cm². The thickness of the light absorption anisotropic layer P1 was 2.0 μm.

### Composition of Liquid Crystal Composition P1

Polymerizable boronic acid compound B1 shown below: 0.090 parts by mass
Polymer liquid crystal compound L1 shown below: 3.280 parts by mass
Low-molecular-weight liquid crystal compound LM1 shown below: 1.406 parts by mass
Dichroic substance Y1 shown below: 0.181 parts by mass
Dichroic substance M1 shown below: 0.278 parts by mass
Dichroic substance C1 shown below: 0.742 parts by mass
Surfactant F1 shown below: 0.060 parts by mass
Polymerization initiator Il (IRGACURE OXE-02, manufactured by BASF SE): 0.054 parts by mass
Tetrahydrofuran: 47.000 parts by mass
Cyclopentanone: 47.000 parts by mass

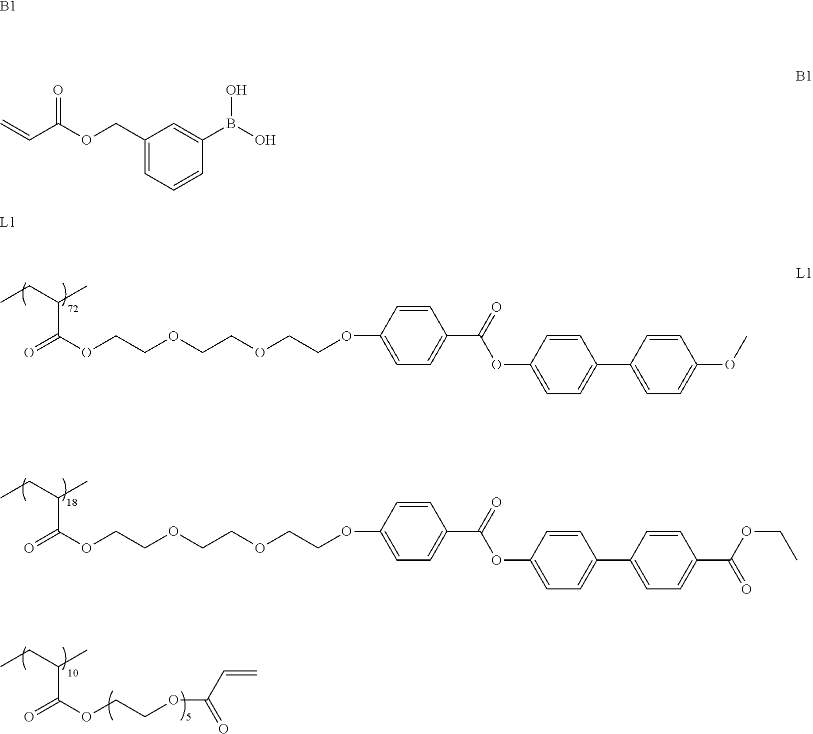

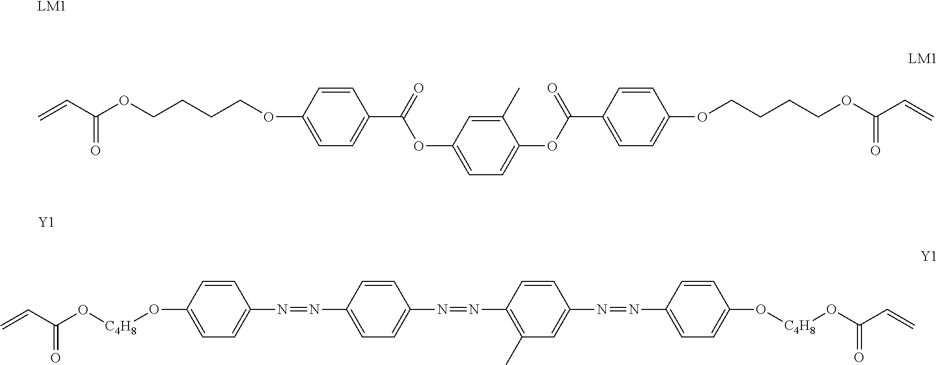

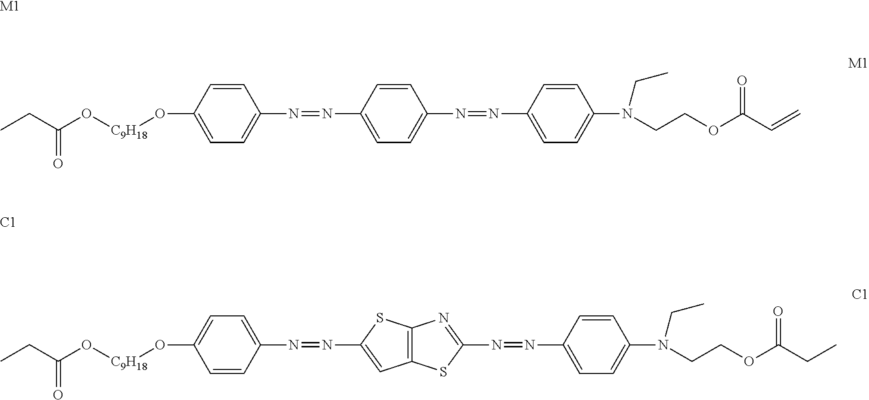

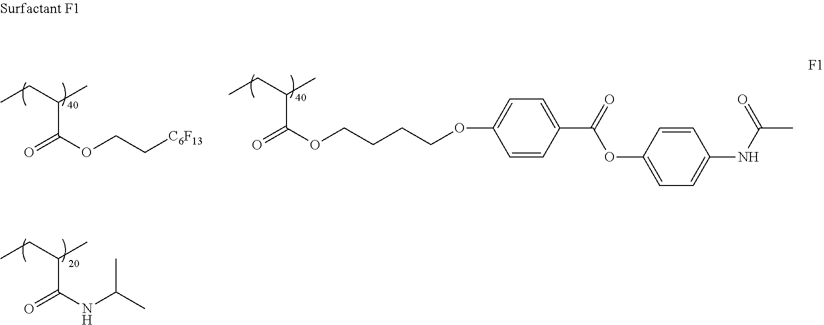

### <Formation of Oxygen-Shielding Layer B 1>

The formed light absorption anisotropic layer P1 was continuously coated with a coating solution having the following composition using a wire bar. Thereafter, the layer was dried with hot air at 100° C. for 2 minutes, thereby forming a polyvinyl alcohol (PVA) alignment layer (oxygen-shielding layer B1) having a thickness of 1.1 μm on the light absorption anisotropic layer N1.

### Composition of Composition B1 for Forming Oxygen-Shielding Layer

Modified polyvinyl alcohol shown below: 3.80 parts by mass
Initiator (IRGACURE 2959): 0.20 parts by mass
Water: 70 parts by mass
Methanol: 30 parts by mass

### Modified Polyvinyl Alcohol

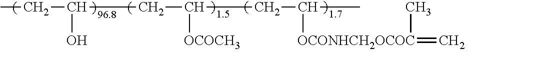

In this manner, the laminate A of Example 1, provided with the cellulose acylate film 1, the photo-alignment layer PA1, the light absorption anisotropic layer P1, and the oxygen-shielding layer B1 adjacent to each other in this order was obtained.

### Examples 2 to 13 and Comparative Examples 1 to 6

Each lamination of Examples 2 to 9 and Comparative Examples 1 to 5 was prepared by the same method as that for the laminate A of Example 1 except that the liquid crystal composition was changed to the liquid crystal composition having the composition listed in Table 1.

Each lamination of Examples 10 to 13 and Comparative Example 6 was prepared by the same method as that for the laminate A of Example 1 except that the liquid crystal composition was changed to the liquid crystal composition having the composition listed in Table 2.

The outline of the components contained in the liquid crystal composition used for preparing the laminates of Examples 2 to 13 and Comparative Examples 1 to 6 is shown below.

### Polymerizable Boronic Acid Compound (Structure Shown Below)

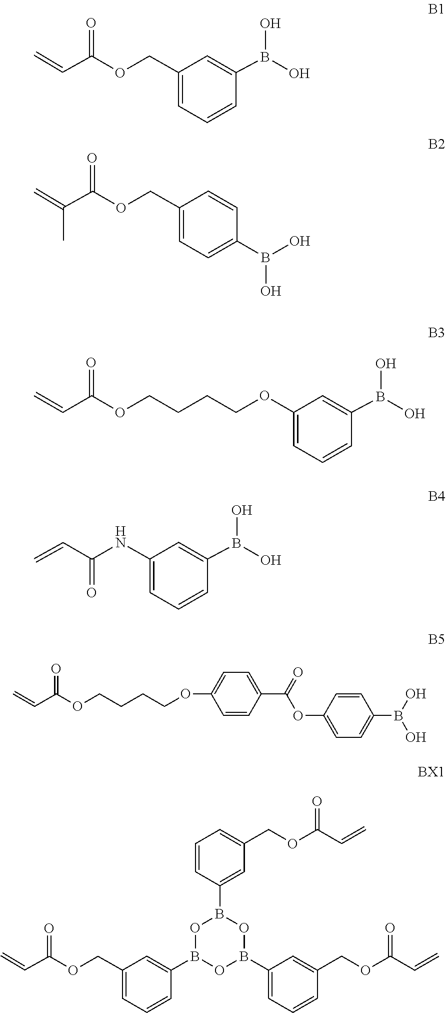 [SMILES: C=CC(=O)OCc1cccc(B(O)O)c1 ; C=C(C)C(=O)OCc1ccc(B(O)O)cc1 ; C=CC(=O)OCCCCOc1cccc(B(O)O)c1 ; C=CC(=O)Nc1cccc(B(O)O)c1 ; C=CC(=O)OCCCCOc1ccc(C(=O)Oc2ccc(B(O)O)cc2)cc1 ; C=CC(=O)OCc1cccc(B2OB(c3cccc(COC(=O)C=C)c3)OB(c3cccc(COC(=O)C=C)c3)O2)c1]

Compounds other than polymerizable boronic acid compound (that is, compounds containing no polymerizable group but containing boronic acid group or boronic acid ester group or compounds containing polymerizable group but not containing boronic acid group and boronic acid ester group)

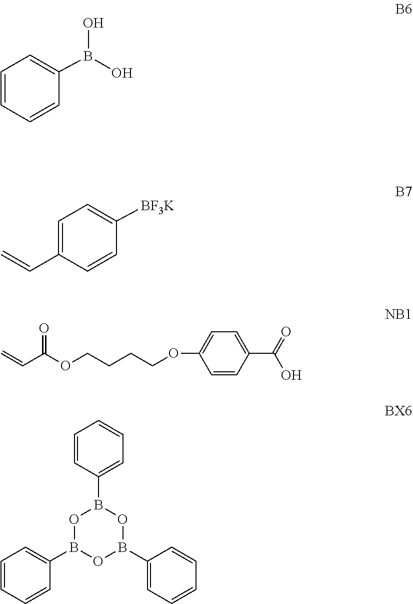

### Liquid Crystal Compound (Structure Shown Below)

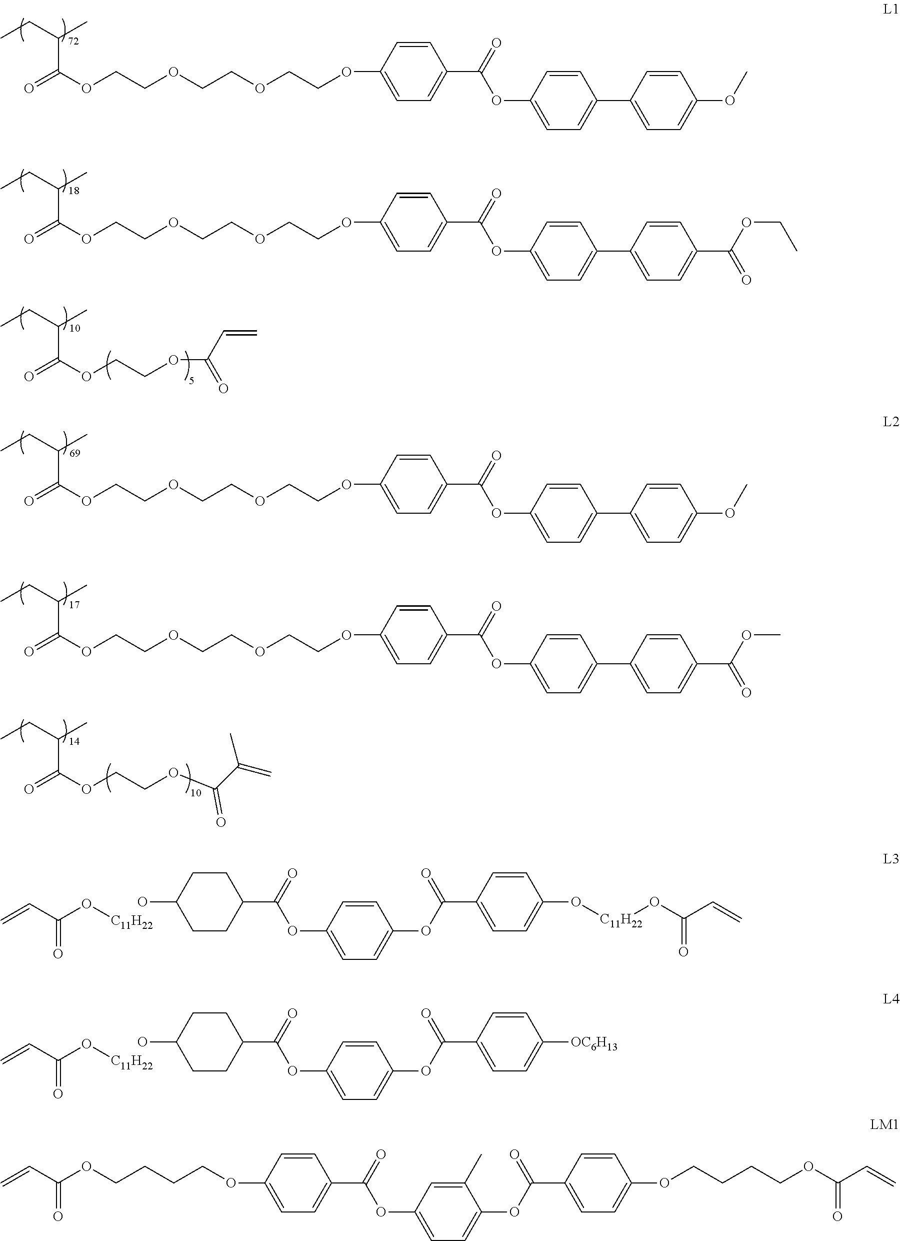

### Dichroic Substance (Structure Shown Below)

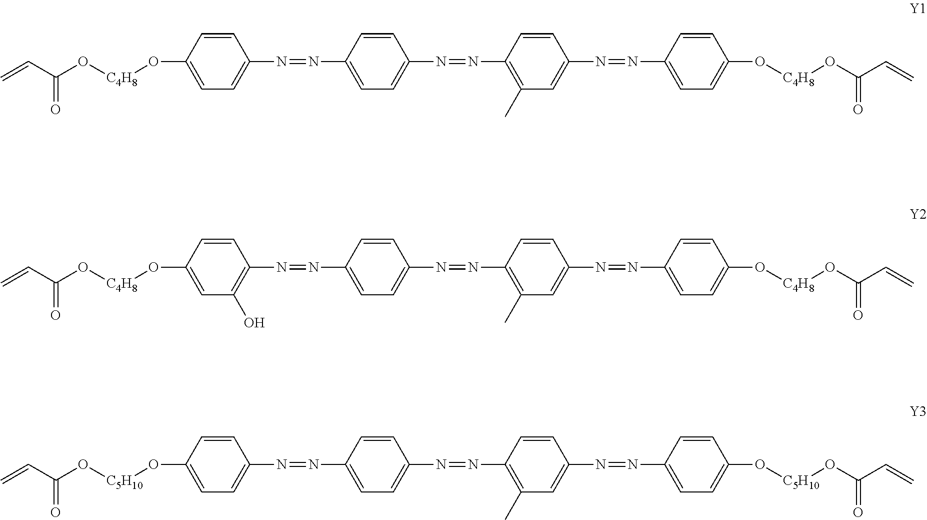

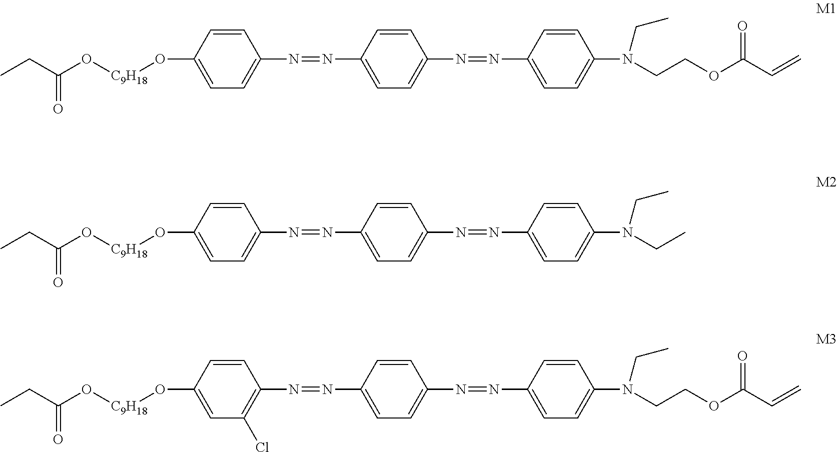

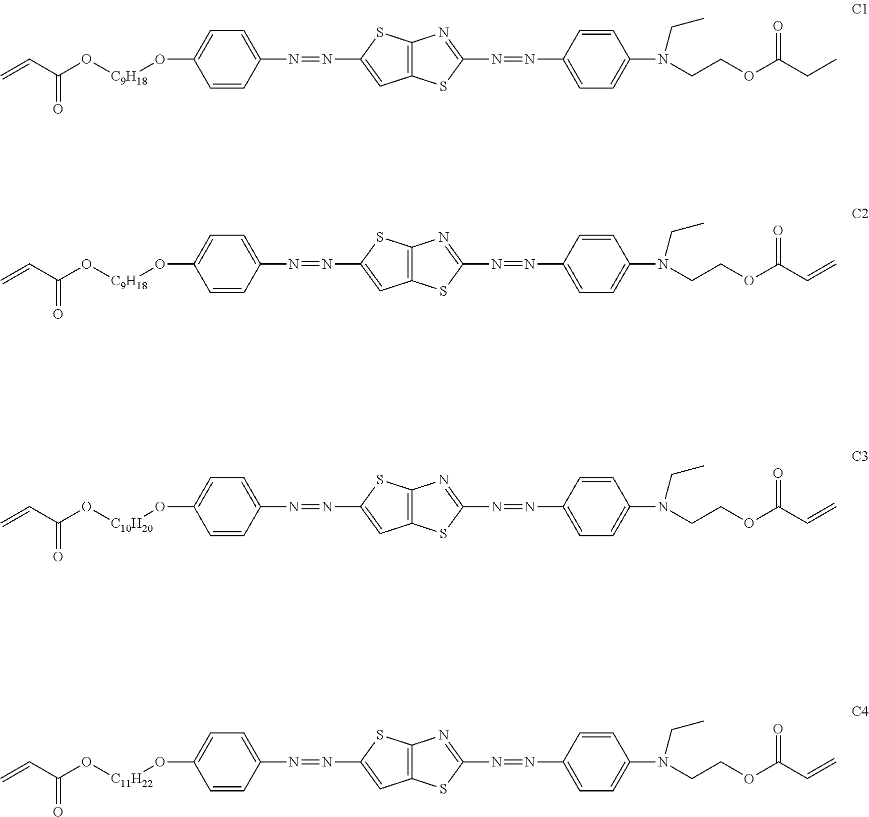

### Surfactant (Structure Shown Below)

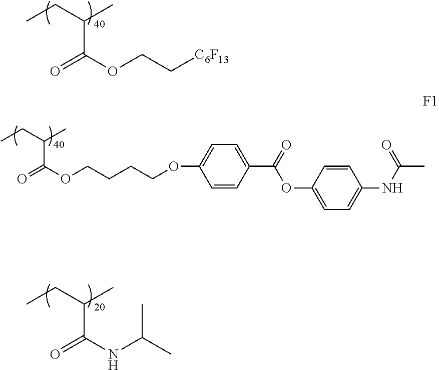

Polymerization initiator I1: IRGACURE OXE-02, manufactured by BASF SE

Tetrahydrofuran (solvent)

Cyclopentanone (solvent)

### (Synthesis of Polymerizable Boronic Acid Compound B1)

The polymerizable boronic acid compound B1 was synthesized as follows. In the following formula, Et represents an ethyl group.

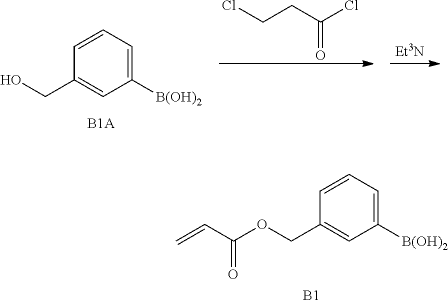

30.0 g of m-hydroxymethylphenylboronic acid (see Formula (B1A)), 0.308 g of 2,2,6,6-tetramethylpiperidine-1-oxyl free radical (TEMPO, manufactured by Wako Pure Chemical Industries, Ltd.), 65 mL of DMAc (N,N-dimethylacetamide, manufactured by Wako Pure Chemical Industries, Ltd.), and 100 mL of methyl isobutyl ketone were added to a three-neck flask, 50.13 g of 3-chloropropionyl chloride was added dropwise to this solution such that the internal temperature thereof did not exceed 30° C., and the solution was stirred at an internal temperature of 30° C. to 40° C. for 4 hours. The reaction solution was sequentially washed with 100 g of 5% saline solution and 120 g of 5% saline solution at an internal temperature of 30° C. to 35° C.

0.154 g of 2,2,6,6-tetramethylpiperidine 1-oxyl free radical (TEMPO, manufactured by Wako Pure Chemical Industries, Ltd.) was added to the washed organic layer, 40.00 g of triethylamine (manufactured by Wako Pure Chemical Industries, Ltd.) was added dropwise thereto such that the internal temperature thereof did not exceed 50° C., and the solution was stirred at an internal temperature of 60° C. for 1 hour.

Subsequently, the reaction solution was sequentially washed twice with 120 g of 10% saline solution, a mixed solution of 5 mL of concentrated hydrochloric acid and 85 mL of water, 120 g of a 5% sodium acetate aqueous solution, and 120 g of water at an internal temperature of to 35° C.

0.52 g of p-methoxyphenol, 90 mL of water, and 75 mL of heptane were added to the obtained organic layer at an internal temperature of 30° C. to 35° C. This solution was cooled to a range of 0° C. to 5° C. over 1 hour, and 150 mL of heptane was added dropwise to the solution while the internal temperature was maintained at 0° to 5° C. to precipitate crystals. The solution was stirred for 1 hour at an internal temperature of 0° C. to 5° C., and crystals were collected by filtration and sequentially washed with 150 mL of cooled heptane and 150 mL of cooled water in which 0.23 g of p-methoxyphenol was dissolved.

The obtained crystals were blast-dried at room temperature (23° C.), thereby obtaining a polymerizable boronic acid compound B1 as a white solid (29.6 g, yield: 72%).

### (Synthesis of Polymerizable Boronic Acid Compound BX1)

The polymerizable boronic acid compound BX1 was synthesized as follows. In the following formula, Et represents an ethyl group.

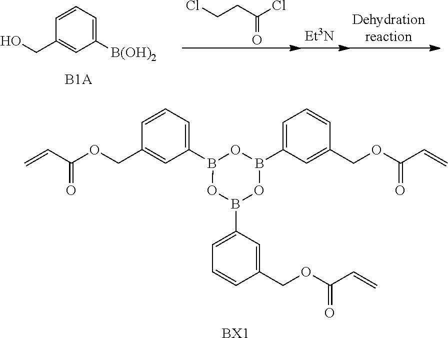

30.0 g of m-hydroxymethylphenylboronic acid (see Formula (B1A)), 0.308 g of 2,2,6,6-tetramethylpiperidine-1-oxyl free radical (TEMPO, manufactured by Wako Pure Chemical Industries, Ltd.), 65 mL of DMAc (N,N-dimethylacetamide, manufactured by Wako Pure Chemical Industries, Ltd.), and 100 mL of methyl isobutyl ketone were added to a three-neck flask, 50.13 g of 3-chloropropionyl chloride was added dropwise to this solution such that the internal temperature thereof did not exceed 30° C., and the solution was stirred at an internal temperature of 30° C. to 40° C. for 4 hours. The reaction solution was sequentially washed with 100 g of 5% saline solution and 120 g of 5% saline solution at an internal temperature of 30° C. to 35° C.

0.154 g of 2,2,6,6-tetramethylpiperidine 1-oxyl free radical (TEMPO, manufactured by Wako Pure Chemical Industries, Ltd.) was added to the washed organic layer, 40.00 g of triethylamine (manufactured by Wako Pure Chemical Industries, Ltd.) was added dropwise thereto such that the internal temperature thereof did not exceed 50° C., and the solution was stirred at an internal temperature of 60° C. for 1 hour.

Subsequently, the reaction solution was sequentially washed twice with 120 g of 10% saline solution, a mixed solution of 5 mL of concentrated hydrochloric acid and 85 mL of water, 120 g of a 5% sodium acetate aqueous solution, and 120 g of water at an internal temperature of 30° C. to 35° C.

0.52 g of p-methoxyphenol, 90 mL of water, and 75 mL of heptane were added to the obtained organic layer at an internal temperature of 30° C. to 35° C. This solution was cooled to a range of 0° C. to 5° C. over 1 hour, and 150 mL of heptane was added dropwise to the solution while the internal temperature was maintained at 0° to 5° C. to precipitate crystals. The solution was stirred for 1 hour at an internal temperature of 0° C. to 5° C., and crystals were collected by filtration and sequentially washed with 150 mL of cooled heptane and 150 mL of cooled water in which 0.23 g of p-methoxyphenol was dissolved.

The obtained crystals were blast-dried at 55° C. for 48 hours and subjected to a dehydration-condensation reaction, thereby obtaining a polymerizable boronic acid compound BX1 as a white solid (25.5 g, yield: 68%).

### [Evaluation Test]

The following evaluations were performed using the laminates of the examples and the comparative examples obtained as described above.

Further, as a result of evaluation performed on the light absorption anisotropic layers included in the laminates of each example by the method of evaluating horizontal alignment described above, all the light absorption anisotropic layers included in the laminates of each example were formed such that the polymer liquid crystal compound and the dichroic substance were horizontally aligned.

### [Alignment Degree]

Each laminate of the examples and the comparative examples was set on a sample table in a state where a linear polarizer was inserted on a light source side of an optical microscope (product name, “ECLIPSE E600 POL”, manufactured by Nikon Corporation), the absorbance of the light absorption anisotropic layer in a wavelength range of 380 nm to 780 nm was measured at a pitch of 1 nm using a multi-channel spectroscope (product name, “QE65000”, manufactured by Ocean Optics, Inc.), and the alignment degree in a wavelength range of 400 nm to 700 nm was calculated according to the following equation. Based on the obtained alignment degree, the alignment degree was evaluated according to the following evaluation standards.

Alignment degree: S=((Az0/Ay0)−1)/((Az0/Ay0)+2)

In the equation described above, “Az0” represents the absorbance of the light absorption anisotropic layer with respect to the polarized light in the absorption axis direction, and “Ay0” represents the absorbance of the light absorption anisotropic layer with respect to the polarized light in the transmittance axis direction.
A: The alignment degree was 0.93 or greater
B: The alignment degree was 0.90 or greater and less than 0.93
C: The alignment degree was less than 0.90

### [Adhesiveness]

Cellophane tape was attached to the laminate obtained in each example and each comparative example on an oxygen-shielding layer side, the cellophane tape was peeled off in a vertical direction, the state where the cellophane tape was peeled off from the laminate was visually observed, and the following evaluation was performed. The cross section of the measurement sample in which the peeling occurred was observed with an optical microscope, and it was confirmed that the peeling occurred at the interface between the light absorption anisotropic layer and the oxygen-shielding layer.
A: The oxygen-shielding layer was peeled off in a region equal to or less than half of the portion where the cellophane tape was attached.
B: The oxygen-shielding layer was peeled off in a region exceeding half of the portion where the cellophane tape was attached, but a part of the oxygen-shielding layer was not peeled off.
C: The oxygen-shielding layer was peeled off from the entire surface of the portion where the cellophane tape was attached.

### [Liquid Stability]

The liquid stability of the liquid crystal compositions used in Examples 10 to 13 and Comparative Example 6 was evaluated. Specifically, the liquid crystal composition prepared in each example was allowed to stand at room temperature (23° C.) for 24 hours, and the presence or absence of crystal precipitation was visually confirmed. The evaluation standards are as follows.
A: The precipitate was not visually found.
B: A trace amount of precipitate was visually found.
C: The precipitate was visually found in the entire region.

The results of the evaluation tests described above are listed in Tables 1 and 2.

In Table 1, “mass ratio (% by mass) with respect to total solid content” in the column of the polymerizable boronic acid compound denotes the content (% by mass) of the polymerizable boronic acid compound with respect to the total mass of the solid content of the liquid crystal composition. Further, “mass ratio (% by mass) with respect to total solid content” in the column of the compound other than the polymerizable boronic acid compound denotes the content (% by mass) of the compound other than the polymerizable boronic acid compound with respect to the total mass of the solid content of the liquid crystal composition.

In Table 2, “mass ratio (% by mass) with respect to total solid content” in the column of the polymerizable boronic acid compound 1 and the polymerizable boronic acid compound 2 denotes the content (% by mass) of the polymerizable boronic acid compound 1 or the polymerizable boronic acid compound 2 with respect to the total mass of the solid content of the liquid crystal composition. Further, “mass ratio (% by mass) with respect to total solid content” in the column of the compound other than the polymerizable boronic acid compound denotes the content (% by mass) of the compound other than the polymerizable boronic acid compound with respect to the total mass of the solid content of the liquid crystal composition.

TABLE 1

| | | | | Compounds other than | | | | | | | | | | | | | | | | | | | | |
|---|---|---|---|---|---|---|---|---|---|---|---|---|---|---|---|---|---|---|---|---|---|---|---|---|
| | Polymerizable boronic acid | | | polymerizable boronic | | | | | Low- | | | | | | | | | | | | | | | |
| | compound | | | acid compound | | | | | molecular | | | | | | | | | | | | | | | |
| | | | Mass ratio | | | Mass ratio | Polymer | | weight | | | | | | | | | | | | | | | |
| | | | with respect | | | with respect | liquid | | liquid | | | | | | | | | | Polymeri- | | | | | |
| | | | to total | | | to total | crystal | | crystal | | Dichroic | | Dichroic | | Dichroic | | | | zation | | | | | |
| | | | solid | | | solid | compound | | compound | | substance | | substance | | substance | | Surfactant | | initiator | | | | | |
| | | Parts | content | | Parts | content | | Parts | | Parts | | Parts | | Parts | | Parts | | Parts | | Parts | Tetrahydro- | Cyclo- | Align- | |
| | | by | (% by | | by | (% by | | by | | by | | by | | by | | by | | by | | by | furan | pentanone | ment | Adhesive- |
| | Type | mass | mass) | Type | mass | mass) | Type | mass | Type | mass | Type | mass | Type | mass | Type | mass | Type | mass | Type | mass | Parts by mass | Parts by mass | degree | ness |
| Example 1 | B1 | 0.091 | 1.500 | — | | — | L1 | 3.280 | LM1 | 1.406 | Y1 | 0.181 | M1 | 0.278 | C1 | 0.742 | F1 | 0.060 | I1 | 0.054 | 47.000 | 47.000 | A | A |
| Example 2 | B1 | 0.186 | 3.000 | — | | — | L1 | 3.281 | LM1 | 1.406 | Y2 | 0.181 | M2 | 0.278 | C2 | 0.743 | F1 | 0.059 | I1 | 0.052 | 47.000 | 47.000 | A | A |
| Example 3 | B1 | 0.316 | 5.000 | — | | — | L1 | 3.281 | LM1 | 1.406 | Y2 | 0.181 | M2 | 0.278 | C2 | 0.743 | F1 | 0.059 | I1 | 0.052 | 47.000 | 47.000 | A | A |
| Example 4 | B2 | 0.091 | 1.500 | — | | — | L1 | 3.281 | LM1 | 1.406 | Y1 | 0.181 | M3 | 0.278 | C3 | 0.742 | F1 | 0.058 | I1 | 0.054 | 47.000 | 47.000 | A | A |
| Example 5 | B3 | 0.091 | 1.500 | | | — | L1 | 3.279 | LM1 | 1.405 | Y3 | 0.181 | M1 | 0.278 | C1 | 0.742 | F1 | 0.060 | I1 | 0.056 | 47.000 | 47.000 | A | A |
| Example 6 | B4 | 0.091 | 1.500 | — | | — | L2 | 3.280 | LM1 | 1.406 | Y1 | 0.181 | M1 | 0.278 | C2 | 0.742 | F1 | 0.060 | I1 | 0.053 | 47.000 | 47.000 | A | A |
| Example 7 | B5 | 0.091 | 1.500 | — | | — | L2 | 3.279 | LM1 | 1.405 | Y2 | 0.181 | M1 | 0.278 | C2 | 0.742 | F1 | 0.060 | I1 | 0.055 | 47.000 | 47.000 | B | A |
| Example 8 | B1 | 0.107 | 1.500 | — | | — | L3 | 4.398 | L4 | 1.466 | — | — | M1 | 0.793 | C1 | 0.293 | F1 | 0.025 | I1 | 0.025 | 46.500 | 46.500 | B | B |
| Example 9 | BX1 | 0.091 | 1.500 | — | | — | L2 | 3.280 | LM1 | 1.406 | Y1 | 0.1 | M1 | 0.278 | C1 | 0.742 | F1 | 0.060 | I1 | 0.054 | 47.000 | 47.000 | A | A |
| Compar- | — | | — | B6 | 0.091 | 1.500 | L1 | 3.280 | LM1 | 1.406 | Y3 | 0.181 | M1 | 0.278 | C1 | 0.742 | F1 | 0.060 | I1 | 0.054 | 47.000 | 47.000 | A | C |
| ative | | | | | | | | | | | | | | | | | | | | | | | | |
| Example 1 | | | | | | | | | | | | | | | | | | | | | | | | |
| Compar- | — | | — | B7 | 0.091 | 1.500 | L1 | 3.278 | LM1 | 1.405 | Y1 | 0.181 | M2 | 0.278 | C2 | 0.742 | F1 | 0.060 | I1 | 0.056 | 47.000 | 47.000 | A | C |
| ative | | | | | | | | | | | | | | | | | | | | | | | | |
| Example 2 | | | | | | | | | | | | | | | | | | | | | | | | |
| Compar- | — | | — | NB1 | 0.091 | 1.500 | L2 | 3.277 | LM1 | 1.404 | Y2 | 0.181 | M3 | 0.273 | C1 | 0.742 | F1 | 0.060 | I1 | 0.060 | 47.000 | 47.000 | A | C |
| ative | | | | | | | | | | | | | | | | | | | | | | | | |
| Example 3 | | | | | | | | | | | | | | | | | | | | | | | | |
| Compar- | — | | — | NB1 | 0.316 | 5.000 | L2 | 3.277 | LMI | 1.404 | Y2 | 0.181 | M3 | 0.278 | C1 | 0.742 | F1 | 0.060 | I1 | 0.060 | 47.000 | 47.000 | C | C |
| ative | | | | | | | | | | | | | | | | | | | | | | | | |
| Example 4 | | | | | | | | | | | | | | | | | | | | | | | | |
| Compar- | — | | — | — | | — | L3 | 4.398 | L4 | 1.466 | — | — | M1 | 0.293 | C1 | 0.293 | F1 | 0.025 | I1 | 0.025 | 46.500 | 46.500 | B | C |
| ative | | | | | | | | | | | | | | | | | | | | | | | | |
| Example 5 | | | | | | | | | | | | | | | | | | | | | | | | |

TABLE 2

| | | | | | | | Compounds other | | | | | | | | |
|---|---|---|---|---|---|---|---|---|---|---|---|---|---|---|---|
| | Polymerizable | | | Polymerizable | | | than polymerizable | | | | | | | | |
| | boronic acid | | | boronic acid | | | boronic acid | | | | | | | | |
| | compound 1 | | | compound 2 | | | compound | | | | | | | | |
| | | | Mass | | | Mass | | | Mass | | | | | | |
| | | | ratio | | | ratio | | | ratio | | | | | | |
| | | | with | | | with | | | with | Polymer | | Low-molecular | | | |
| | | | respect | | | respect | | | respect | liquid | | weight liquid | | | |
| | | | to total | | | to total | | | to total | crystal | | crystal | | Dichroic | |
| | | | solid | | | solid | | | solid | compound | | compound | | substance | |
| | | Parts | content | | Parts | content | | Parts | content | | Parts | | Parts | | Parts |
| | | by | (% by | | by | (% by | | by | (% by | | by | | by | | by |
| | Type | Mass | mass) | Type | Mass | mass) | Type | mass | mass) | Type | mass | Type | mass | Type | mass |
| Example 10 | B1 | 0.088 | 1.485 | BX1 | 0.001 | 0.015 | | | — | L1 | 3.278 | LM1 | 1.405 | Y1 | 0.208 |
| Example 11 | B1 | 0.079 | 1.350 | BX1 | 0.009 | 0.150 | | | — | L1 | 3.278 | LM1 | 1.405 | Y1 | 0.208 |
| Example 12 | B1 | 0.088 | 1.500 | — | | | | | — | L1 | 3.279 | LM1 | 1.403 | Y1 | 0.208 |
| Example 13 | — | | | BX1 | 0.088 | 1.500 | | | — | L1 | 3.279 | LM1 | 1.405 | Y1 | 0.208 |
| Comparative | | | | — | | | BX6 | 0.088 | 1.500 | L1 | 3.278 | LM1 | 1.405 | Y1 | 0.208 |
| Example 6 | | | | | | | | | | | | | | | |
| | | | | | | | | | | | Tetra- | Cyclo- | | | |
| | | | Dichroic | | Dichroic | | | | Polymerization | | hydro | penta- | | | |
| | | | substance | | substance | | Surfactant | | initiator | | furan | none | | | |
| | | | | Parts | | Parts | | Parts | | Parts | Parts | Parts | Align- | Adhe- | |
| | | | | by | | by | | by | | by | by | by | ment | sive- | Liquid |
| | | | Type | mass | Type | mass | Type | mass | Type | mass | mass | mass | degree | ness | stability |
| | | Example 10 | M1 | 0 402 | C4 | 0.402 | F1 | 0.060 | I1 | 0.054 | 47.000 | 47.000 | B | A | A |
| | | Example 11 | M1 | 0.402 | C4 | 0.402 | F1 | 0.060 | I1 | 0.054 | 47.000 | 47.000 | B | A | A |
| | | Example 12 | M1 | 0.402 | C4 | 0.402 | F1 | 0.059 | I1 | 0.054 | 47.000 | 47.000 | B | A | B |
| | | Example 13 | M1 | 0.402 | C4 | 0.402 | F1 | 0.060 | I1 | 0.054 | 47.000 | 47.000 | B | A | B |
| | | Comparative | M1 | 0.402 | C4 | 0.402 | F1 | 0.060 | I1 | 0.054 | 47.000 | 47.000 | B | C | B |
| | | Example 6 | | | | | | | | | | | | | |

As shown in Tables 1 and 2, the light absorption anisotropic film which was formed of the liquid crystal composition containing the liquid crystal compound, the dichroic substance, and the boronic acid compound containing a polymerizable group and in which the liquid crystal compound was horizontally aligned had excellent adhesiveness to other layers and exhibited a high alignment degree (Examples 1 to 13).

Based on the comparison between Examples 1 to 6 and Example 7, it was found that a light absorption anisotropic film with a higher alignment degree was obtained in a case where the compound represented by Formula (B-2) was used as the polymerizable boronic acid compound (Examples 1 to 6).

Based on the comparison between Examples 1 and 8, it was found that a light absorption anisotropic film with a higher alignment degree and more excellent adhesiveness was obtained in a case where the polymer liquid crystal compound (Example 1) was used.

Based on the comparison between Examples 10 and 11 and Examples 12 and 13, it was found that the liquid stability of the liquid crystal composition was excellent in a case where the compound represented by Formula (B-1) and the compound represented by Formula (BX-1) were used in combination as the polymerizable boronic acid compound (Examples 10 and 11).

On the contrary, as listed in Tables 1 and 2, it was found that at least one of the alignment degree or the adhesiveness was degraded in a case where the light absorption anisotropic film was prepared without using the polymerizable boronic acid compound (Comparative Examples 1 to 6).

What is claimed is:

1. A light absorption anisotropic film formed of a liquid crystal composition that contains a liquid crystal compound, a dichroic substance, and a boronic acid compound containing a polymerizable group,
wherein the liquid crystal compound is horizontally aligned.

2. The light absorption anisotropic film according to claim 1,
wherein the boronic acid compound containing a polymerizable group includes at least one of a compound represented by Formula (B-1) or a compound represented by Formula (BX-1), 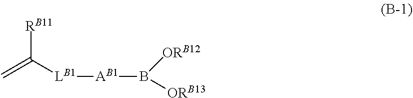
in Formula (B-1), R^{B11} represents a hydrogen atom or a methyl group,
L^{B1} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{B14})—, R^{B14} represents a hydrogen atom or an alkyl group,
A^{B1} represents an arylene group that may have a substituent or a heteroarylene group that may have a substituent,
R^{B12} and R^{B13} each independently represent a hydrogen atom, an alkyl group that may have a substituent, an aryl group that may have a substituent, or a heteroaryl group that may have a substituent, and R^{B12} and R^{B13} may be bonded to each other to form a ring, 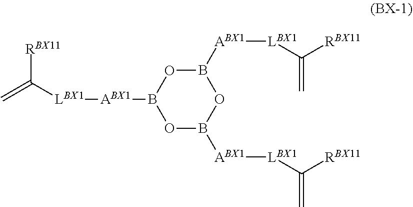
in Formula (BX-1), R^{BX11} represents a hydrogen atom or a methyl group, where a plurality of R^{BX11}'s may be the same as or different from each other,
L^{BX1} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{BX14})—, where a plurality of L^{BX1}'s may be the same as or different from each other, R^{BX14} represents a hydrogen atom or an alkyl group, and in a case where a plurality of R^{BX14}'s are present, the plurality of R^{BX14}'s may be the same as or different from each other,
A^{BX1} represents an arylene group that may have a substituent or a heteroarylene group that may have a substituent, and a plurality of A^{BX1}'s may be the same as or different from each other.

3. The light absorption anisotropic film according to claim 1,
wherein the boronic acid compound containing a polymerizable group includes at least one of a compound represented by Formula (B-2) or a compound represented by Formula (BX-2), 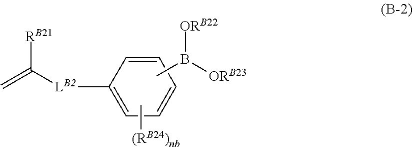
in Formula (B-2), R^{B21} represents a hydrogen atom or a methyl group,
L^{B2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{B25})—, R^{B25} represents a hydrogen atom or an alkyl group,
R^{B22} and R^{B23} each independently represent a hydrogen atom, an alkyl group that may have a substituent, an aryl group that may have a substituent, or a heteroaryl group that may have a substituent, where R^{B22} and R^{B23} may be bonded to each other to form a ring,
R^{B24} represents a monovalent substituent,
nb represents an integer of 0 to 4, and in a case where nb represents 2 or greater, a plurality of R^{B24}'s may be the same as or different from each other, 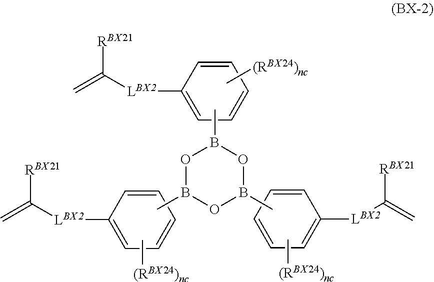
in Formula (BX-2), R^{BX21} represents a hydrogen atom or a methyl group, where a plurality of R^{BX21}'s may be the same as or different from each other,
L^{BX2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{BX25})—, where a plurality of L^{BX2}'s may be the same as or different from each other, R^{BX25} represents a hydrogen atom or an alkyl group, and in a case where a plurality of R^{BX25}'s are present, the plurality of R^{BX25}'s may be the same as or different from each other,
R^{BX24} represents a monovalent substituent, where in a case where a plurality of R^{BX24}'s are present, the plurality of R^{BX24}'s may be the same as or different from each other,
nc represents an integer of 0 to 4, and a plurality of nc's may be the same as or different from each other.

4. The light absorption anisotropic film according to claim 1,
wherein a content of the boronic acid compound containing a polymerizable group is in a range of 0.1% to 10% by mass with respect to a total mass of a solid content of the liquid crystal composition.

5. The light absorption anisotropic film according to claim 2,
wherein the boronic acid compound containing a polymerizable group includes the compound represented by Formula (B-1) and the compound represented by Formula (BX-1), and
a mass ratio of a content of the compound represented by Formula (B-1) to a content of the compound represented by Formula (BX-1) is in a range of 5 to 500.

6. The light absorption anisotropic film according to claim 3,
wherein the boronic acid compound containing a polymerizable group includes the compound represented by Formula (B-2) and the compound represented by Formula (BX-2), and
a mass ratio of a content of the compound represented by Formula (B-2) to a content of the compound represented by Formula (BX-2) is in a range of 5 to 500.

7. The light absorption anisotropic film according to claim 1,
wherein the liquid crystal compound includes a polymer liquid crystal compound.

8. A laminate comprising:
the light absorption anisotropic film according to claim 1; and
a layer containing a polyvinyl alcohol-based resin disposed to be in contact with the light absorption anisotropic film.

9. The laminate according to claim 8, further comprising:
a λ/4 plate on a side of the light absorption anisotropic film opposite to the layer containing a polyvinyl alcohol-based resin.

10. An image display device comprising:
the light absorption anisotropic film according to claim 1

11. A liquid crystal composition comprising:
a liquid crystal compound;
a dichroic substance; and
a boronic acid compound containing a polymerizable group,
wherein the boronic acid compound containing a polymerizable group includes at least one of a compound represented by Formula (B-2) or a compound represented by Formula (BX-1), 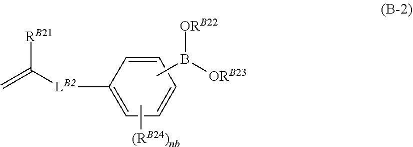
in Formula (B-2), R^{B21} represents a hydrogen atom or a methyl group,
L^{B2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{B25})—, R^{B25} represents a hydrogen atom or an alkyl group,
R^{B22} and R^{B23} each independently represent a hydrogen atom, an alkyl group that may have a substituent, an aryl group that may have a substituent, or a heteroaryl group that may have a substituent, where R^{B22} and R^{B23} may be bonded to each other to form a ring,
R^{B24} represents a monovalent substituent,
nb represents an integer of 0 to 4, and in a case where nb represents 2 or greater, a plurality of RB²⁴'s may be the same as or different from each other, 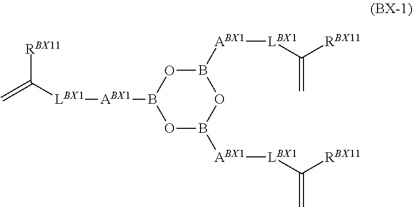
in Formula (BX-1), R^{BX11} represents a hydrogen atom or a methyl group, where a plurality of R^{BX11}'s may be the same as or different from each other,
L^{BX1} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{BX14})—, where a plurality of L^{BX1}'s may be the same as or different from each other, R^{BX14} represents a hydrogen atom or an alkyl group, and in a case where a plurality of R^{BX14}'s are present, the plurality of R^{BX14}'s may be the same as or different from each other,
A^{BX1} represents an arylene group that may have a substituent or a heteroarylene group that may have a substituent, and a plurality of A^{BX1}'s may be the same as or different from each other.

12. The liquid crystal composition according to claim 11,
wherein the compound represented by Formula (BX-1) is a compound represented by Formula (BX-2), 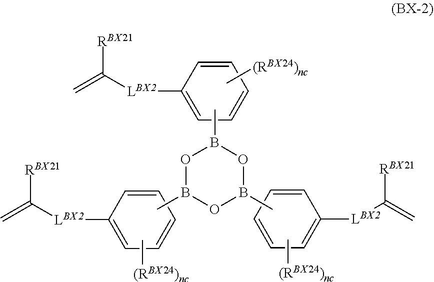
in Formula (BX-2), R^{BX21} represents a hydrogen atom or a methyl group, where a plurality of R^{BX21}'s may be the same as or different from each other,
L^{BX2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{BX25})—, where a plurality of L^{BX2}'s may be the same as or different from each other, R^{BX25} represents a hydrogen atom or an alkyl group, and in a case where a plurality of R^{BX25}'s are present, the plurality of R^{BX25}'s may be the same as or different from each other,
R^{BX24} represents a monovalent substituent, where in a case where a plurality of R^{BX24}'s are present, the plurality of R^{BX24}'s may be the same as or different from each other,
nc represents an integer of 0 to 4, and a plurality of nc's may be the same as or different from each other.

13. The liquid crystal composition according to claim 11,
wherein a content of the boronic acid compound containing a polymerizable group is in a range of 0.1% to 10% by mass with respect to a total mass of a solid content of the liquid crystal composition.

14. The liquid crystal composition according to claim 11,
wherein the boronic acid compound containing a polymerizable group includes the compound represented by Formula (B-2) and the compound represented by Formula (BX-1), and
a mass ratio of a content of the compound represented by Formula (B-2) to a content of the compound represented by Formula (BX-1) is in a range of 5 to 500.

15. An image display device comprising:
the laminate according to claim 8.

16. The light absorption anisotropic film according to claim 2,
wherein the boronic acid compound containing a polymerizable group includes at least one of a compound represented by Formula (B-2) or a compound represented by Formula (BX-2), 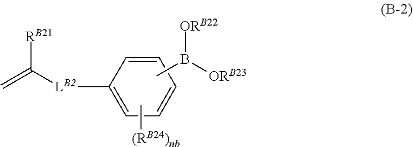
in Formula (B-2), R^{B21} represents a hydrogen atom or a methyl group,
L^{B2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{B25})—, R^{B25} represents a hydrogen atom or an alkyl group,
R^{B22} and R^{B23} each independently represent a hydrogen atom, an alkyl group that may have a substituent, an aryl group that may have a substituent, or a heteroaryl group that may have a substituent, where R^{B22} and R^{B23} may be bonded to each other to form a ring,
R^{B24} represents a monovalent substituent,
nb represents an integer of 0 to 4, and in a case where nb represents 2 or greater, a plurality of R^{B24}'s may be the same as or different from each other, 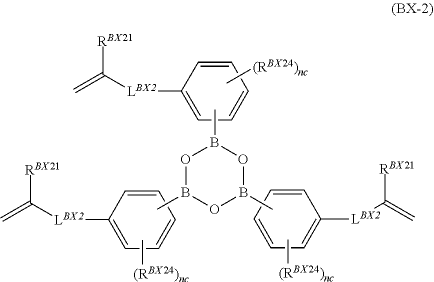
in Formula (BX-2), R^{BX21} represents a hydrogen atom or a methyl group, where a plurality of R^{BX21}'s may be the same as or different from each other,
L^{BX2} represents a single bond, a divalent aliphatic hydrocarbon group, or a divalent group in which one or more of —CH₂—'s constituting a divalent aliphatic hydrocarbon group is substituted with at least one group selected from the group consisting of —O—, —C(═O)—, and —N(R^{BX25})—, where a plurality of L^{BX2}'s may be the same as or different from each other, R^{BX25} represents a hydrogen atom or an alkyl group, and in a case where a plurality of R^{BX25}'s are present, the plurality of R^{BX25}'s may be the same as or different from each other,
R^{BX24} represents a monovalent substituent, where in a case where a plurality of R^{BX24}'s are present, the plurality of R^{BX24}'s may be the same as or different from each other,
nc represents an integer of 0 to 4, and a plurality of nc's may be the same as or different from each other.

17. The light absorption anisotropic film according to claim 2,
wherein a content of the boronic acid compound containing a polymerizable group is in a range of 0.1% to 10% by mass with respect to a total mass of a solid content of the liquid crystal composition.

18. The light absorption anisotropic film according to claim 2,
wherein the liquid crystal compound includes a polymer liquid crystal compound.

19. A laminate comprising:
the light absorption anisotropic film according to claim 2; and
a layer containing a polyvinyl alcohol-based resin disposed to be in contact with the light absorption anisotropic film.

20. The laminate according to claim 19, further comprising:
a λ/4 plate on a side of the light absorption anisotropic film opposite to the layer containing a polyvinyl alcohol-based resin.
